(19) United States
(12) Patent Application Publication
(10) Pub. No.: US 2025/0231886 A1
(43) Pub. Date: Jul. 17, 2025

(54) INTEGRATED SUPERCONDUCTING MEMORY AND LOGIC PIPELINES

(71) Applicant: William Robert Reohr, Severna Park, MD (US)

(72) Inventors: William Robert Reohr, Severna Park, MD (US); Barry Watson Krumm, Ocean Grove, NJ (US); Steven Andrew Engel, Milltown, IN (US)

(21) Appl. No.: 19/038,748

(22) Filed: Jan. 28, 2025

Related U.S. Application Data
(63) Continuation of application No. PCT/US2023/071446, filed on Aug. 1, 2023.
(60) Provisional application No. 63/394,130, filed on Aug. 1, 2022.
(60) Provisional application No. 63/412,317, filed on Sep. 30, 2022.
(60) Provisional application No. 63/425,160, filed on Nov. 14, 2022.

(51) Int. Cl. G06F 12/1027; G06F 12/02

(52) U.S. Cl. CPC G06F 12/1027; G06F 12/0238; G06F 2212/7201

(57) ABSTRACT

A time-division multiplexed (TDM) lookup circuit for use in a superconducting cache, the TDM lookup circuit including a superconducting memory and at least one comparator circuit operatively coupled to the superconducting memory. The comparator circuit includes a first input adapted to receive a first address corresponding to a requested data location in the superconducting memory and a second input adapted to receive a second address corresponding to a memory location external to the TDM lookup circuit. The comparator is configured to perform at least one compare process wherein the first address is compared with the second address and an output signal is generated that is indicative of whether a match has occurred between the first and second addresses. The comparator is configured to perform multiple compare processes per lookup access.

### CROSS-REFERENCE TO RELATED APPLICATIONS

This application is a bypass continuation of PCT Application No. PCT/US2023/071446, filed Aug. 1, 2023, which claims the benefit of and priority under 35 U.S.C. § 119 to U.S. Provisional Patent Application No. 63/425,160, filed on Nov. 14, 2022, entitled “Superconducting Memory, Programmable Logic Arrays, and Fungible Arrays,” U.S. Provisional Patent Application No. 63/412,317, filed on Sep. 30, 2022, entitled “Superconducting Cache Memory, Memory Control Logic, and Fungible Memories,” and U.S. Provisional Patent Application No. 63/394,130, filed on Aug. 1, 2022, entitled “Control and Data Flow Logic for Reading and Writing Large Capacity Memories, Logic Arrays, and Interchangeable Memory and Logic Arrays Within Superconducting Systems,” the disclosures of which are incorporated by reference herein in their entirety for all purposes.

### BACKGROUND

The present invention relates generally to quantum and classical digital superconducting electronics, and more specifically to the integration of memory and logic circuits in architected pipelines.

Virtual addressing refers to the process of assigning easily manageable, temporary, memory addresses to physical memory. Essentially, it is to an organizational system for computer random-access memory (RAM), much as the Dewey decimal system is to libraries. Virtual memory helps with code sharing between multiple processes, data security, and preventing memory fragmentation and errors. Most often virtual memory extends the address space into the “pages” stored within the file system (i.e., disk or flash memory). Data movement (i.e., page movement) between main memory (physical addresses) and the file system is managed by an operating system.

Caches are a form of memory that improve processing speed by storing the most recently used data, and spatially related data (e.g., next instruction in a program), closer to the processor elements (relative to other types of memory) such that future similar operations can occur faster. Caches can vary in size, structure, and cost; as a general trend, there are multiple levels of caches, which tend to decrease in size and increase in energy cost as they are brought closer to the CPU.

In order to support ultra-low power systems, in the near term, and quantum computing, eventually, cache memory capable of operating in a temperature range from about 3 to 4.2 degrees Kelvin is needed.

### SUMMARY

The present invention, as manifested in one or more embodiments, is directed to illustrative systems, circuits, devices and/or methods for forming superconducting memory and logic pipelines.

In accordance with an embodiment of the present inventive concept, a time-division multiplexed (TDM) lookup circuit for use in a superconducting cache is provided. The TDM lookup circuit includes at least one superconducting memory configured to serve as a directory in the lookup circuit, and at least one comparator circuit. The comparator circuit includes a first input adapted to receive a first physical address corresponding to a requested data location and a second input adapted to receive a second physical address corresponding to a main memory external to the TDM lookup circuit. The comparator is configured to perform at least one compare process wherein the first physical address is compared with the second physical address, and to generate an output signal indicative of whether a match has occurred between the first and second physical addresses. The comparator is configured to perform multiple compare processes per lookup access period.

Techniques of the present invention can provide substantial beneficial technical effects. By way of example only and without limitation, techniques for exploiting RQL/SFQ memory and logic in caches and CAMs and as variable latency memories according to one or more embodiments of the invention may provide one or more of the following advantages, among other benefits:
improves wireability to a comparator which performs a RAM-versus-RAM output comparison advantageously reducing bussing/comparator width and/or number of busses/competitors in selected embodiments, by using several time division multiplexing (henceforth TDM) techniques along with copying/replication techniques;
provides a means for read and write row-oriented time division multiplexing, which generates two waves of data for every memory read operation and which stores two waves of data for every memory write operation;
provides a means for read and write controls-oriented time division multiplexing, which generates two waves of data for every memory read operation and which stores two waves of data for every memory write operation, operations being for a particular architected function such as a lookup;
provides a means for spatially-based and time-based confluence of signals for substantially concurrent virtual translation lookup and directory lookup and associated address matching of the lookups to identify whether the data RAM stores the requested data (hit or miss);
enables seamless physical and timing integration of match array and data array components of a content addressable memory (CAM), maintaining identical data array output skew—signal timing—regardless of the match location/column within the match array;
integrates RAM output skew with various serially-evaluating comparator embodiments (or, more generally speaking, other output logic) using novel skewed serial comparators;
cancels out RAM output skew to improve comparator output timing, by using novel skewed serial comparators (or other logic);
rather than fixing all latencies to the slowest path, aspects of the inventive concept provide a means for addresses having variable raw delays through a memory, for example, slow, medium slow, medium fast, and fast, to have lower latency access of the memory, where and when feasible;
reduces the total layers of metal required to support the integrated memory and logic associated with a cache lookup.

These and other features and advantages of the present invention will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a block diagram conceptually depicting at least a portion of a dual-ported reciprocal quantum logic (RQL)/single flux quantum (SFQ) memory cell 100;

FIG. 2 is a block diagram conceptually illustrating a memory element(s) and a logic circuit specifying a timing allotment associated with each, showing alternative memory cell orientations and aspect ratios/sizes (e.g., RQL-based), identifying relative memory cell and logic gate orientations using an orientation indicator;

FIGS. 3A, 3B and 3C are timing diagrams that may be used to conceptually illustrate how the physical location of read row lines and read column lines in an exemplary 128×128 memory array can impact the delay of their outputs, or that of a superconducting array system;

FIG. 4 is a block diagram depicting at least a portion of a cache system, according to one or more embodiments of the invention;

FIG. 5 is a block diagram conceptually depicting an exemplary address anatomy for a level 1 cache, which serves to define different addresses at work within a level 1 cache;

FIG. 6A is a block diagram depicting at least a portion of an exemplary lookup path for a four-way set associate cache, with a fully associative translation lookaside buffer (TLB) (content addressable memory (CAM)-based), according to one or more embodiments of the invention;

FIG. 6B is a block diagram depicting at least a portion of an exemplary serial AND-OR arrays circuit, which can support any Boolean function, according to one or more embodiments of the invention;

FIG. 7 conceptually depicts a more detailed illustration of the exemplary TLB in the lookup path of a four-way set associative cache according to one or more embodiments of the invention, which defines required, read and write line orientations and flow directions within its internal memories (i.e., TLB_Match and TLB_Array) and relative to a directory RAM(s);

FIG. 8 conceptually depicts a detailed illustration of the exemplary TLB in the lookup path of a four-way set associative cache, according to one or more embodiments of the invention;

FIG. 9 is an illustrative timing diagram that conceptually summarizes component latencies of the TLB pipeline for different exemplary translations paths (e.g., paths 1 and 2 of FIGS. 7 and 8, respectively), according to one or more embodiments of the invention;

FIG. 10 is a block diagram conceptually depicting a more detailed illustration of the exemplary directory RAM and serial compare equal circuits of the lookup path for the four-way set associative cache shown in FIG. 6A, according to one or more embodiments of the invention;

FIG. 11 is a block diagram depicting at least a portion of an exemplary serial compare equal circuit, according to one or more embodiments of the invention;

FIG. 12 is a block diagram depicting at least a portion of an exemplary serial compare equal circuit having increased bandwidth compared to the illustrative serial compare equal circuit shown in FIG. 11, according to one or more embodiments of the invention;

FIG. 13 is a flow diagram and schematic conceptually depicting at least a portion of an exemplary lookup path for a two-way set associative cache which implements virtual to physical address translation, with a fully associative TLB (CAM-based), according to one or more embodiments of the invention;

FIG. 14 is a flow diagram and schematic depicting at least a portion of an exemplary lookup path for a direct-mapped cache which implements virtual to physical address translation, with a fully associative TLB (CAM-based), according to one or more embodiments of the invention;

FIG. 15 is a schematic diagram depicting at least a portion of an exemplary serial compare equal circuit, according to one or more embodiments of the invention;

FIG. 16 is a flow diagram and schematic depicting at least a portion of an exemplary lookup path for a two-way set associative cache, with a fully associative TLB (CAM-based), according to one or more embodiments of the invention;

FIG. 17 is a flow diagram and schematic depicting at least a portion of an exemplary lookup path for a two-way set associative cache, with a fully associative TLB (CAM-based), which implements virtual to physical address translation, according to one or more embodiments of the invention;

FIG. 18 is a schematic diagram depicting at least a portion of an exemplary RQL (or SFQ)-based time-division multiplexed memory array employing TDM for reading data from memory cells (or fixed switches/ROM cells as known in the art) within an array, according to one or more embodiments of the invention;

FIG. 19 is a timing diagram conceptually depicting certain illustrative signals in the exemplary time-division-multiplexed memory array shown in FIG. 18 during a TDM read operation, according to one or more embodiments of the invention;

FIGS. 20 and 21 are a block diagram and corresponding write timing diagram, respectively, conceptually depicting a time-division-demultiplexing memory array and an illustrative write operation associated therewith, according to one or more embodiments of the invention;

FIG. 22 is a flow diagram and schematic depicting at least a portion of an exemplary lookup path for a two-way set associative cache which implements virtual to physical address translation, with a fully associative TLB, according to one or more embodiments of the invention;

FIGS. 23 and 24 show an exemplary flow diagram and schematic of a TLB Virtual-Address-Match portion of a lookup path for a four-way set associative cache, which implements virtual to physical address translations, according to one or more embodiments of the invention;

FIGS. 25 and 26 collectively depict a lookup path for an exemplary two-way set associative cache having a two-way set associative TLB in its entirety, according to one or more embodiments of the invention;

FIG. 27 is a block diagram depicting at least of an exemplary variable delay pipelined SFQ memory array, according to one or more embodiments;

FIG. 28 is a block diagram depicting at least a portion of an exemplary four-way set associative cache, with a fully associate TLB, that is capable of metamorphosis, according to one or more alternative embodiments of the inventive concept;

FIG. 29 is a block diagram conceptually depicting at least a portion of an exemplary variable delay pipelined memory array, according to one or more embodiments of the invention;

FIG. 30 is a block diagram depicting at least a portion of an exemplary variable delay pipelined memory array 3000 including added delay elements, according to one or more embodiments of the invention;

FIG. 31 conceptually depicts exemplary collision cases, according to one or more embodiments of the invention;

FIG. 32 depicts an alternative embodiment of control circuits for a variable latency RAM having a plurality of mimic delay pipelines and their associated address request entities, according to one or more embodiments of the invention;

FIG. 33 depicts inputs, outputs, and states of an address request entity, according to one or more embodiments of the invention; and

FIG. 34 depicts a scheduler and an injection decision circuit, according to one or more embodiments of the invention.

It is to be appreciated that elements in the figures are illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in one or more embodiments, will be described herein in the context of cache and its associated memories. It is to be appreciated, however, that the invention is not limited to the specific devices, circuits, systems and/or methods illustratively shown and described herein. Rather, it will become apparent to those skilled in the art given the teachings herein that numerous modifications to the embodiments shown are contemplated and are within the scope of the present inventive concept. That is, no limitations with respect to the embodiments shown and described herein are intended or should be inferred.

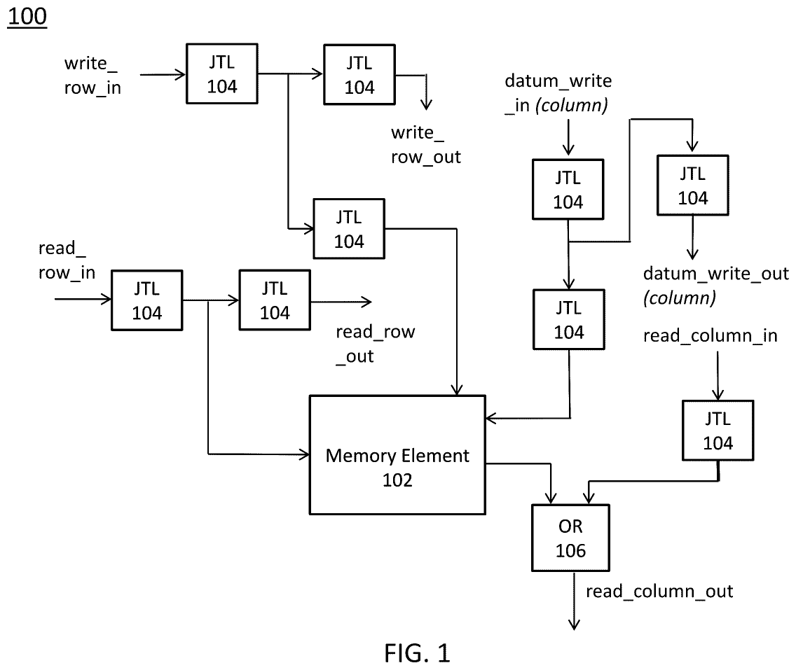

FIG. 1 is a block diagram conceptually depicting at least a portion of a dual-ported reciprocal quantum logic (RQL)/single flux quantum (SFQ) memory cell 100. The RQL/SFQ memory cell 100 includes a memory element 102, a plurality of Josephson transmission lines 104 (henceforward JTL(s)), and at least one logic gate 106 (here an OR gate). The RQL/SFQ memory cell 100 furthermore (and notably) includes independent read and write ports, like most known superconducting memory cells (there is at least one exception where ports are combined), which enable advantageous data flow arrangements and functional capabilities. While FIG. 1 represents a particular RQL/SFQ memory cell schematic, it can also provide a functional representation and can also be used to indicate/assess latency, for high-level description of other memory cells at a next level of hierarchy in a memory system architecture. For the purpose of this disclosure, FIG. 1 can represent/express timing features present in different SFQ memories, such as described in Burnett, R., et al., “Demonstration of Superconducting Memory for an RQL CPU,” Proceedings of the International Symposium on Memory Systems, ACM (2018) (“Burnett 2018”), or Herr, Q, et al. “Superconducting Pulse Conserving Logic and Josephson-SRAM,” Applied Physics Letters 122, no. 18 (2023) (“Herr 2023”), the disclosures of which are incorporated by reference herein in their entirety, even though their behavioral/functional descriptions may not be identical.

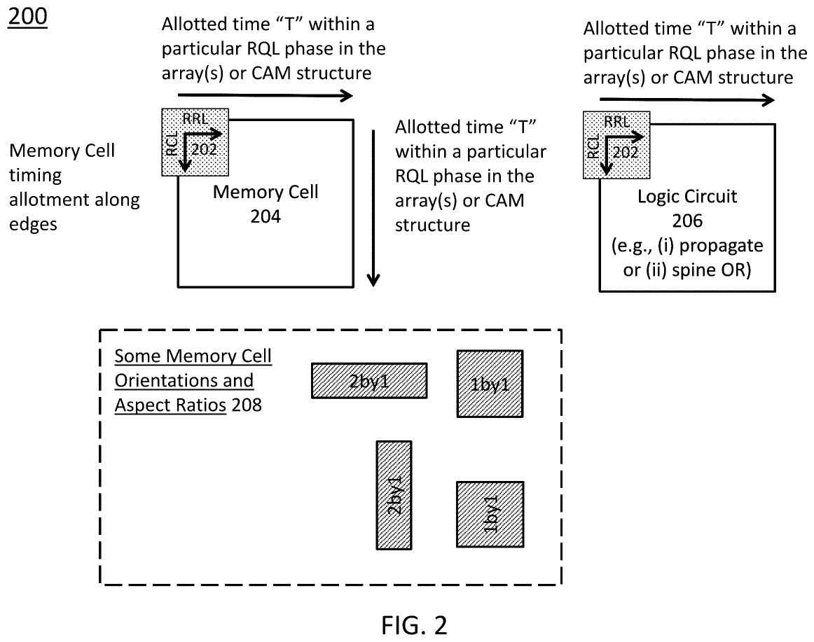

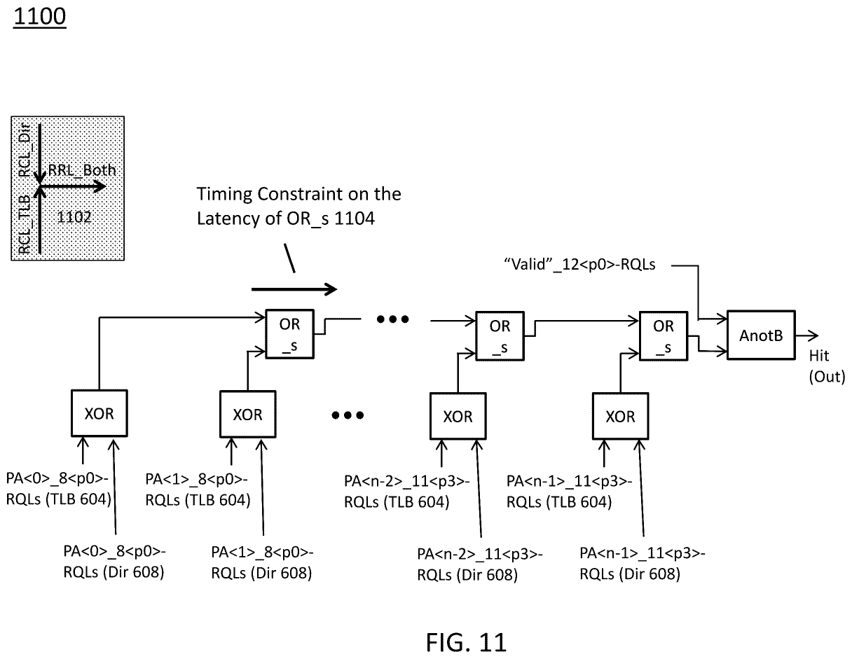

FIG. 2 is a block diagram conceptually illustrating horizontal and vertical features of a memory cell(s) 204 and a logic circuit 206 specifying a timing allotment associated with each, showing alternative memory cell orientations and aspect ratios/sizes 208 (e.g., RQL-based), identifying relative memory cell and logic circuit orientations using an orientation indicator 202. Used throughout the detailed description and integrated into its associated FIGS., the orientation indicator 202 relates a circuit(s) orientation to read row line(s) (RRL(s)) and read column line(s) (RCL(s)) of an associated memory array, or defines the orientation of the memory cell in the memory array itself. Generally, the orientation indicator 202 defines signal flow direction and indicates accumulating time (where the RCL direction is an exception for all comparator circuits depicted in FIGS. 11, 12, and 15, which have dual-sided top and bottom inputs shown exclusively as bottom inputs in the schematics). One or more interrelated physical, logical, and timing relationships may be established with the orientation indicator 202 in subsequent descriptions herein.

With reference to FIG. 2, the memory cell 204 arrangement describes timing as it relates to physical design. Also shown in FIG. 2 is a timing rule which specifies that a time allotment “T” for a given selection signal passing through a read row line (RRL) in the memory element can be equal to a time allotment “T” for data passing through a read column line (RCL) for memory cells of several possible orientations and/or aspect ratios by careful design of the memory cell 204. Specific aspect ratios can be required for the integration of memory-to-memory and memory-to-logic data flows as will be described later with respect to cache and content-addressable memory (CAM) embodiments.

For purposes of illustration only and without limitation, latency/timing numbers can be derived for a memory array size of 128 rows by 128 columns (128×128 array), based on the circuits of Burnett 2018. This exemplary memory is 16,384 bits, equivalent to 2K bytes (KB), where a byte is 8 bits, or if 9 bits are assigned to a byte for error correction code (ECC)/parity, 2 KB would equal 18,432 bits of data storage. Burnett 2018 reported that, in their design, the traversal of 32 memory cells in either row or column dimensions occurs over a given memory cycle. Therefore, it takes four RQL cycles to either cross a full row of memory cells or traverse a full column of memory cells. The cycle time was 500 picoseconds (ps) for a D-Wave technology/process exploited. With process improvements, cycle times were expected to drop to 200 ps. Other changes in design, such as pipeline depth, may yield further improvements in speed or other metrics.

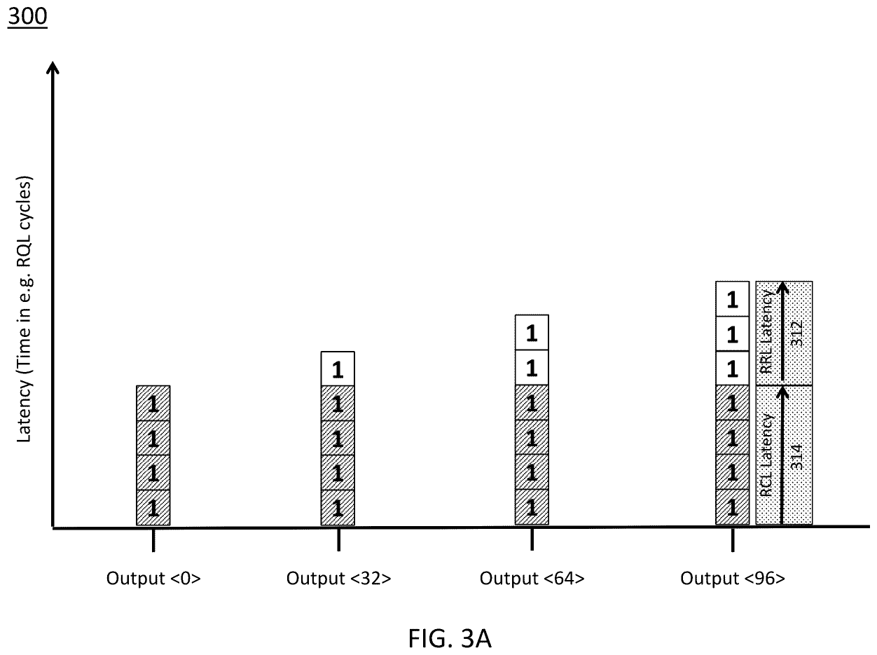

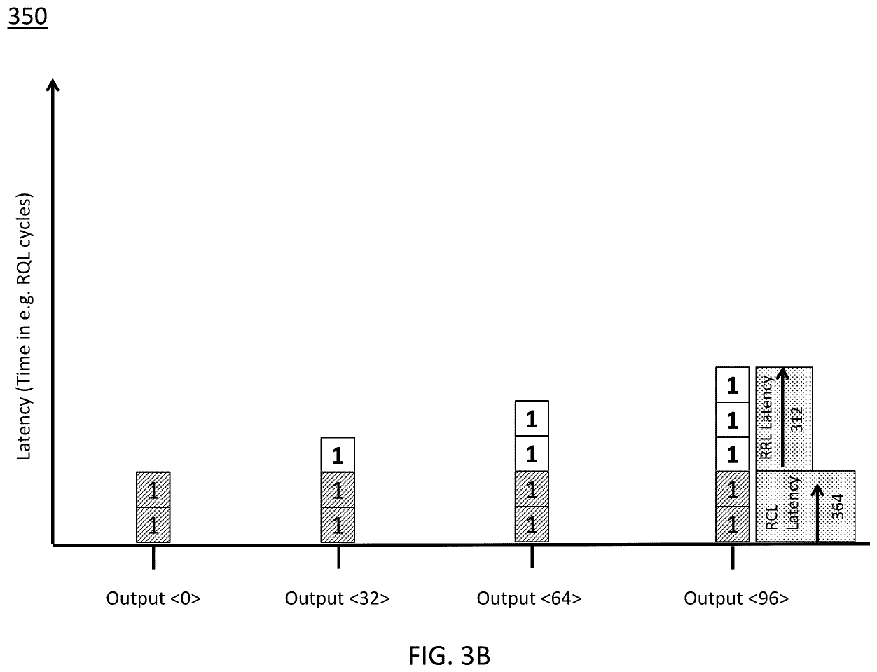

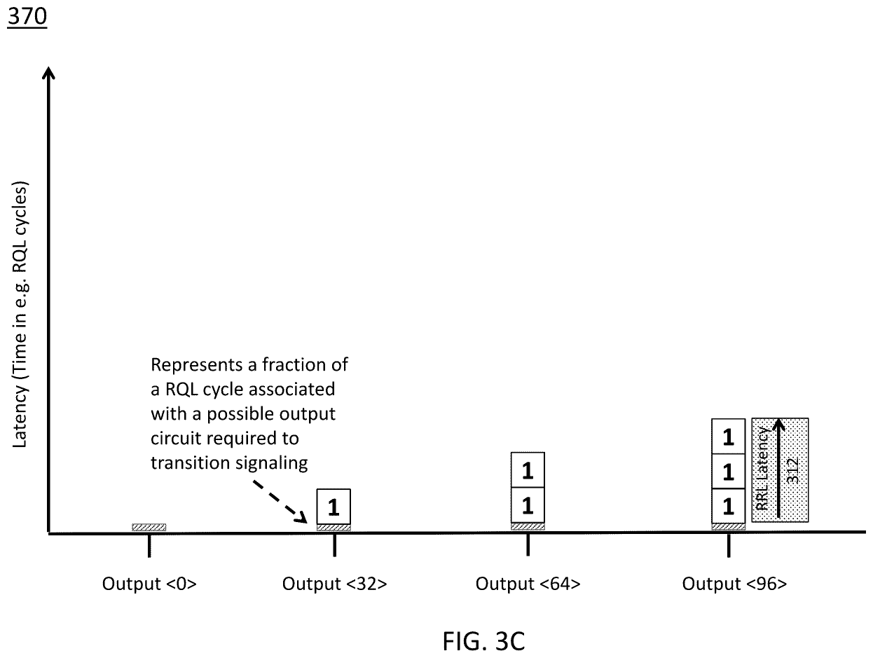

FIGS. 3A, 3B and 3C are timing diagrams that may be used to conceptually illustrate how the physical location of read row lines and read column lines in an exemplary 128×128 memory array can impact the delay of their outputs, or that of a superconducting array system (labeled as “Output<N>,” where N is an integer, 0, 1, 2 . . . ). Incremental inter-cycle skews are shown for far, middle, and near read row lines, respectively. Output delays are indicated across columns. While not explicitly displayed in FIGS. 3A, 3B, and 3C, intracycle delay (referred to as phase delay) is also present due to specific row and column locations in a memory circuit. In this example, it is assumed that column 0, generating output signal output <0> is closer to the processor/entity utilizing the memory compared to output <96>, for example, at least in terms of physical location and latency, although it is to be appreciated that embodiments of the invention are not limited to this arbitrary assignment. Latency contributors have been included on FIGS. 3A, 3B and 3C, for the purposes of clearly identifying where latency arises in the exemplary 128×128 memory array.

Cycle skews may arise in many forms of RQL/SFQ memory interactions ranging from (i) memory to logic, (ii) memory to memory, or (iii) logic disposed among memories (where memories can serve as the logic's principle functional sources). Skews can arise, for example, in cache lookup paths, programmable logic array (PLA) paths, and content addressable memories (CAMs). Multi-cycle memory skews for these various memory paths may be mitigated by one or more embodiments of the present inventive concept.

With reference to FIGS. 3A, 3B, and 3C, timing diagrams 300, 350 and 370, respectively, illustrate three exemplary read requests to different addresses of the 128 bit by 128 bit RQL array, where a first read request depicted in FIG. 3A selects a “far” read row line (i.e., farthest in time from the output (output <N>) relative to a processor requesting data) associated with a first address, where a second read request depicted in FIG. 3B selects a “middle” read row line (i.e., half way in time from the output (output <N>) relative to a processor requesting data) associated with a second address, and a third read request depicted in FIG. 3C selects a “near” read row line (i.e., nearest in time to the output (output <N>) relative to the requesting processor) associated with a third address. The latency of OR gates and Josephson transmission lines (JTLs) associated with a given column (a part of each memory cell) appears prominently in the read operation directed to the “far” read row line, which occupies four RQL cycles (four boxes labeled with a “1” having diagonal fill lines), due to the signal traversal of 128 memory cells in the column read line. The row column line (RCL) latency indicators 314 and 364 highlight the cumulative latency in the column dimension for the “far” and “middle” row addresses, associated with FIGS. 3A and 3B, respectively. By contrast, the latency of the single column OR and its JTL (a part of the final memory cell) appear insignificant in the read operation directed to the “near” read row line due to the signal traversal of one memory cell in the column read line as depicted in FIG. 3C.

Boxes accumulating indicate that row line latency grows across data outputs from the nearest output, output <0>, to the farthest output depicted, output <96>. A blank box labeled with a “1” represents a row cycle. The read row line (RRL) latency indicator 312 highlights the cumulative latency in a row line to reach output <96> for FIGS. 3A, 3B, and 3C.

In general, it should be understood that column lines can be formed with intrinsic logic that perform Boolean operations other than OR, such as an AND.

### Cache Logic, Circuits, and Floor Plan

Aspects according to embodiments of the invention will be illustrated using various “lookup” paths (i.e., flows) of a cache. To assure technical clarity in the detailed description, some categorizations may be made, and some terms of art are defined, subsequently.

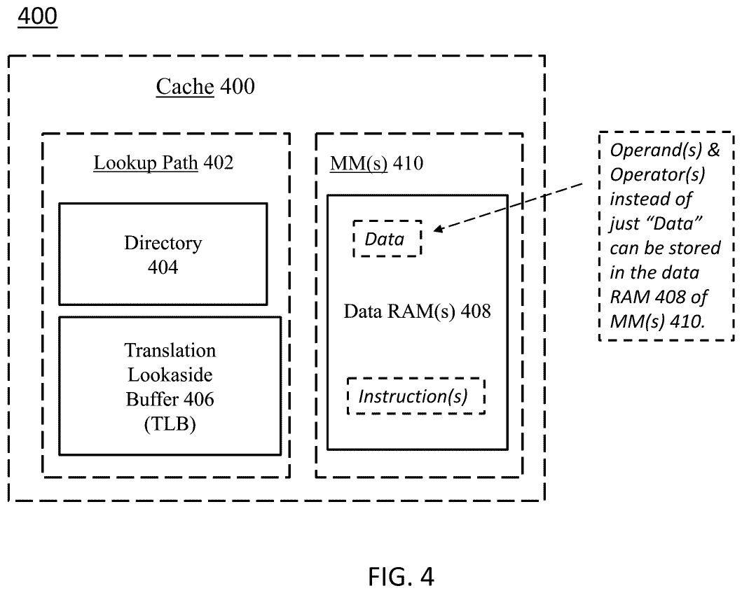

FIG. 4 is a block diagram depicting at least a portion of a cache system 400, according to one or more embodiments of the invention. The cache system 400 may include at least one lookup path (i.e., circuit) 402 and at least one data RAM 408, or other addressable storage element. The cache system 400 is exhibited primarily for the purpose of establishing consistent terminology within the present disclosure and for defining certain functional/logical features of the overarching system, enabled seamlessly, and for less cost, than conventional approaches, by unique physical and pipeline implementations disclosed in embodiments of the invention.

The exemplary lookup path 402 may include a directory 404 and a translation lookaside buffer (TLB) 406, which is often defined as a memory cache that stores recent translations of logical/virtual memory to absolute/physical memory. In one or more embodiments, the data RAM 408 may be fungible—configured to perform logic, memory, and mixed memory and logic operations. The data RAM 408 is preferably configured to store lines of data, each line of data comprising, for example, contiguous data, independently addressable, and/or contiguous instructions, also independently addressable. Furthermore, the data RAM 408 may comprise data, one or more operands, one or more instructions, and/or one or more operators stored in at least a portion of the data RAM. In one or more embodiments, a metamorphosing memory (MM) 410 can include additional elements, in relation to those commonly associated with a data RAM, to perform unique logic computations within the address and data flows of the data RAM. A metamorphosing memory suitable for use in conjunction with aspects of the present inventive concept may be found, for example, in PCT Application No. PCT/US23/16090, entitled “Metamorphosing Memory,” filed in the U.S. Receiving Office on Mar. 23, 2023, the disclosure of which is incorporated by reference herein in its entirety.

With regards to the lookup path 402 of the cache system 400, many different possibilities for translation and associativity can exist. Some first-level cache implementation alternatives may include the following:
(i) a fully associative translation lookaside buffer (TLB) and a set associative directory;
(ii) A set associative TLB and a fully associative directory;
(iii) A set associative TLB and set associative directory; and
(iv) A fully associative TLB and a fully associative directory.

Full associativity allows any address to be stored in any line of the cache. When a memory operation is sent to a fully associative cache, the address of the request must be compared to each entry in the tag array to determine whether the data referenced by the operation is contained in the cache. In a direct-mapped cache, each memory address can only be stored in one location in the cache. When a memory operation is sent to a direct-mapped cache, a subset of the bits in the address is used to select the line in the cache that may contain the address; another subset of the bits is used to select the byte within a cache line to which the address points. Set associative caches are a compromise between fully associative caches and direct-mapped caches. In a set associative cache, there are a fixed number of locations (referred to as “sets”) in which a given address may be stored. The number of such locations defines the associativity of the cache.

Likewise, caches can be classified into the following four categories:
(i) physically indexed, physically tagged;
(ii) virtually indexed, virtually tagged;
(iii) virtually indexed, physically tagged; and
(iv) physically indexed, virtually tagged.

Although some embodiments of a cache will be described herein in the context of physically indexed, physically tagged directories for economy and clarity of description, it is to be appreciated that the structure highlighted by the cache embodiments shown and described herein can be more broadly applied to all four categories of cache, as well as other memory systems, as will become apparent to those skilled in the art given the teachings herein. Additionally, with regards to RAM, arrays, and CAM, it is assumed that the timing of signals driving read row lines (RRLs) may be selectively adjusted such that the “far” RRL receives the earliest input and the “near” RRL receives the latest input. A staggering of this kind can assure that regardless of the RRL selected, the data will arrive with an identical (or nearly identical) latency to the corresponding output of a memory array (RAM); that is, the latency of the requested data will be essentially constant regardless of where in the memory array the data resides, according to embodiments of the inventive concept.

For a CAM application, the additional delay may be added to bits of a virtual or logical address being compared and is not explicitly noted in the lookup path schematics. For a RAM, a decoder included in the RAM can be configured to add additional latency to each successive input RRL select signal in moving from a far RRL to a near RRL, with the farthest RRL receiving the least (or no) additional latency, and the nearest RRL receiving the most additional latency, according to aspects of the inventive concept.

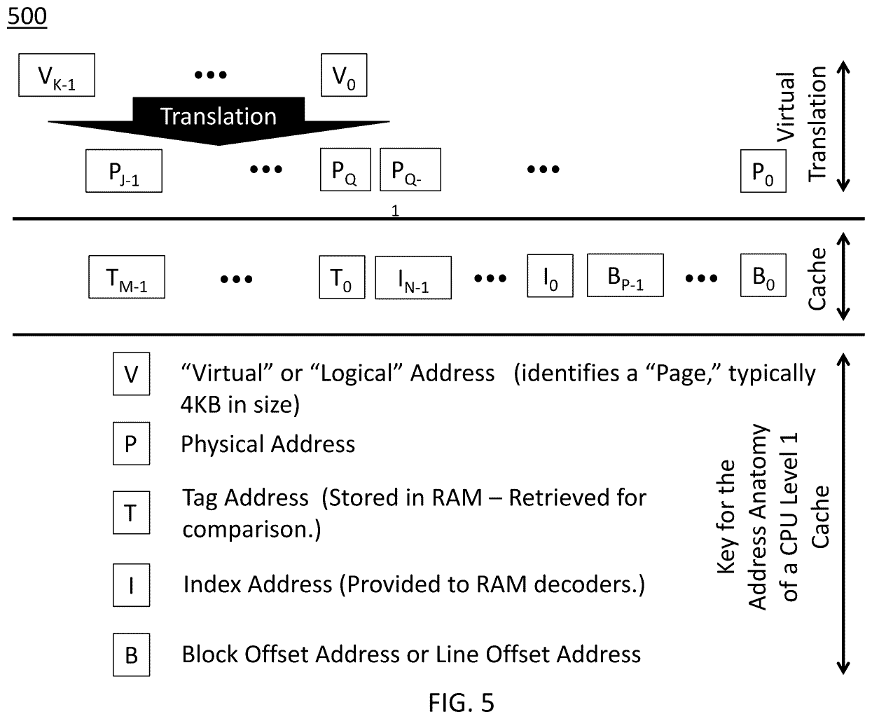

FIG. 5 is a block diagram conceptually depicting an exemplary address anatomy (where P_{Q-1} aligns with I_{N-1}) for a level 1 cache, which serves to define different addresses at work within a level 1 cache. With reference to FIG. 5, the first and second rows of bits indicate a translation from a virtual (i.e., logical) address (V₀ to V_{K-1}) to a physical address (P₀ to P_{J-1}) associated with main memory.

The operating system oversees virtual-to-physical address translations as files are moved from slower storage to much higher speed main memory for processing. Virtual addresses, or logical addresses, can be spawned by various processes initiated by code/computations being executed by Boolean processors and potentially quantum processors in the future. In all or most of the exemplary embodiments of lookup paths for caches according to aspects of the present inventive concept, a virtual-to-physical address translator, often referred to as a translation lookaside buffer (TLB), may be incorporated into the lookup path schematic.

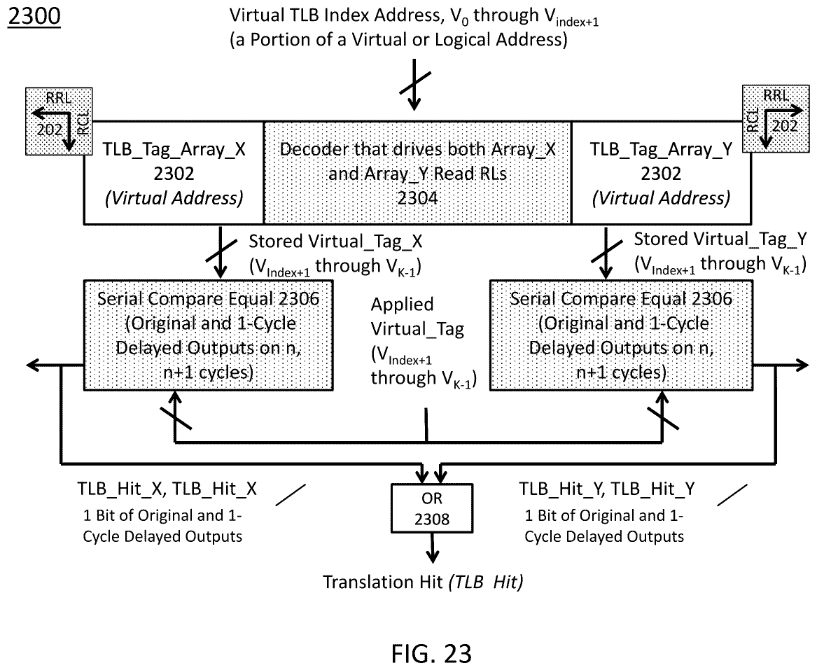

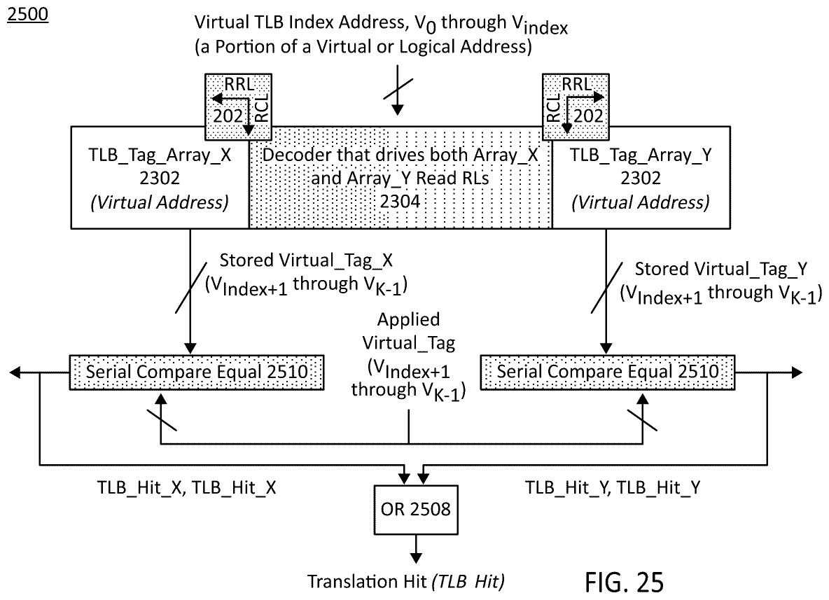

In practice, physical addresses can be necessary for a processor to communicate with higher-level memories (e.g., level 2 cache, level 3 cache, main memory, etc.) that preferably operate with physical addresses, and through those higher-level memories to other processors. Therefore, address translators, where virtual address bits are transformed into higher-order physical address bits (P_{J-1} through P_{Q}) are often an integral part of an address lookup path in a first level cache system. A virtual address presented to such a system can thus be represented as follows:
V_{K-1}*************V_{Index}**********V₀, P_{Q-1}***********P₀
   (Note that V_{Index} is included in this address definition to help define the index address range of the TLB virtual tag array of FIGS. 23 and 25.)

A virtual address may get translated to the following physical address, which is almost always smaller in extent/size:
P_{J-1}************P_{Q}, P_{Q-1}***********P₀ (little endian addressing convention)

For all or some lookup path embodiments, it is important to note the boundary between where the virtual bits end (V₀ and P_{Q}) and where the overall address (also called a virtual address, terms being contextual), which does not vary under translation, begins (P_{Q-1}). This boundary defines the “page” size, which is typically 4 KB, but can be as large as 1 MB or 2 GB, although embodiments of the inventive concept are not limited to any specific page size. Some cache implementations may require simultaneous support of multiple page sizes. The page size can determine the permissible upper limits of the directory, in terms of size, for what is known as a physically tagged, physically indexed cache-one of the simplest caches to design given the absence of “synonyms.”

With continued reference to FIG. 5, a set-associative directory principally stores tag bits, T₀ through T_{M-1}, and is addressed by index bits, I₀ through I_{N-1}, where N and M are integers. The index bits do not vary under translation and thus can be used to perform a table lookup of at least one specific set of tag bits (T₀ through T_{M-1}). Together, the directory index address bits along with the at least one set of tag bits can help identify a line of data stored in the cache. In an N-way set associative cache, a line of data can be stored in any of N locations in the cache.

A block offset address, B₀ through B_{P-1}, a line offset address, points to data to be fetched or stored within a cache line. To boost hit rates (i.e., the likelihood that the cache holds the data of interest), spatial related data having proximate addresses to the requested data may be moved as part of the line to and from higher levels of memory.

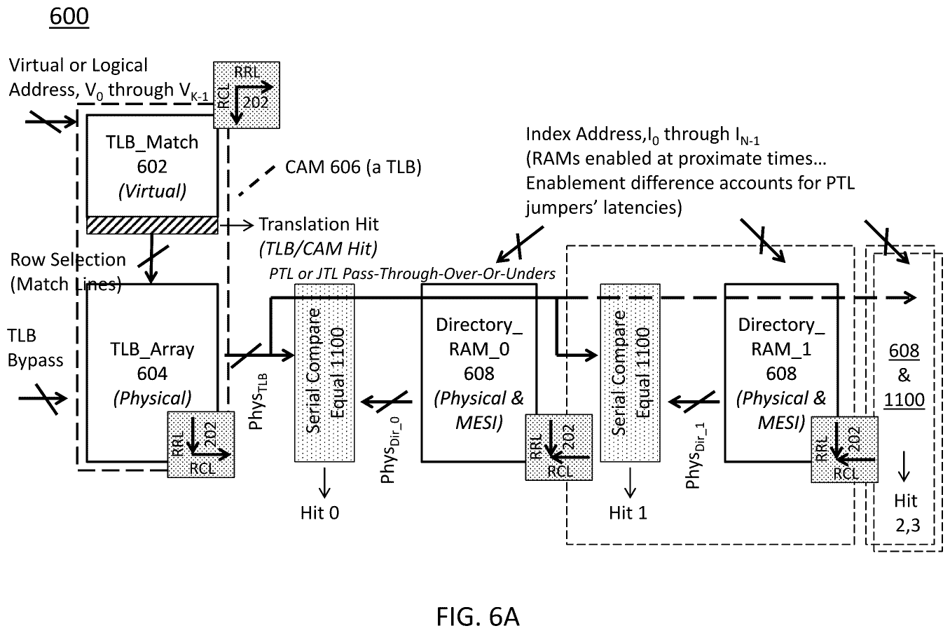

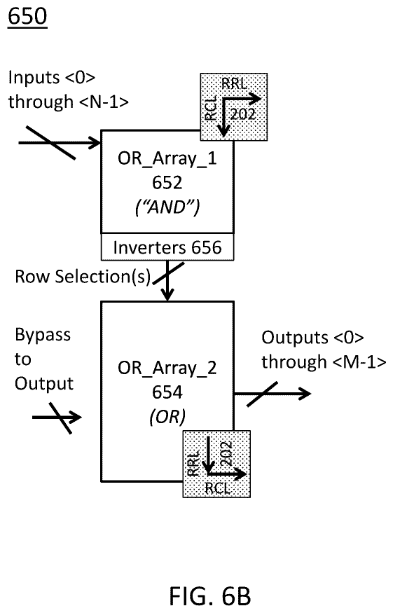

FIG. 6A is a block diagram depicting at least a portion of an exemplary lookup path 600 for a four-way set associate cache, with a fully associative TLB (CAM-based), according to one or more embodiments. Specifically, FIG. 6A shows an illustrative flow diagram and schematic of a lookup path 600 for a four-way set associative cache, which is configured, in part, to implement virtual (i.e., logical) to physical address translations. A superconducting set associative lookup path in this illustrative embodiment may implement a physically-indexed and physically-tagged directory.

Complementary metal-oxide semiconductor (CMOS) designers trying to gauge the complexity of RQL memory circuit timing integration, for example, should assess the timing diagrams depicted in FIGS. 3A, 3B, and 3C. This timing complexity does not currently exist in CMOS designs. Within one or more embodiments of the inventive concept, timing may be managed through a physically and logically oriented confluence of timing signals spanning multiple cycles (and fractional cycles known as phases).

Before discussing timing alignment, it is important to recognize that the exemplary embodiment of a lookup path 600 for a cache depicted in FIG. 6A may have certain disadvantages, which may be addressed by other embodiments described herein. Such disadvantages may include, for example: (i) too much latency in the virtual address translation path passing through the translation lookaside buffer (the TLB is implemented as a CAM 606); (ii) too many metal/wiring layers over the directory RAMs 608; and (iii) lower bandwidth. A discussion of the first embodiment, however, illuminates memory design opportunities (such as those for RAMs, CAMs, and PLAs) and teaches how to visualize information flow within RQL/SFQ memories and at their outputs.

As will be known by those skilled in the art, the lookup path of a modern level 1 cache in a microprocessor with virtual memory may include a TLB, which is a cache itself and which performs the virtual to physical address translation. The content addressable memory (CAM) 606, which serves as a TLB in the lookup path 600 of FIG. 6A, may be formed by the combination of the TLB_Match 602 and TLB_Array 604, which store virtual and physical addresses, respectively. FIG. 6A further includes: (i) a four-way set associate directory, physically divided into four regions—directory_RAM_0 608 through directory_RAM_3 608—that indicates if and where requested data are stored within the data RAM of the level 1 cache; and (ii) a “serial compare equal” circuit 1100 for assuring that the caches and main memory hold the appropriate page of file system data. (The data stored in main memory is typically managed by an operating system.)

The lookup path for an N-way set associative cache (shown in FIG. 6A as a four-way set associative cache, easily modified to be N-way, where N is an integer greater than 1) may include at least one TLB_Match 602 (TLB CAM holding virtual/logical addresses), at least one TLB Array 604 (TLB RAM holding physical addresses), at least one serial compare equal circuit 1100 (which evaluates over a plurality of RQL cycles), and at least one Directory_RAM 608 (containing the physical address bits and cache management bits, such as MESI, standing for modified, exclusive, shared, and invalidated). All components may be accessed in sequential data flow order from the application of a virtual address and index address to the generation of one or more hit results (e.g., Hit 0, 1, 2, and 3).

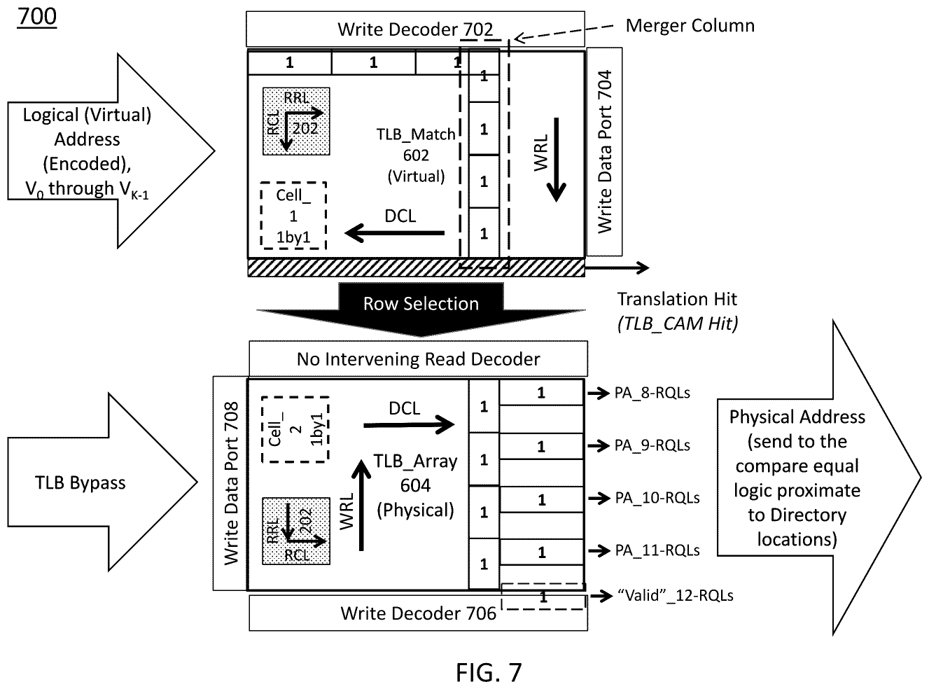

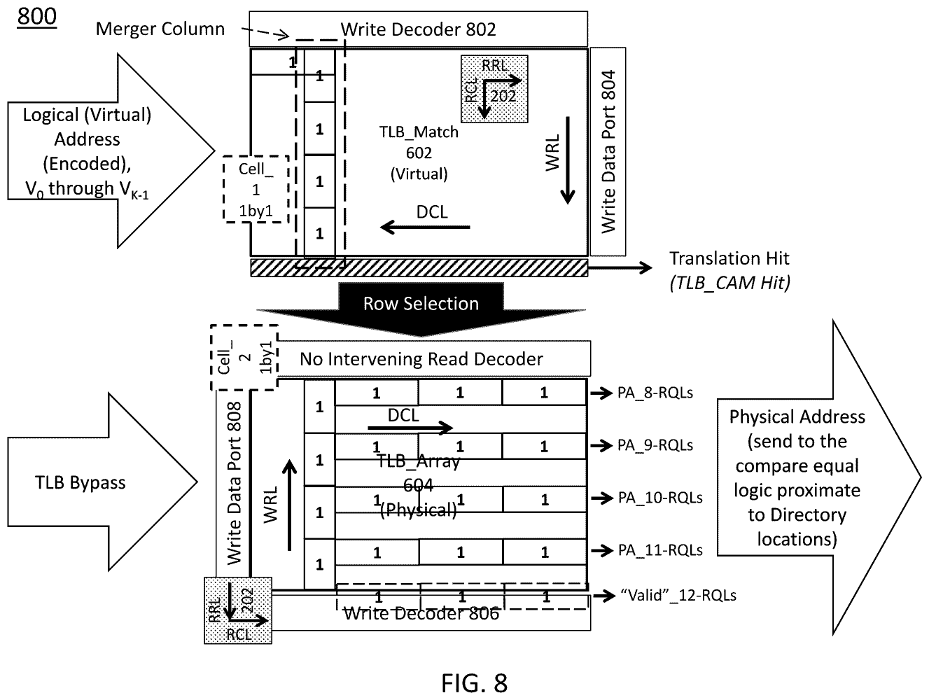

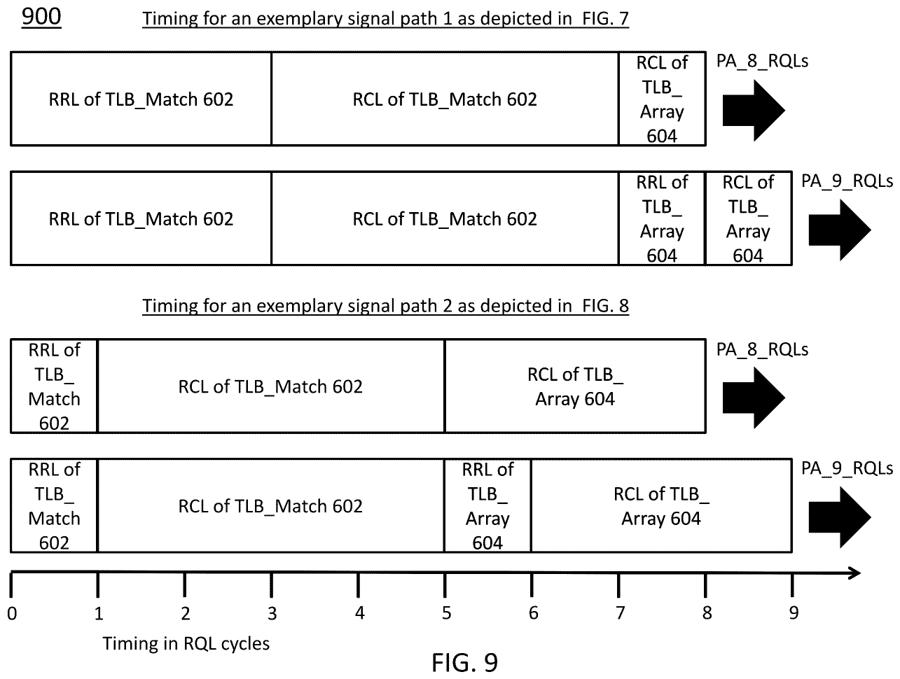

In one or more embodiments, wave pipelining in logic may be implemented to avoid the use of intermediate latches or registers, which is especially advantageous in a superconducting environment given that latches are extremely costly in terms of physical real estate. The signals associated with the virtual address request moves through the TLB_Match 602 and then the TLB_Array 604 substantially concurrently with respect to the wave associated with the index address request moving through directory RAMs 608. The outputs of TLB_Array 604 and directory RAM(s) 608 both converge on the serial compare equal circuit(s) 1100 over a range of RQL/SFQ cycles and phases, processing a physical compare in bit by bit timing order associated with TLB_Array 604 and directory 608 output bit timing. (These are timing matched, as will be seen in the exemplary FIGS. 7 (and 8) and 10, both having proximate/almost identical timing in a given physical pitch allocated to each bit mismatch circuit of the serial compare equal circuit, an XOR.) The outputs propagate an intermediate mismatch onward, combining it with the next bit mismatch result until the full tag comparison (physical address bits) is complete and then other control bits can be processed/merged (e.g., a “valid” bit, which indicates a line is valid) and hit result(s) generated.

In a conventional CMOS design, all output signals emerge from a single RAM on the same or, at most, a few subsequent cycles of its access. Compares are generally completed in less than a single cycle, and intermediate results are not processed in a bit-by-bit fashion, but in a parallel fashion, where bit mismatches feed wide ORs, having substantially similar timing inputs/requirements (i.e., as measured by the latency from input to output of the wide OR). In other words, memory/array outputs arrive at the XORs of the comparator circuit on the same cycle.

To reiterate the functional and timing activity, associated with the first cache embodiment, the serial compare equal circuit receives phase and cycle shifted address bits (e.g., physical address bits in our example of physically tagged, physically indexed caches), retrieved from the at least one TLB_Array 604 and the at least one Directory_RAM 608. These addresses may be compared to determine whether they are equal. A true hit signal, one of N different hit signals associated with N different sets, preferably indicates that a data cache (not formally part of the lookup path) stores the requested line of interest and specifies a particular way/set (e.g., 0, 1, 2, or 3) of N ways/sets that contains the requested line. If all hit signals are false, a miss to the data cache is recognized; that is, the data cache does not contain the line requested.

To reduce wiring congestion, the read path data flows of the TLB_Array 604 and directory RAM 608 may be configured to be mirror images of one another (i.e., 180 degrees rotation) as indicated by the orientation indicators 202 associated with each memory array. Furthermore, the read path circuitry associated with each TLB array can be made perpendicular (see, e.g., FIGS. 7 and 8). As will be explained in the context of a CAM example, TLB_Match 602 and TLB_Array 604 may be pitch matched and timing sequenced (see, e.g., FIGS. 7 and 8) in such a way as to consume minimum circuitry (e.g., arrays and operatively coupling circuitry) and to minimize their latency (as expressed in FIG. 9) and to assure identical latency for any match associated with TLB_Match 602.

Many other elements in a cache design will be considered for their place in an SFQ-based lookup path and how its timing and other resource requirements may impact the overall design. The memory array itself is where some of the most prominent changes from traditional design are expected to occur, with the understanding that the cache design will very likely contain some choices considered unorthodox relative to conventional designs.

Unique to this illustrative lookup path embodiment 600 are the combination of the logical function, circuit physical orientations, and temporal arrangement/organization (made manifest by the expressed phase assignments of the RQL logic and memory cells) described herein for managing the processing of a cache read/fetch, write/store, or other requests/operations through its RQL/SFQ circuits and memory cells (e.g., nondestructive read-out (NDRO)). A wave-pipelined RQL/SFQ-based lookup path can be realized with extremely low latency and low circuit overhead, which maintains in-order processing of requests.

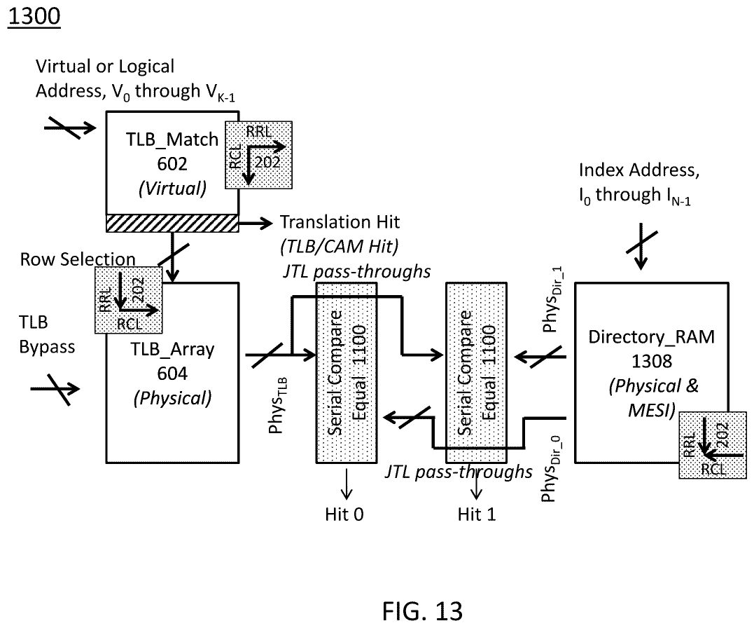

Lookup path 600 features a TLB Bypass input, which will be included in all other alternative lookup path embodiments including those described with respect to FIGS. 13, 14, 16. 17, 24, 26, and 28 Each TLB bypass bit feeds a read column line usually employed to transfer state from a memory cell to an output of its associated memory (e.g., Phys_{TLB} bit). Such a bypass may also be enabled in a serial AND-OR arrays circuit of FIG. 6B. In that context, it is called “Bypass to Output.”

It should be recognized that the same underlying logic, timing constraints (allotments) for its memory cells, and physical structure, associated with CAM 606, can be used to form a generalized Boolean logic function comprising two serial PLAs, one serving as an AND plane (using a Boolean inversion transformation of an OR-based column), the other serving as an OR plane, or to form a CAM. With reference to FIGS. 7, 8, and 9, a detailed description of signal flow and timing enabled by the embodiments of the physical structure for the CAM (and also the serial PLAs, collectively referred to herein as SFQ serial AND-OR arrays circuit) will be given.

The match array (e.g., TLB Match 602) of the CAM (e.g., TLB CAM 606) may store true and complement bits of each address bit along columns. The CAM 606 may receive true and complement row signals, address bits (virtual or logical address, V, for the TLB_Match of FIG. 7), at a periphery of the match array. Less restrictive than a CAM match array, a PLA can retain any desired state in its memory cells that form its AND (OR) plane logic. Like a CAM match array, however, the data path of the PLA can include, for a restricted case, bit pairs having both a true version of a first bit and a complement version of the first bit. Unlike a CAM, inverters are disposed between memory arrays to realize a requisite Boolean transformation, as explained subsequently.

FIG. 6B is a block diagram depicting at least a portion of an exemplary SFQ (or RQL) serial AND-OR arrays circuit 650, which may be configured to support any Boolean function, according to one or more embodiments of the invention. The SFQ serial AND-OR arrays circuit 650 may include a first OR array 652, having first memory cells with a timing allotment T along their read row line and read column line dimensions, a second OR array 654, having second memory cells with a timing allotment, T, along their read row line and read column line dimensions substantially similar to those of the first memory cells (also T), inverters 656, inputs <0> through <N−1>, where N is a positive integer, and outputs <0> through <M−1>, where M is a positive integer, wherein the inputs <0> through <N−1> feed inputs of the first OR array 652, outputs of the first OR array 652 feed inputs of the inverters 656 (transforming OR signals into AND signals), outputs of inverters 656 feed inputs of the second OR array 654, and outputs of the second OR array 654 feed outputs <0> through <M−1>.

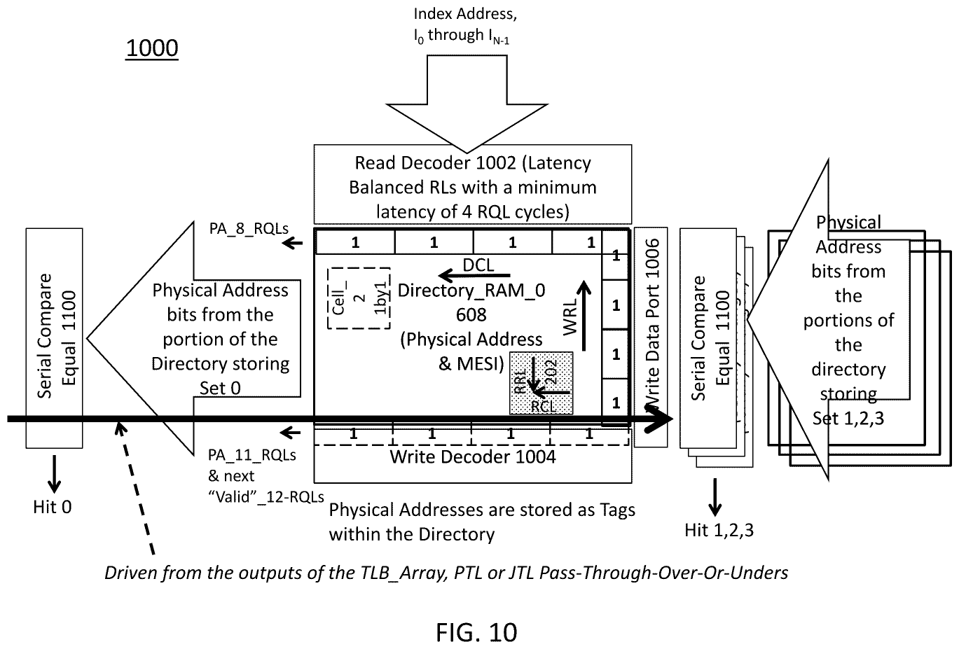

FIG. 7 conceptually depicts a more detailed illustration of the exemplary TLB 700 (CAM TLB 606) in the lookup path of a four-way set associative cache according to one or more embodiments, which defines required, read and write line orientations and flow directions (i.e., RRL, read column line (RCL), write row line (WRL), and data column line (DCL)) within its internal memories (i.e., TLB_Match 602 and TLB_Array 604) and relative to the directory RAM(s) 608 (as represented by FIG. 10). Other noteworthy details of the exemplary TLB 700 shown in FIG. 7 may include one or more of the following:
(i) TLB_Match 602 and TLB_Array 604 relative locations and orientations (read lines being designated by the orientation indicators 202 within each array 602,604);
(ii) the virtual address input bus (which may be encoded);
(iii) different memory cells—cell_1 and cell_2—both with exemplary aspect ratios (e.g., 1 by 1), but different internal relative read and write orientations;
(iv) superimposed “1”-RQL cycle boxes (which delineate time-of-flight spatially, as subsequently explained);
(v) a preferred location of the write decoder 702 of the TLB_Match 602;
(vi) a preferred location of the write data port 704 of the TLB_Match 602;
(vii) a translation hit detection logic (i.e., a TLB_Match Hit . . . );
(viii) a preferred location of a write decoder 706 of the TLB_Array 604;
(ix) a preferred location of the write data port 708 of the TLB_Array 604; and
(x) physical address outputs (e.g., PA_8-RQLs through PA_12-RQLs).

It is important to note for the lookup control logic that the translation hit logic may be a serially arranged OR of the TLB_Match outputs, and that the relative positioning of the write data ports and RCL outputs can impact the relative timing of cache fetches as compared to their stores. Memory locations in the TLB may require updating before the next translation can be processed.

With the general direction of data flow for the lookup path 600 through the TLB_Match 602 and TLB_Array 604, indicated by orientation indicators 202, relative orientations between the TLB_Match 602 and TLB_Array 604 may be revealed. In one or more embodiments, the RRL of the TLB_Match 602 may be rotated 90 degrees clockwise with respect to that of the TLB_Array 604. The write lines may be configured according to the requirements of a CAM match circuit (e.g., TLB Match 602) and the requirements of a typical array (e.g., TLB_Array 604. Orientations of the data column lines (DCL) and write row lines (WRL) are indicated on 602,604 of FIG. 7.

Logic functionality may be assured (i) by appropriate timing allocations (with RQL phases) along the RRL and RCL of memory cells and (ii) by any rotation or mirror image of the physical design of these combined orientations of a TLB_Match 602 (or more simply CAM-abstracted for other uses such as a fully associative Directory.) and a TLB_Array 604 (or more simply RAM), both having memory cell circuits allocated to appropriate locations within a RQL phase that are made to be timing consistent across the TLB_Match 602 and TLB_Array 604. The memory cells along the RRL of the TLB_Match 602 occupy the same allocated time as the memory cells along the RCL of TLB_Array 604 interlaced timing interactions (e.g., timing granularity being within an RQL phase) from RCL outputs of the TLB_Match 602, conducted by the operatively connected row selection signals, to the RRL inputs of the TLB_Array 604. Other logical circuits, such as (and their underlying PLAs), fall within the spirit of this broadly speaking “serially-accessed/arranged memories/arrays” embodiment. As will be discussed, these physical orientations, and timing allocations, assure a consistent latency regardless of what column “hits” or misses in a match array (e.g., TLB_Match 602), or regardless of what column generates a “1” or “0” in a PLA (e.g., OR_Array_1 652 or OR_Array_2 654).

By way of example only and without limitation or loss of generality, with continued reference to FIG. 7, overlaid on the TLB_Match 602 and TLB_Array 604 are boxes, labelled with a “1,” that may be used to indicate the spatial propagation of a signal for a time period corresponding to a single RQL cycle, which corresponds to the traversal of 32 memory cells. For better comprehension, it should be noted that only the flight of the RQL/SFQ signal, initiated at the input of the “far” RRL of the TLB_Match 602, is highlighted by the “1” boxes. That signal can still be viewed as generating multiple outputs—PA_8-RQLs through PA_12-RQLs. For an exemplary TLB hit, the logical address signal is traced along the “far” RR. It propagates along the far RRL for three RQL cycles, corresponding to a traversal of 96 memory cells, as a positive and negative flux quanta pair (RQL) pair or SFQ. After accessing the 96^{th} memory cell, the signal then propagates for four RQL cycles, corresponding to a traversal of 128 memory cells, down the RCL as the absence of an RQL pair, which represents a “match” or “compare equal” at this location within the TLB_Match 602. The column where this particular logical address assessment is occurring within the TLB_Match 602 is labeled as a “merger column.” The results from all the bit-by-bit matches (actually mismatches) of the applied logical address and stored logical address literally merge, into a single bit, in the merger column. Mergers of bit-by-bit mismatches (or matches) may occur in all RCLs during a set of RQL/SFQ cycles associated with each TLB_Match 602 operation.

Along the merger column, any mismatch would generate an RQL pair that would propagate down the column. In contrast, the signal representing a match can be thought of as an absence of an RQL pair. At the end of the RCL within the TLB_Match 602, the signal is inverted generating an RQL pair, for a match (hit), that is applied to the RRL of the TLB_Array 604, where it is propagated along the RRL for four RQL cycles, enabling memory cells as it passes through them. When a memory cell is selected, its state, which represents a particular physical address bit associated with a matching virtual address in the TLB_Match 602, propagates for an additional one RQL/SFQ cycle (corresponding to a traversal of 32 memory cells) to its designated TLB_Array 604 output. Only one RRL may be active in the TLB Array 604 (which is not true in general for other similar structures such as a grouping of two PLAs). In reaching the first/nearest output, 256 total cells are traversed in this example, and the total number of RQL cycles is eight. The last/farthest TLB path measures a total of 12 RQL cycles, since the wave must traverse the RRL of the TLB_Array 604, which adds four RQL/SFQ cycles to the overall latency. It can be shown that the latency through the TLB is invariant regardless of which RCL (e.g., nearest or farthest) matches at the merger column in the TLB_Match 602, due to the memory cell timing allotment “T” of FIG. 2 and the RCL output, and RRL input, interfaces.

To form a signal that indicates a mismatch, but subsequently is inverted to form a match, in the comparison with the associated stored logical address bits, moving down the column of memory cells in the TLB_Match 602, each two memory cells representing one bit, logic address bits associated with near RRLs (in relation to the TLB_Match 602 outputs) may be applied at the input of the near RRLs later in time than those logic address bits applied at the input of the far RRLs to satisfy timing requirements for signal convergence. Thus, the algebraic merger of logical bit-by-bit comparisons propagates along what is labelled the merger column as an RQL pulse pair (representing a logic “1”) or the absence of such a pair (representing a logic “0”), evolving as it moves from the top of the TLB_Match 602 to a bottom thereof. Any evolution in value is from a logic “0” or “1” to a logic “1,” given the OR logic functionality (of the exemplary memory cell shown in FIG. 1) that is inherent in the RCL. What is shown as it relates to the “1” boxes in the TLB_Match 602 is only the far RRL signal progress of a logical bit associated with the far RRL.

In the TLB_Array, an RQL signal divergence may occur, and a set of unique paths through the TLB_Array, along with their corresponding outputs PA_8-RQLs through PA_12-RQLs, are depicted, primarily because they factor into the timing, and thus the structure, of the serial compare equal 1100 described in relation to FIGS. 6, 7 and 10. The serial compare equal circuit 1100 may follow the TLB_Array 604 in terms of signal flow. An embodiment of the serial compare equal circuit 1100 will be described in detail with respect to FIG. 11, according to aspects of the inventive concept. Shown emerging from the illustrative TLB_Array 604 of FIG. 7 are cycle-bundled physical addresses appearing as PA_8-RQLs through PA_12-RQLs.

Concerning the nomenclature, the term “PA_8-RQLs” as used herein refers to a set of physical address outputs with an approximate latency of eight RQL cycles (i.e., the delay of signals within a range from exactly eight RQL cycles to just under nine RQL cycles, where the set may include a fractional cycle known as a phase.). The latency recorded in the signal names is merely representative of the combined latencies of the TLB_Match 602 and TLB_Array 604; it does not include the additional latency in both feeding and passing through “Translation Hit” logic which may be included in the lookup signal path.

FIG. 8 conceptually depicts a detailed illustration of the exemplary TLB in the lookup path of a four-way set associative cache, according to one or more embodiments. The exemplary TLB shown in FIG. 8 may be functionally and physically similar to that shown in FIG. 7, with one difference being that a timing “path 1” is superimposed on FIG. 7, and a timing “path 2” is superimposed on FIG. 8, which together will be discussed with respect to the illustrative timing diagram of FIG. 9. Here again, each of the boxes labeled “1” represents the spatial traversal of a signal over one RQL/SFQ cycle.

FIG. 9 is an illustrative timing diagram that conceptually summarizes component latencies of the TLB pipeline for different exemplary translations paths (e.g., paths 1 and 2 of FIGS. 7 and 8, respectively), according to one or more embodiments of the inventive concept. While the latencies of the component delays for two different paths may be different—the RRL measures three RQL cycles for path 1 while the RRL measures one RQL cycle for path 2—the overall latency is invariant for any path through the TLB and measures eight RQL cycles for the PA_8-RQLs output. This ability for the latency to remain essentially unchanged regardless of the signal path through the TLB is due at least in part to the physically orthogonal nature of the signal flow across memory cells in which both its read row circuitry (RRL) and read column circuitry (RCL) are allocated within each RQL phase an identical maximum latency equal to, or below, which both circuits operate.

In general, a deliberate skewing of RRL inputs to an RQL memory array in accordance with intrinsic column line latencies, while assuring row operation independence (i.e., no collisions of RQL pulses for different read operations/waves directed to the memory array), introduces an overall latency adder of a full column delay no matter what RRL is selected in the array. Such skewing of latencies should be applied to the logical address, additional latencies ranging from zero RQL cycles (i.e., no latency) for the farthest RRL, to four RQL cycles for the nearest read row line. If the aforementioned skewing is implemented on the logical address, regardless of the path through the TLB_Match 602 and TLB_Array 604, then all path delays will total, at any particular output (e.g., PA_8-RQLs), to the same value as depicted in FIG. 9.

It is to be understood that discrete latencies associated with each memory cell may not be accurately represented in FIG. 9. These illustrative diagrams are merely intended to represent a granularity of 32 memory cells associated with each RQL cycle. For example, the eighth RQL cycle completes at the TLB_Match 604 output. Therefore, the latency in reaching the PA_8-RQLs output from the logical address input of the TLB is the sum of eight RQL cycles and an additional memory cell delay (e.g., 1/32 of a cycle, using a granularity of 32 memory cells).

Furthermore, it is important to note that the physical address outputs arrive one after the other feeding the serial compare equal circuit 1100, which will described in more detail with respect to FIG. 11. Instantiations of the serial compare equal circuit 1100 appear in FIG. 6A and FIG. 10, to be described subsequently.

FIG. 10 is a block diagram conceptually depicting a more detailed illustration of the exemplary directory RAM 608 and serial compare equal circuits 1100 of the lookup path 600 of a four-way set associative cache shown in FIG. 6A, according to one or more embodiments. FIG. 10 defines required read and write line orientations and flow directions (i.e., RRL, RCL, write row line (WRL), and data column line (DCL)), relative to the exemplary TLB_Match 602 and TLB_Array 604 shown in FIG. 7. Note, in particular, the orientation indicator 202. It is to be appreciated that, unlike for CMOS interconnections, the interconnections between functional blocks shown in FIG. 10 (e.g., JTLs or JTLs and OR gates) may be directional.

Other noteworthy details of the directory RAM 608 shown in FIG. 10 may include one or more of the following:
(i) directory RAMs 608 and serial compare equal circuit 1100 relative locations and orientations (note orientation indicator 602);
(ii) highlighted internal circuit paths of physical address bits moving from the directory(ies) 608 to the serial compare equal circuit(s) 1100;
(iii) memory cell 2 with exemplary aspect ratio (e.g., 1 by 1) has the same footprint/aspect ratio as memory cell 1 shown in FIG. 7 (e.g., 1 by 1). One difference between the memory cells 1 and 2 may be their read and write port orientations, reflected by read and write column line relative orientation differences between the two arrays (TLB_Match 602 and Directory_RAM 608);
(iv) superimposed “1”-RQL cycle boxes, which delineate time-of-flight for signals within the directory (ies) 608;
(v) a preferred location of the write decoder 1004 of the directory RAM 608;
(vi) a preferred location of the write data port 1006 of the directory RAM 608;
(vii) a preferred location of the read decoder 1002 of the directory RAM 608 (Directory RAM 608 has, for this example only, a deliberately inserted four RQL cycle delay for the shortest path through the read decoder that enables the “far” RRL. Delay has been added for the purpose of illustrating necessary physical address timing alignment.);
(viii) serial compare equal circuits 1100, which form a core of the hit logic of the lookup path 600 that compare the translated address (i.e., virtual-to-physical translation) to four potential addresses stored in four sets of the directory to ascertain whether the four-way set associative cache stores the line of data requested;
(ix) an exemplary passive transmission line (PTL) or JTL pass-through-over-or-under interconnection, which is intended to represent all PTL or JTL pass-through-over-or-under interconnections; and
(x) hit outputs 0, 1, 2, and 3 that indicate whether or not the associated sets of the four-way set associative cache store the line of data requested.

In a manner consistent with the illustrative TLB, overlaid on the directory RAM 608 (Directory_RAM) are boxes labeled with a “1,” each of which represents the spatial propagation of a signal for a time period corresponding to a single RQL cycle. For better comprehension, it should be noted that only the flight of RQL signal, initiated at the input of the “far” RRL of the directory RAM 608, is highlighted by the “1” boxes in the FIG. 10. That “far” RRL activation signal generates multiple outputs-PA_8-RQLs through PA_12-RQLs. For this example and without limitation, where the array sizes have been fixed at 128 rows by 128 columns, a four RQL cycle delay has been added to the read decoder of the directory RAM to balance (i.e., equate) latencies through the translation (i.e., TLB) and directory paths such that their physical address bits concurrently converge on the serial compare equal circuit 1100.

A real sizing for a superconducting cache can be helpful for bounding actual directory RAM 608 sizes. If the data RAM 408 of FIG. 4 (not shown in FIG. 6A, which describes lookup) is four-way set associative, and its line size is 32 bytes, and its capacity is 16K bytes (chosen to avoid “synonyms”), the directory RAM 608 may be addressed with seven bits (the directory RAM 608 being 128 bits deep). Perhaps a more reasonable two-way TLB would be addressed with seven bits (TLB_RAM being 128 bits deep). (Note, that in this illustrative example of FIGS. 6 and 7, the TLB was fully associative.) Depending on the number of TLB entries necessary to assure a high “hit” rate on virtual-to-physical translations, it may not be clear how the TLB_Array 604 and directory RAM 608 depths would compare to each other.

Increasing the number of ways/sets reduces the required directory RAM 608 depth. Thus, increasing associativity may appear to provide a significant decrease in overall latency of the directory RAM, due at least in part to the reduction in RAM depth. However, this simple conclusion overlooks the extension of the RRL of the directory RAM 608 necessary to contain the tag bits of each way/set, should the directory RAM 608 not be able to be broken into four separate directory RAM 608 instances corresponding to the four separate ways, as was done in FIG. 6A.

Specifically, as previously discussed for the four discrete directory instances, the problem manifests itself in the delivery of the TLB tag bits to the remote ways/sets of each Directory instance via PTL-or-JTL-pass-through-over-or-under interconnections, which may significantly impact yield (e.g., due to additional levels of wiring) and performance (e.g., restricted cycle time of multiple flux quanta (MFQ) PTL circuits). Multiple flux quanta cannot be generated quickly enough to support the native bandwidth of RQL/SFQ memory and logic. While revealing (i) a CAM circuit 606 embodiment of FIG. 6A, which manages timing between TLB_Match 602 and TLB_Array 604, and (ii) a serial compare equal circuit 1100, the overarching alternative cache embodiments (and extended row previously described) appear less than satisfactory. One or more embodiments for the lookup path of a cache will be developed subsequently by considering various circuit enhancements to support alternative cache and TLB associativities.

It is important to discuss in detail a yield-detracting circuit issue that may be inherent to the lookup path design 600 shown in FIG. 6A and the associated directory of FIG. 10 that involves the PTL or JTL or pass-through-over-or-under interconnections depicted in FIGS. 6 and 10. Superconducting processes have far fewer layers for signal transmission than semiconductor processes. PTL or JTL or pass-through-over-or-under interconnections convey physical address signals to the serial compare equal circuits 1100, associated with directory RAMs 608 (Directory_RAMs_1, 2, 3). These address signals are logical replicas of the physical address bits of the TLB_Array 604 (e.g., PA_8_RQLs through PA_12_RQLs). They are included in the schematic of FIG. 6A and physical design of FIG. 10, and labeled as such, to make explicit the additional burden of the propagation of signals (in the physical design) through, over, or under the Directory_RAMs_0, 1, 2, 3 608. If such a solution were implemented, it may be simpler than alternatives, conceptually speaking, but come at a great cost including: (i) more layers can be added to a superconducting process that is already burden by yield issues; or (ii) the pass through signal can be included in the area allotted to the memory cell, again a yield issue. These yield-detracting circuit issues (as well as peak bandwidth issues, imposed by a PTL) can be addressed by wave pipelining (e.g., time division multiplexing TDM) embodiments of the present inventive concept, which will be discussed in further detail herein below.

FIG. 11 is a block diagram depicting at least a portion of an exemplary serial compare equal circuit 1100, according to one or more embodiments of the inventive concept. The serial compare equal circuit 1100 may use logic gates to implement three principle internal functions: XOR gates (e.g., formed from an AND-OR gate and an AnotB gate) configured for detecting bit-by-bit mismatches; OR gates for accumulating mismatch results; and an AnotB gate for converting an overall miss signal (i.e., indicating that a mismatch occurred) into a hit signal (i.e., indicating that a match was found). Each spine OR gate, labeled “OR_s,” is configured to merge the latest mismatch result of an XOR gate with all prior mismatch results. Any single bit mismatch causes a miss equal to “1,” or a hit equal to “0,” to be registered by the serial compare equal circuit logic.

More particularly, the serial compare equal circuit 1100 includes a plurality of XOR gates, each XOR gate being configured to receive, as inputs, a pair of a physical address bits from the directory RAM 608 and from the TLB array 604 corresponding to a given RQL cycle and phase. Outputs generated by each of the XOR gates are supplied as an input to a corresponding one of the spine OR gates. An output generated by each of the spine OR gates is supplied as an input to a subsequent adjacent spine OR gate in the string of sequentially-connected spine OR gates.

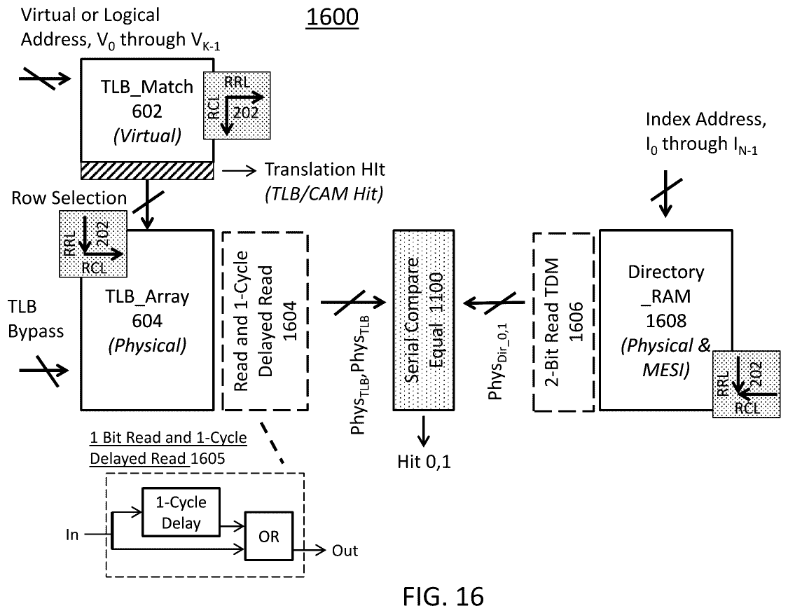

Concerning a timing constraint on the latency of OR_s 1104 for the serial compare equal circuit 1100, which are subtle, it should be understood that they change according to (i) non-TDM, (ii) TDM, and (iii) other non-TDM contexts: Latency of OR_s is (i), for FIG. 6A, which does not exploit TDM in its lookup path, less than or equal to one times the allocated time “T” of each memory cell and is (ii), for FIGS. 13 and 16, which both exploit TDM in their lookup paths, less than or equal to two times the allocated time “T” of each memory cell (ii), for FIG. 13, which both does not exploit TDM in its lookup path, less than or equal to two times the allocated time “T” of each memory cell.

In FIG. 11, the serial compare equal_circuit 1100 may be rotated counter-clockwise by 90 degrees with respect to the TLB array 604 and director RAM 608 of FIG. 6A. Directory RAM input is also shown on the same side as the TLB input. With labels read column line for the TLB array 604 (RCL_TLB), read column line for the directory array 608 (RCL_Dir), read row line of both arrays 604, 608 (RRL_Both), the orientation indicator 1102 expresses both the 90 degree counter-clockwise rotation already mentioned and the prevailing signal flow, all with respect to the arrays 604, 608 as it relates to the serial compare equal circuit 1100. Also noteworthy, for simplicity, JTLs are not shown (as is true for many of the embodiments of the invention).

In the schematic, a particular physical bit address number, its assigned RQL cycle, and its assigned phase are indicated on the TLB and directory inputs to each XOR gate following the convention: PA<particular_physical_bit_address_number>_RQL-Cycles<RQL phase within a cycle>−RQLs. Italicized entries have actual physical numbers assigned in the schematic to relate (to conform) to 128 by 128 memory array sizing being discussed. A final output-“Valid”_12<p0>−RQLs—follows the physical address bits (PAS) in this timing sequence. This timing relationship remains consistent wherever else “Valid” _12<p0>—RQLs (or as “Valid_12-RQLs) has appeared or will appear in schematics (FIGS. 7, 8. 10, 11, 12, and 15).

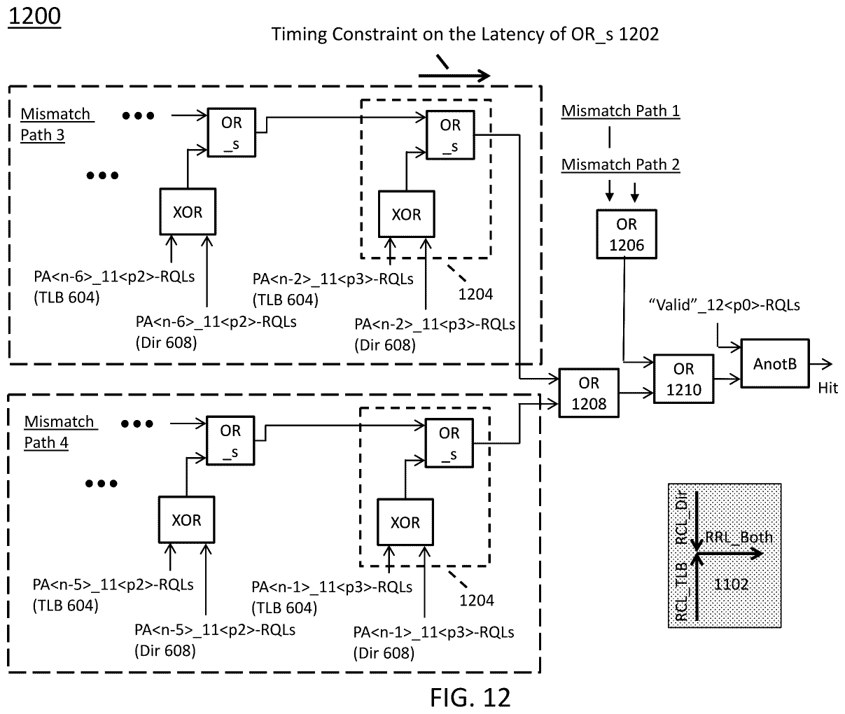

FIG. 12 is a block diagram depicting at least a portion of an exemplary serial compare equal circuit 1200 having increased bandwidth compared to the illustrative serial compare equal circuit 1100 shown in FIG. 11, according to one or more embodiments. Specifically, the exemplary serial compare equal circuit 1200 may provide increased bandwidth due, at least in part, to the mixed parallel and serial logic processing, which is associated with its underlying mismatch-propagate building block enclosed by the dashed box 1204 (i.e., three JTLs, AND-OR, AnotB, and OR_s gates, where a series connected AND-OR gate and AnotB gate implement an XOR functionality). Similar to the embodiment shown in FIG. 11, the serial compare equal circuit 1200 may use the following logic gates to implement the noted internal functions: (i) XOR gates for detecting bit-by-bit mismatches; (ii) OR gates for summing/collecting mismatch results; and (iii) an AnotB gate for converting an overall miss signal into a hit signal.

With reference to FIG. 12, each spine OR (“OR_s”) in the serial compare equal circuit 1200 may be configured to merge a mismatch result from a corresponding XOR gate with all prior mismatch results. The serial compare equal 1200 circuit includes four parallel mismatch paths, 1 through 4, which would be identical, as illustrated in FIG. 12, except for possible 1-RQL cycle shifts (occurring from phase 3 to phase 1), any single phase shift, and within phase locations of their circuits. This final point may not be expressed by the schematic, and thus is not shown in the schematic, but settings would rather result from a timing assessment of an actual design. In one or more embodiments, the three OR gates 1206,1208, 1210, which are fed by the four mismatch paths 1 through 4, are configured to merge the separate path results into a single mismatch result for the entire physical address fields associated with the tag addresses of the directory and TLB. Any single-bit mismatch anywhere along a single mismatch path will generate a miss signal equal to “1,” or a hit signal equal to “0,” to be registered by the serial compare equal logic.

A critical point in terms of timing relaxation is that the serial compare equal circuit 1200 has four times fewer stages in the spines of its parallel mismatch paths 1 through 4 than the serial compare equal circuit 1100 has along its single spine. Hence, four times more latency can be allocated to each stage as noted on the schematic 1200. A key design rule—timing constraint on the latency of ORs 1202—may be that the latency of all spine ORs (OR_s) cannot exceed four times the allocated time “T” of each memory cell.

While the illustrative embodiment shown in FIG. 12 can be referred to as serial compare equal circuit given the nature of how it merges timing-sequenced physical address bit comparisons, it may also be referred to as a parallel-serial compare equal circuit since it includes both parallel and serial ORing components. In this example, the internal circuit (three JTLs, AND-OR, AnotB, and OR_s gates), may be configured with four times as much intrinsic RQL phase latency than that of the memory cells. A minimum phase latency of the memory arrays can be deduced, for example, from Burnett 2018 because a phase contains at least 8 OR gates and 8 JTLs.

FIG. 13 is a flow diagram and schematic conceptually depicting at least a portion of an exemplary lookup path 1300 for a two-way set associative cache, which implements virtual to physical address translation, with a fully associative TLB (CAM-based), according to one or more embodiments. This lookup path 1300 may be configured to implement what is known in the art as a physically indexed and physically tagged directory. While more than one logical feature of this exemplary embodiment has been noted, it is to be appreciated that embodiments of the invention are not limited thereto.

The lookup path for an N-way set associative cache (shown in FIG. 13 as a two-way set associative cache) may include a TLB_Match 602 (e.g., translation look aside buffer content addressable memory), a TLB Array 604 (Physical) (translation look aside buffer array holding physical addresses), a plurality of serial compare equal circuits 1100 (e.g., where the plurality is practically constrained here to two due to the memory cell dimensions associated with pitch matching between TLB_Array and Directory_RAM), and a Directory_RAM 1308 (Physical and MESI), wherein, upon access, the Directory_RAM 1308 generates physical addresses corresponding to two different Tags—Phys_{Dir_0}, Phys_{Dir_1},—for application separately to the two serial compare equal circuits 1100, and wherein the TLB_Array 604 produces one set of high-order physical address bits—Phy_{STLB_Array}—for application to both serial compare equal circuits 1100. Hits/misses can be resolved for the physical addresses using techniques known in the art and as previously explained.

Important to this two-way set associative cache is that the Directory_RAM 1308 holds the tags and MESI corresponding to ways/sets 0 and 1. Given that the directory 1308 is two-way (i.e., two tag entries) while the fully associative TLB has only one tag entry, a pitch-matched width of the memory cells of the Directory_RAM 1308 (as measured along their RRL) may be half that of the memory cells of the TLB_Array 604 (also as measured along their RRL). Also, the latency allocated to each mismatch stage of the compare equal circuit 1100 may be twice that allocated to each memory cell of the directory RAM 1308.

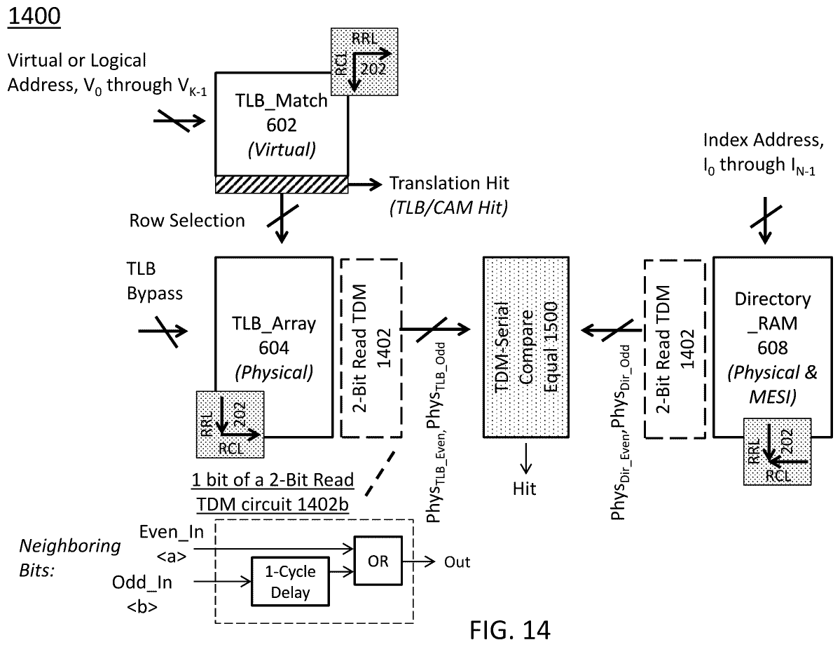

FIG. 14 is a flow diagram and schematic depicting at least a portion of an exemplary lookup path 1400 for a direct-mapped cache, which implements virtual to physical address translation, with a fully associative TLB (CAM-based), according to one or more embodiments. Like the illustrative lookup path 1300 of FIG. 13, the lookup path 1400 shown in FIG. 14 may be configured to implement a physically indexed and physically tagged directory. While more than one logical feature of this exemplary embodiment has been noted, it is to be understood that embodiments of the present invention are not limited thereto. Unique to this embodiment is the use of time division multiplexing (TDM) for relaxing pitch constraints imposed on the serial compare equal circuit. Advantageously, the height allotted to the combination of a bit-by-bit mis-compare (i.e., XOR) and a propagate (i.e., OR) element within this TDM circuit 1500, referred to as a TDM-serial compare equal circuit 1500, may be twice that of the serial compare equal circuit 1100 of FIG. 11.

A consequence of the column-oriented TDM implemented in this design is that the lookup path operational bandwidth may be reduced by a factor of two. The “2-bit Read TDM” (column-oriented TDM) circuit 1402 may provide half the physical address width on each of its two associated cycles. A 2× timing relief in the “OR spine” of each TDM-serial compare equal circuit can be realized because only half the number of comparisons are performed per cycle. Broadly speaking, such a timing relief can be necessary for matching memories, with fast per-memory cell latencies (noted as timing allotments “T” earlier), to logic with slower stage delays (which, with more time allocated, can incorporate more function).

It is important to note in the lookup path 1400 that physical even (cycle 1) and physical odd (cycle 2) address bits converge upon the TDM serial compare equal 1500. Phy_{STLB_Even}, Phy_{STLB_Odd} and Phys_{Dir_Even}, Phys_{Dir_Odd} signals are sourced to the TDM serial compare equal circuit 1500, indirectly by the TLB array 604 and directory RAM 608, respectively, through the “2-bit Read TDM” (column-oriented TDM) circuit 1402.

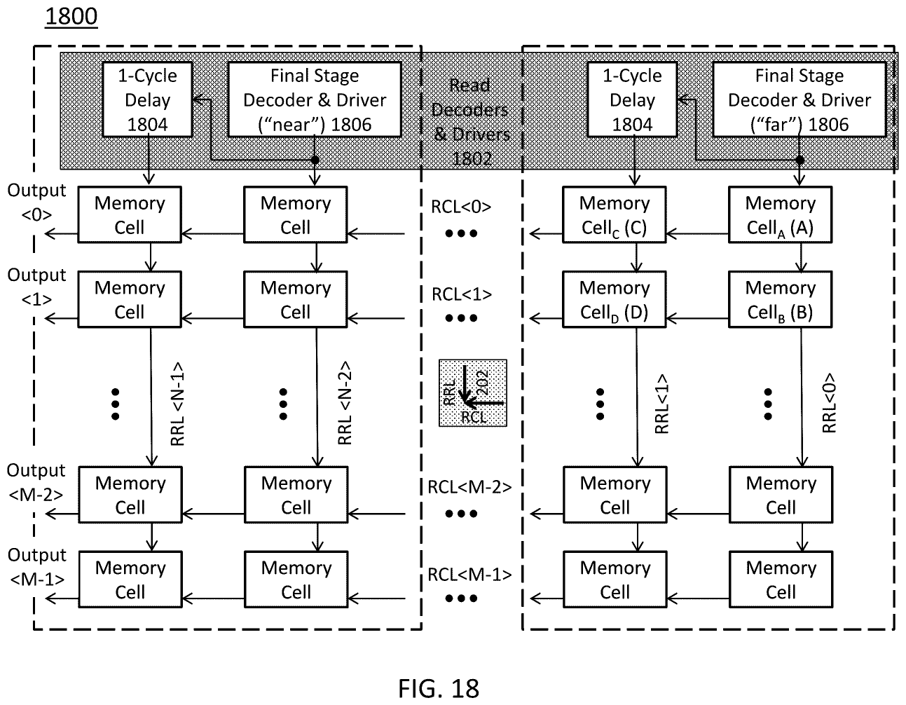

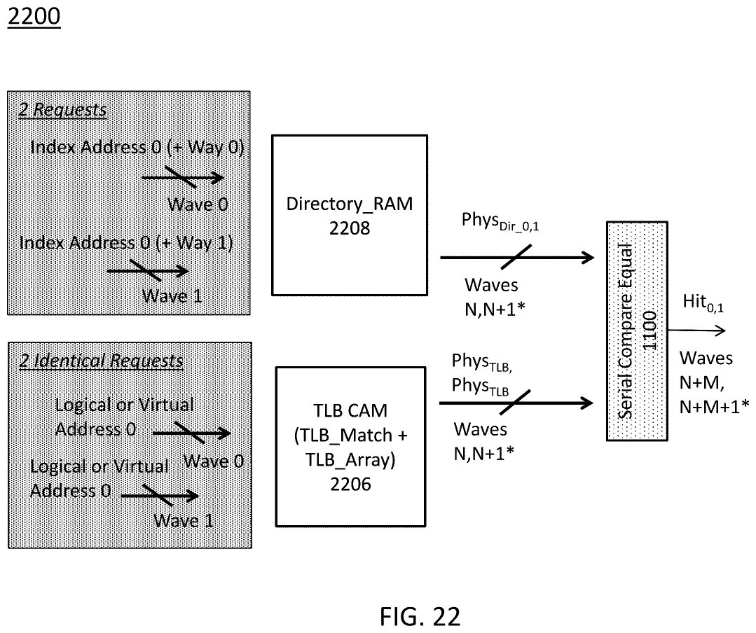

Prudent use of TDM, like the column oriented TDM exploited in the lookup path 1400, can offer many advantages, including, among other benefits: (i) energy savings; (ii) physical pitch matching (i.e., a better aspect ratio for a logic cell pitch matched to memory cell(s)); (iii) timing relief (e.g., 2×, 4×, etc.); (iv) alternative memory array organization/footprint (i.e., rows versus columns); and (v) alternative memory array latency (ies). Use case embodiments for TDM appear in subsequent lookup path embodiments themselves, which exploit multi-cycle copy circuit techniques with waves of computation passing through a circuit to realize an important functional logic objective. Concerning direct memory array interactions, it should be noted that “column-oriented” TDM, associated with the memory arrays, has been described in U.S. application Ser. No. 17/993,543, filed on Nov. 23, 2022, entitled “Time-Division Multiplexing for Superconducting Memory” (“Reohr 2022”), the disclosure of which is incorporated by reference herein in its entirety; “row-oriented” TDM and “controls-based TDM” will be described principally with respect to FIGS. 18 and 22.

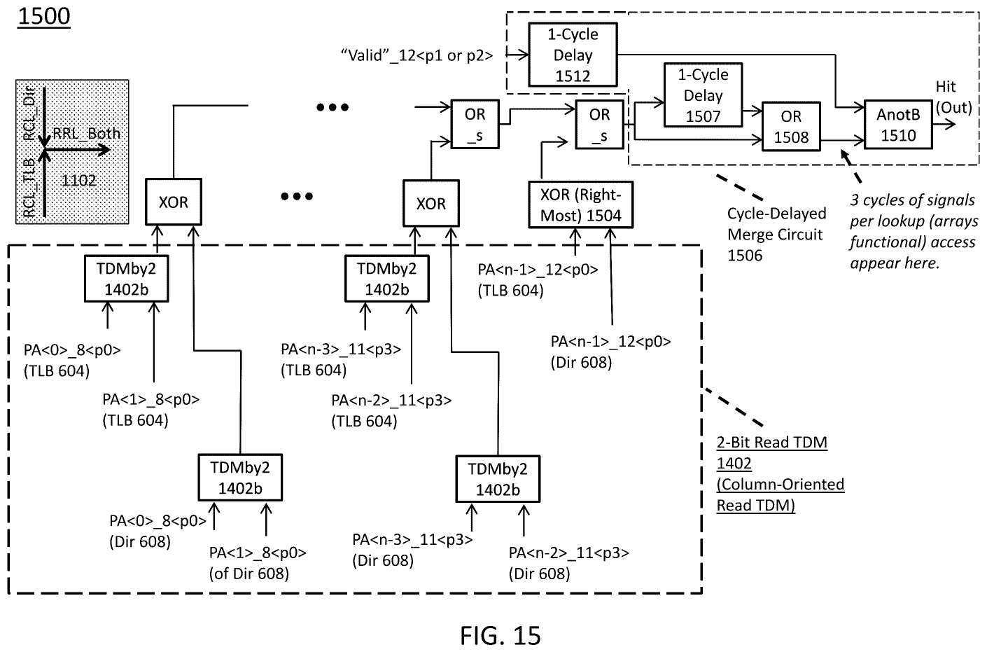

FIG. 15 is a schematic diagram depicting at least a portion of an exemplary serial compare equal circuit 1500, according to one or more embodiments. In the exemplary serial compare equal circuit 1500, a combination of a one-cycle delayed mismatch signal along with a current mismatch signal, by a cycle-delayed merge circuit 1506, forms an overall mismatch (hit) signal. More particularly, within bit-by-bit mismatch stages of this serial compare equal circuit 1500 (on the left side of the schematic), two (two sets of signals passing through the same locations on different cycles) waves associated with one cache lookup access and one portion of a physical address (e.g., the single tag of a lookup path 1400 of a direct-mapped cache, depicted in FIG. 14) may propagate through the spine ORs (OR_s) and combine at the cycle-delayed merge circuit 1506 into a single hit signal available, and sampled on a second cycle of three cycles of signals associated with (triggered by) a lookup (which involves parallel access of TLB_Array 604 and Directory_RAM 608). Enabled by column-oriented TDM, separate even and odd bit waves collect individual bit mismatch results and propagate down the spine until their collective results are merged by the cycle-delayed mismatch merge circuit 1506, which may include a first 1-cycle delay circuit 1512, a second 1-cycle delay circuit 1507, an OR circuit 1508, and A not B circuit 1510, wherein the A not B circuit propagates only the merged hit signal (occurring on the second cycle of three cycles of signals associated with (triggered by) each lookup).

It is noteworthy that even bit mismatches are available on a first cycle of the three cycles; ORed even and odd bit mismatches on a second of three cycles; and odd bit mismatches on a third cycle of the three cycles. The second cycle functions as the merge cycle. Specifically with respect to the TDM serial compare equal circuit 1500, the “Valid” _12<p1 or p2> serves to sample the resulting mis-compare, generating a hit signal (compare “out”) through the A not B gate 1510. In general, the cycle delayed merge circuit 1506 can perform merges on parity data, generated by a XOR series connected chain (serving in place of a spine OR series connected chain), etc.

The TDM serial compare equal circuit 1500 of FIG. 15 shows an odd number of bits, for expressing the circuit topology impacts/changes of that odd number: no TDMby2 circuits front the right-most XOR. In different words, PA<n−1>_12<p0> (of TLB Array 604) and PA<n−1>_12<p0> (of Directory_RAM 608) drive XOR (right-most) 1504. Only half as many XORs and spine ORs (labelled “OR_s”) than the other serial compare equal circuits (e.g., serial compare equal 1100 of FIG. 11).

FIG. 16 is a flow diagram and schematic depicting at least a portion of an exemplary lookup path 1600 for a two-way set associative cache, with a fully associative TLB (CAM-based), according to one or more embodiments. The lookup path 1600 may be configured to implement virtual to physical address translation, and is further configured to implement a physically indexed and physically tagged directory. Due to the use of TDM in the lookup path 1600, the lookup path 1600 processes requests at half the peak bandwidth of the arrays (TLB_Match 602, TLB_Array 604, and Directory_RAM 1608) and logic.

With reference to FIG. 16, the lookup path 1600 includes a Directory_RAM 1608, which may be a full directory configured to store physical address bits and cache management bits (e.g., MESI) corresponding to sets 0 and 1. The physical address bits/memory cells for set 0 and set 1 may be interleaved (i.e., alternated) along a row line. A width of the memory cell of the Directory_RAM 1608, in one or more embodiments, is half that of a TLB_Array (physical) block 604 included in the lookup path 1600. This dimension reduction in the width of the memory cell is along the read row line (RRL) of the Directory_RAM and that of the TLB_Array (physical). The Directory_RAM 1608 may also receive, as an input, an index address, I₀ through I_{N-1}.

Operatively coupled to an output of the Directory_RAM 1608 in the lookup path 1600 is a two-bit read circuit. The two-bit read circuit may be a column-oriented TDM circuit (i.e., 2-bit read TDM circuit) 1606 (e.g., consistent with the TDM read circuit described in Reohr 2022). The two-bit read TDM circuit (column-oriented read TDM) 1606 may be configured to forward, without substantial delay, a first output bit of the Directory_RAM 1608 (a first bit of PhysDir_0, notated as PhysDir_0<0>_8-RQLs<p0>) to the serial compare equal circuit 1100. This output bit is preferably representative of a bit, Tag 0, stored in an associated first memory cell. A second adjacent output bit of the Directory_RAM 1608 (a first bit of PhysDir_1, notated as “PhysDir_1<0>_8-RQLs<p0>”) may be delayed by an RQL (SFQ) cycle and then forwarded (both actions being conducted by the two-bit read column-oriented TDM circuit 1606) to the serial compare equal circuit 1100. In this way, each of the tag bits of the two-way set associative directory are provided for comparison with the physical address, Phys_{TLB}, retrieved from the TLB (which may be a CAM 606 consisting of a TLB_Match 602 and TLB_Array 604 components, as shown in FIG. 6A). It should also be noted that two functionally identical copies of Phys_{TLB}, one delayed by an RQL cycle from the other, may be generated for each TLB access by a read and one-cycle delayed read circuit coupled to the output of the TLB_Array 604, and that both the outputs of the TLB_Array 604 and Directory RAM may be skewed across at least one RQL cycle and thus so too are signals Phys_{TLB} and Phys_{Dir_0, 1}.

In the case of a TLB match, for a first relative TLB_Array output RQL cycle (e.g., “n”), the physical address, which may be retrieved (i.e., read) from the TLB_Array 604, propagates through individual OR gates of the read and one-cycle delayed read circuit 1604, as indicated by the one bit of a read and one-cycle-delayed read circuit 1605. This physical address is compared to the tag portion of the physical address for set 0, which was retrieved from the Directory_RAM 1608. This tag, corresponding to a portion of the physical address of the line stored in set 0 and obtained in a table formed by the Directory_RAM 1608 and indexed by the index address, may be referred to as Tag 0 because it is associated with the Hit 0 output of the serial compare equal circuit, which indicates whether or not set 0 of the data cache stores the indexed line.

In the case of a TLB match for a second relative TLB_Array output RQL cycle (n+1), a copy of the physical address, which was retrieved from the TLB_Array 604, may be generated (e.g., by the read and one-cycle delayed read circuit) and delayed by an RQL cycle. The copy of the physical address is compared to the tag portion of the physical address for set 1, which was retrieved from the Directory_RAM 1608 and is also delayed an RQL cycle by the two-bit read column-oriented TDM circuitry 1606. This tag, corresponding to a portion of the physical address of the line stored in set 1 and obtained in a table formed by the Directory_RAM 1608 and indexed by the index address, may be referred to as Tag 1 because it is associated with the Hit 1 output of the serial compare equal circuit, which indicates whether or not set 1 of the data cache stores the indexed line.

Note, that compared to the illustrative embodiment of FIG. 13, the Hit 0 output may be computed one RQL cycle in advance of the Hit 1 output in the embodiment shown in FIG. 14. Also, given the two wave processing occurring in the serial compare equal circuit, a fetch or store pretest operation through the lookup path of the cache will occur every other cycle. Although TDM (column oriented) may reduce the bandwidth of the lookup path 1600 in half, the need for JTL pass-throughs may be eliminated thereby saving a comparator. Moreover, and more importantly, for lookup path 1600, the timing allotted to each spine OR (OR_s) of serial compare equal 1100 may be twice that allotted for each memory cell of directory RAM 1608. Faster SFQ memory cells (e.g., as described in Herr 2023) may require spine OR logic with the aforementioned relaxed timing allotment.

For the lookup path configuration 1400 shown in FIG. 14, having a reduced bandwidth may have a less significant impact on performance because, for example in an instruction cache application, the TLB and Directory pipelines may be sufficiently long in terms of latency that it is difficult to determine how an instruction stream might branch to update a program counter (the cache operation requester). Spatially, larger lines can be incorporated in the cache, as will become apparent to those skilled in the art.

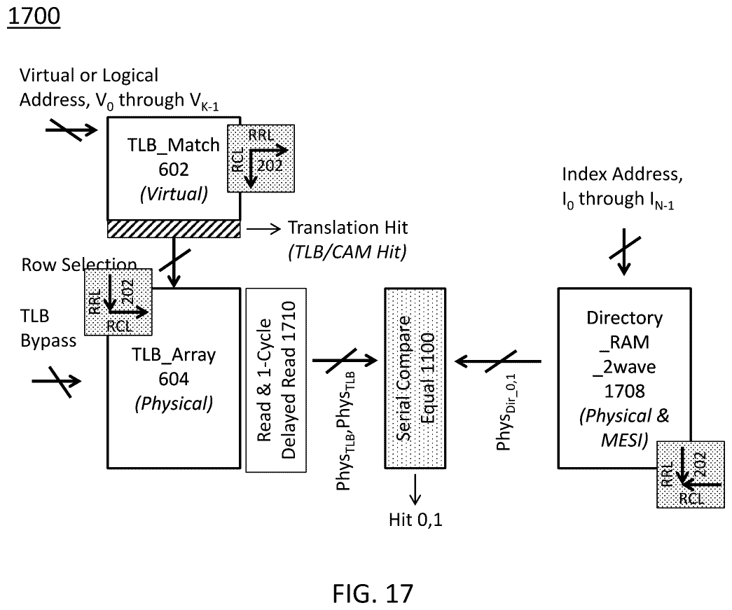

FIG. 17 is a flow diagram and schematic depicting at least a portion of an exemplary lookup path 1700 for a two-way set associative cache, with a fully associative TLB (CAM-based), which implements virtual to physical address translation, according to one or more embodiments. The lookup path 1700, like the lookup path 1600 of FIG. 16, may include TLB_Match 602 and TLB_Array 604 blocks, and a read and one-cycle delayed read block 1710 coupled to the TLB_Array 604. The TLB_Match 602 and TLB_Array 604 may be configured to provide two accesses of the TLB to the same virtual address along with, in parallel, two accesses to directory row lines storing tags of the indexed set 0 and set 1 entries. Outputs, Phys_{TLB}, generated by the TLB_Array 604 are supplied to a serial compare equal circuit 1100. Due to the use of TDM in the lookup path 1600, the lookup path 1600 processes requests at half the peak bandwidth of the arrays (TLB_Match 602, TLB_Array 604, and Directory_RAM 2wave 1708) and logic.

The lookup path 1700 may be configured to implement a physically indexed and physically tagged directory. More particularly, the lookup path 1700 may further include a directory, Directory_RAM_2wave 1708, which may be a full directory storing physical address bits and cache management bits (e.g., MESI) corresponding to set 0 and set 1. The Directory_RAM_2wave 1708 may be configured such that one read request triggers two waves of data from RRLs (or for FIG. 18, neighboring RRLs)—TDM data—to be retrieved from the RAM onward. Physical address bits/memory cells for set 0 and set 1 may be stored on separate RRLs.

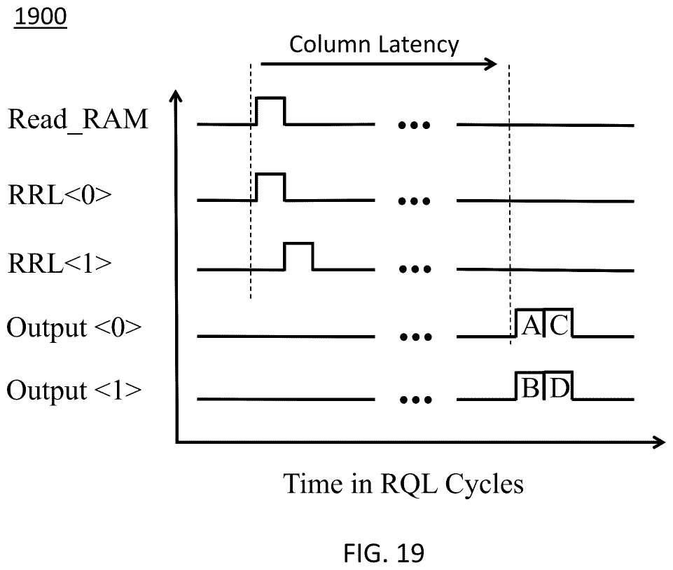

Distinguishable from the lookup path 1600 of FIG. 16, the Directory_RAM_2wave 1708 shown in FIG. 17 may employ row-oriented TDM in place of or in addition to the column-oriented TDM previously described. Advantageously, a row-oriented TDM (enabled in the row lines) permits identical memory cells to be deployed both in the TLB_Array 604 and the Directory_RAM_2wave 1708 because physical tag bits can be aligned between them. Only one set is read from the directory each cycle, for the two back-to-back cycles associated with a single lookup request. The row-oriented TDM configuration of the Directory_RAM_2wave 1708 will be explained in further detail herein below in connection with the schematic depicted in FIG. 18 and its associated read timing diagram depicted in FIG. 19, according to one or more embodiments of the inventive concept. (It is noteworthy that a lookup path, having a controls-based read TDM, described with respect to FIG. 22, functions in almost an identical manner to the lookup path 1700 of FIG. 17)

Specifically, FIG. 18 is a schematic diagram depicting at least a portion of an exemplary RQL (or SFQ)-time-division multiplexed memory array 1800 employing TDM for reading data from memory cells (or fixed switches/ROM cells as known in the art) within an array, according to one or more embodiments of the invention. The memory array 1800 may include a plurality of memory cells arranged vertically along corresponding RRLs (RRL<0> to RRL<N−1> and horizontally along corresponding RCLs (RCL<0> to RCL<M−1>), with RRLs and RCLs being oriented substantially perpendicular to one another, in this illustrative embodiment. Each dashed box represents a set (i.e., collection or grouping) of neighboring memory cells in the array 1800, with the dashed box on the right representing memory cells residing farthest from their respective data outputs, and the dashed box on the left side of FIG. 18 representing memory cells residing nearest to their respective data outputs. The memory array 1800 further includes read decoders and drivers operatively connected to corresponding sets of memory cells. Data from one memory cell in a given RCL is passed to a memory cell in an adjacent RRL of that RCL. Data outputs, Output<0> through Output<M−1>, are generated by the memory cells associated with the last RRL (RRL<N−1>) in each of the respective RCLs in the memory array 1800.

The time-division-multiplexed memory array 1800 can be used in conjunction with JTL and OR gate-based RCLs (i.e., read column lines). In an exemplary read path associated with the time-division-multiplexed array 1800, it is assumed that a controlling signal is a logic “1,” and thus the array read path preferably utilizes OR gates, although embodiments of the inventive concept are not limited to these assignments. For example, it is to be appreciated that in other embodiments, wherein the controlling signal is a logic “0,” the read path may utilize AND gates instead of OR gates, as will become apparent to those skilled in the art.

FIG. 19 is a timing diagram conceptually depicting certain illustrative signals in the exemplary time-division-multiplexed memory array 1800 shown in FIG. 18 during a TDM read operation, according to one or more embodiments. For the TDM read operation, explained in conjunction with the time-division-multiplexed memory array 1800 of FIG. 18, a subscript appended to a given memory cell designates a location/address of the memory cell, while its parenthetical designates a state of the memory cell. (See four memory cells in the upper right quadrant of FIG. 18. Note, that the labels A, B, C, and D, associated with the state of the memory cells, are unrelated to the labeling of cache ways/sets often using those letters in the prior art.)

More specifically, as depicted in the read timing diagram of FIG. 19, the memory array 1800 of FIG. 18 may generate two back-to-back waves of RRL results as a time-division multiplexed set of data on its representative outputs, Output<0> and Output<1> (all outputs would include 0 through <N−1>), which are triggered by the activation of RRL<0>, followed by activation of RRL<1> on subsequent RQL cycles. The ellipses along each RRL and each RCL are intended to indicate a larger N×M memory array, where N and M are integers that are not necessarily the same (although they can be the same).

As an extension of this exemplary embodiment, circuits (e.g., read decoders and drivers, not explicitly shown but implied) included in the time-division-multiplexed memory array 1800 can be designed to launch multiple waves associated with multiple row accesses by simply forwarding an enable signal through at least one cycle delay element onto the next read row line. Moreover, timing between waves can be extended by an integer number of desired RQL cycles rather than a single RQL cycle (labeled “1-Cycle Delay”) as indicated on the schematic.

The time-division-demultiplexed memory array 1800 of FIG. 18 beneficially reduces the number of final decoder and driver stages, final stage decoder & driver 1806, by a factor of two (at least a factor of two in general for a launch of multiple waves of data from an integer number of columns) because only one final stage decoder & driver 1806 (e.g., “near”) drives first and second RRLs (e.g., RRL <N−1> and RRL <N−2 . . . ), the second RRL being driven by a cycle delayed signal from the first RRL, which is generated by the 1-cycle delay circuit 1804.

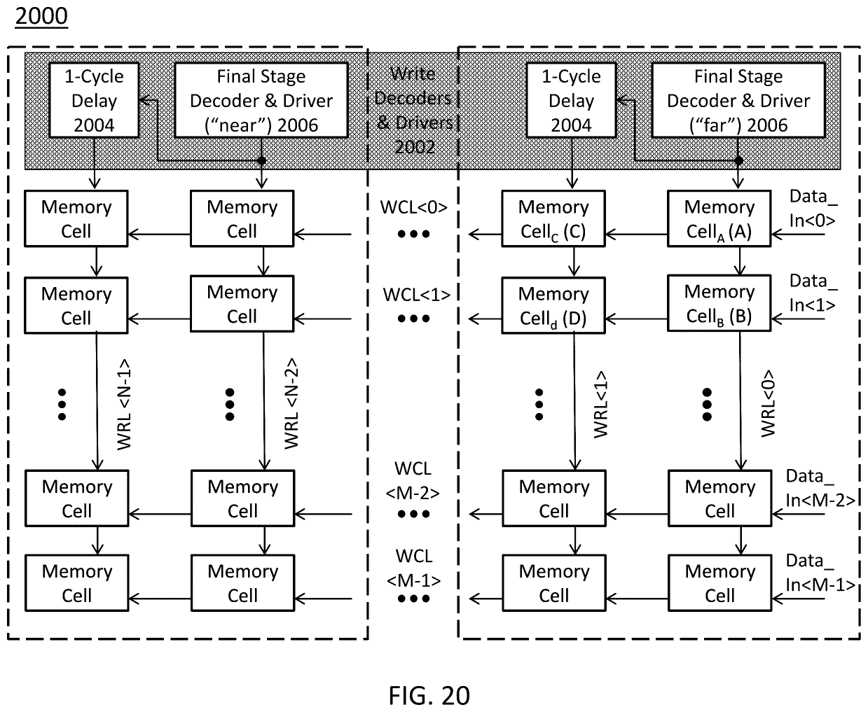

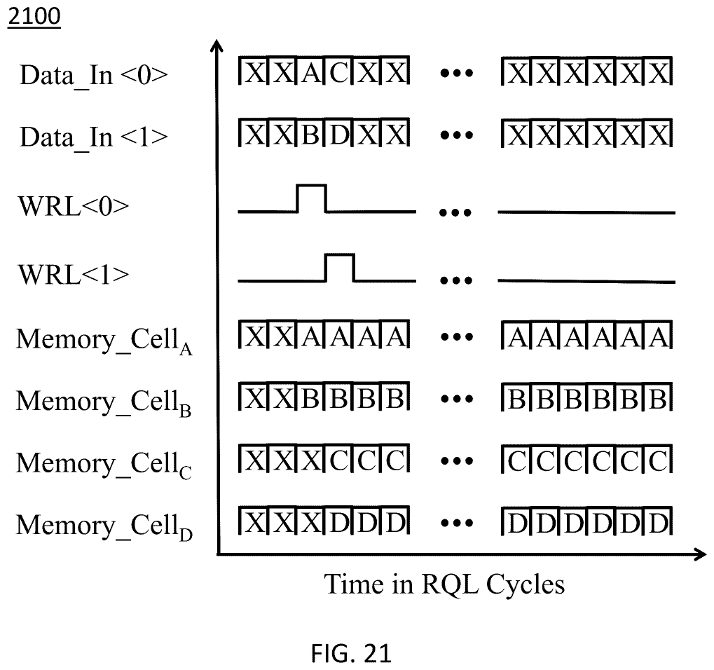

FIGS. 20 and 21 are a block diagram and corresponding write timing diagram, respectively, conceptually depicting a time-division-demultiplexing memory array 2000 and an illustrative write operation associated therewith, according to one or more embodiments. In FIGS. 20 and 21, it should be noted that write row line is abbreviated WRL, and in FIG. 20, that write column line is abbreviated WCL.

With reference to FIG. 20, the memory array 2000, like the illustrative memory array 1800 shown in FIG. 18, may include a plurality of memory cells arranged vertically along corresponding WRLs (WRL<0> to WRL<N−1> and horizontally along corresponding WCLs (WCL<0> to WCL<M−1>), with WRLs and WCLs being oriented substantially perpendicular to one another, in this illustrative embodiment. Each dashed box represents a set (i.e., collection or grouping) of neighboring memory cells in the array 2000, with the dashed box on the right representing memory cells residing farthest from their respective data inputs, and the dashed box on the left side of FIG. 20 representing memory cells residing nearest to their respective data inputs. The memory array 2000 further includes write decoders and drivers operatively connected to corresponding sets of memory cells. Data from one memory cell in a given WCL is passed to a memory cell in an adjacent WRL of that WCL. Data inputs, Data_In<0> through Data_In<M−1>, are supplied to the memory cells associated with the first WRL (WRL<0>) in each of the respective WCLs in the memory array 2000.

A single associated write operation of the time-division-demultiplexing memory array 2000 is described which stores TDM data presented to exemplary data inputs, Data_In<0>, Data_In<1> (all inputs would include 0 through <N−1>), in multiple rows of the memory array (illustrated by data A, B, C, and D). Write demultiplexing is done to separate, preferably neighboring rows.

The time-division-demultiplexing write memory array 2000 of FIG. 20 beneficially reduces the number of final decoder and driver stages, final stage decoder & driver 2006, by a factor of two because only one final stage decoder & driver 2006 (e.g., “near”) drives first and second WRLs (e.g., WRL <N−1> and WRL <N−2>), the second WRL being driven by a cycle delayed signal from the first WRL, which is generated by the 1-cycle delay circuit 2004.

FIG. 21 is a timing diagram conceptually depicting certain illustrative signals in the exemplary time-division-demultiplexing memory array 2000 shown in FIG. 20 during a TDM write operation, according to one or more embodiments. For the TDM write operation, explained in conjunction with the time-division-demultiplexing memory array 2000 of FIG. 20, a subscript appended to a given memory cell (i.e., Memory_Cell_{A}, Memory_Cell_{B}, Memory_Cell_{C}, and/or Memory_Cell_{D}) designates a location/address of the memory cell, while its parenthetical (i.e., A, B, C, and/or D, respectively) designates a state of the memory cell after it is written.

More specifically, as depicted in the write timing diagram 2100 of FIG. 21, the memory array 2000 of FIG. 20 receives two back-to-back waves of WRL input as a time division multiplexed set of data on its representative inputs, Data_In<0> and Data_In<1> (all inputs would include 0 through <M−1>), which are triggered by the activation of write row line WRL <0>, followed by activation of write row line WRL<1> on subsequent RQL cycles. The ellipses along each WRL and each WCL are intended to indicate a larger N×M memory array.

In the write timing diagram 2100 of FIG. 21, before a memory cell is written it contains unknown (or prior) states, labelled with a “X,” in FIG. 21. After the memory cells, Memory_Cell_{A}, Memory_Cell_{B}, Memory_Cell_{C}, and Memory_Cell_{D}), are written, they contain their new states, A, B, C and D, respectively. Subscripts and parentheticals have been chosen to correspond (to be identical) to provide clarity as to which memory cells the TDM write data are directed to. Note that the two waves have been stored in memory cells associated with different rows, WRL<0> for A and B in the first wave and WRL<1> for C and D in the second wave.

As an extension of this exemplary embodiment, circuits (e.g., read decoders and drivers) included in the time-division-multiplexed memory array 1800 can be designed to launch multiple waves associated with multiple row accesses by simply forwarding an enable signal through at least one cycle delay element onto the next read row line. Moreover, timing between waves can be extended by an integer number of desired RQL cycles rather than a single RQL cycle (labeled “1-Cycle Delay”) as indicated on the schematic.

One subtlety worth mentioning is that, while this example embodiment—time-division demultiplexing memory array 2000—illustrates a row-oriented TDM write operation, only the row-oriented TDM read operation of the memory array (labeled Directory_RAM_2wave 1708 of FIG. 17) need be enabled for cache read operations. For a directory write operation, only a single tag need be modified to write the directory. However, the row-oriented TDM write approach, may for example, be used to load a new line in a data RAM (of the cache), if a line has a separate index addresses, permitting it to be stored across two waves, which are separated by at least one RQL cycle.

FIG. 22 is a flow diagram and schematic depicting at least a portion of an exemplary lookup path 2200 for a two-way set associative cache, which implements virtual to physical address translation with a fully associative TLB, according to one or more embodiments. The lookup path 2200 represents an alternative to the illustrative approach shown in FIG. 17. In the exemplary embodiment of FIG. 22, instead of using the row-oriented TDM circuits 1800 of FIG. 18 (associated lookup of FIG. 17), such a two-wave output, for accessing two portions of addresses associated with Tag 0 (through way 0), holding Phys_{Dir_0}, and Tag 1 (through way 1), holding Phys_{Dir_1}, may also be generated through a normal memory array (e.g., RAM) access by making read directory RAM 2208 requests on back-to-back RQL cycles. Similar to the lookup operation 1800 enabled by the approach shown in FIG. 18, the approach 2200 shown in FIG. 22 only permits a lookup operation every other RQL cycle. This alternative approach is a “controls-based” version of TDM (control-based TDM), primarily because two directory RAM 2208 complete accesses occur for each logical lookup operation; that is, multiple waves of data may be processed during each function lookup access period. Standard lookup operations may occupy one system cycle of throughput of RAMs (i.e., bandwidth). To support a lookup, two requests to the TLB CAM 2206 retrieve data from the same location (e.g., logical address 0).

Unlike a “page mode” used in standard DRAMs, where additional data from a single read access resides in output latches (associated with the memory cell sense and restore operation) after a read operation, and thus the data can be fetched in subsequent cycles (before the output latches/sense amplifiers are pre-charged), two full accesses are performed here, which, for a RAM, independently traverse read decoders, RRL, memory cells, and RCLs.

The term “wave” is employed here to describe the processing of addresses in FIG. 22 rather than “cycle” because, as explained with respect to earlier figures (e.g., FIGS. 3A, 3B, and 3C), the outputs of a RAM read request of an array of reasonable size (e.g., 128 RRLs by 128 RCLs) are skewed in time across RQL cycles. “Cycle” or “cycles” would have to be specified across a range. The integers N and M here are still intended to provide an indication of accumulated latencies through each circuit element (i.e., RAM, CAM, and serial compare equal).

“Hit₀” and “Hit₁” may occur as waves N+M, and N+M+1, respectively; the first on a specific RQL cycle while the second follows one RQL cycle later, as evident for the serial compare equal schematic 1100. Two sets of inputs—(i) Phys_{Dir_0} and Phys_{TLB}, applied in combination, and (ii) Phys_{Dir_1} and Phys_{TLB}, applied in combination—yield two outputs—(i) Hit₀ and (ii) Hit₁, respectively. Within the serial compare equal circuit, skewed outputs from arrays for each of two accesses converge (i.e., merge) in time to two signals occupying two corresponding RQL cycles, back to back, at the “Hit” output.

Notice, the inputs to the directory are labeled “Index Address 0 (+Tag 0)” and “Index Address 0 (+Tag 1).” While they are different addresses, they are labeled with the “Index Address 0” prefix to remain consistent with existing cache nomenclature and its associated address mapping and memory array access structure. The tag bit can be the low order bit of the directory (RAM) address and can be “0” for the first access and “1” for the second access.

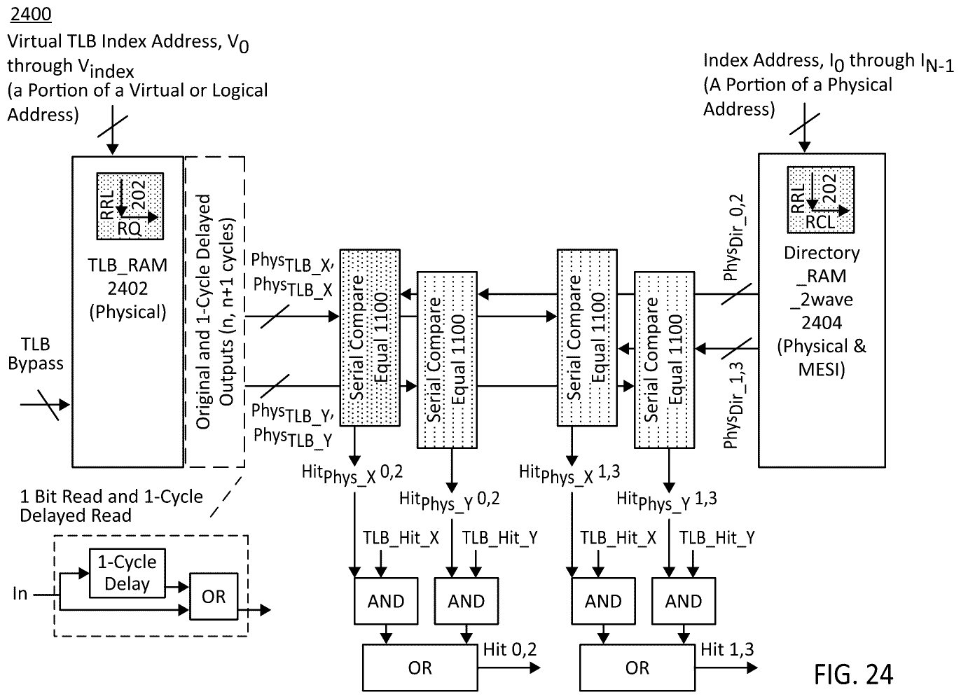

FIG. 23 shows an illustrative flow diagram and schematic of a TLB Virtual-Address-Match portion of a lookup path for a four-way set associative cache, which implements virtual (i.e., logical) to physical address translations, according to one or more embodiments. Together, FIGS. 23 and 24 describe an entire lookup path 2300, 2400, combined, for an exemplary four-way set associative cache having a two-way set associative TLB in its entirety. Due to the inclusion of TDM (e.g., a two-wave access per lookup operation—preferably row-oriented TDM) for aligning the pitches of a two-way TLB_RAM 2402 with a four-way directory RAM 2wave 2404, this lookup path operates with half the bandwidth, which might otherwise be made possible by its RQL micro-pipeline.

The superconducting set associative lookup path 2300, 2400, combined, in this exemplary embodiment may be configured to implement a physically indexed and physically tagged directory and to implement a virtually indexed and virtually tagged TLB. The lookup path 2300, 2400, combined, for an N-way set associative cache (shown here as a four-way set associative cache, easily modified to be N-way, where N is an integer greater than 1) includes at least one TLB tag array, TLB_Tag_Array_X 2302 and TLB_Tag_Array_Y 2302 (e.g., TLB Tag Array 2302), which stores a virtual address, at least one TLB RAM 2402, which stores a corresponding physical address, at least one serial compare equal circuit 2306 associated with the TLB tag array and generating two identical results on back to back cycles (e.g., denoted “TLB_Hit_X,TLB_Hit_X” on FIG. 23), for comparing a tag portion of the virtual address to the output of the TLB tag array (labeled “Stored_Virtual_Tag”), at least one directory RAM, configured for time division multiplexing (Directory_RAM 2wave 2404), at least one serial compare equal circuit 1100 for comparing TLB RAM 2402 and directory RAM 2404 outputs, at least one AND circuit, at least one OR circuit, wherein all the serial compare equal circuits complete their bit-by-bit match evaluations over a plurality of RQL cycles (e.g., two cycles) for each lookup operation and wherein AND OR circuits combine virtual matches (denoted “TLB_Hit”) and director matches (denoted “Hit_{Phys}”) to generate an overall hit signal (denoted “Hit”).

More specifically, a portion of the embodiment of the lookup path 2400 shown on FIG. 24 involves four serial compare equal circuits 1100, four AND circuits, and two OR circuits, which perform operations on 2 waves of data for each lookup operation requested.

Conventionally, signals emerge from RAMs on the same or, at most, subsequent cycles. Compares are completed in less than a single cycle. Furthermore, a plurality of tag matching (i.e., physical address matching) can occur within a wave or within a plurality of waves, as noted in connection with FIG. 24. The AND OR logic at the output of the serial compare equal circuits 1100 shown in FIG. 24 may assure that the translated address from the TLB, one of two physical addresses, is valid, and that the directory stores that particular address. This notation is intended to indicate that Hit₀ and Hit₁ are computed from the first wave of data retrieved from the TLB RAM and Directory RAM—notably accessing the first read row line of a wave pipelined pair of read row lines within the Directory RAM as described with respect to FIG. 24—while Hit₂ and Hits are computed from the second wave of data retrieved from the TLB RAM and Directory RAM-notably accessing the second read row line of a wave pipelined pair of read row lines within the Directory RAM as described with respect to FIG. 24.

It is important to note that the physical design (layout) of the lookup path 2300,2400, combined, has been specified so that TLB RAM 2402 (2-way set associative TLB) can be directly aligned with directory RAM 2wave 2404 (4-way set associative directory). Memory cells of TLB RAM 2402 may store interleaved Phys_{TLB_X} and Phys_{TLB_Y} bits along each RRL. Memory cells of directory RAM 2wave 2404 may store (i) interleaved Phys_{Dir_0} and Phys_{Dir_1} bits along each even RRL and (ii) interleaved Phys_{Dir_2} and Phys_{Dir_3} bits along each odd RRL. The pair of odd and even RRLs may be accessed over a plurality of cycles (e.g., 2 cycles) for a read TDM operation (e.g., row-oriented read TDM of FIG. 18). With this physical and logical structure, a common (identical) memory cell layout may advantageously be used for all memories: (i) TLB Tag Array 2302; (ii) TLB RAM 2402; and (iii) directory RAM 2404.

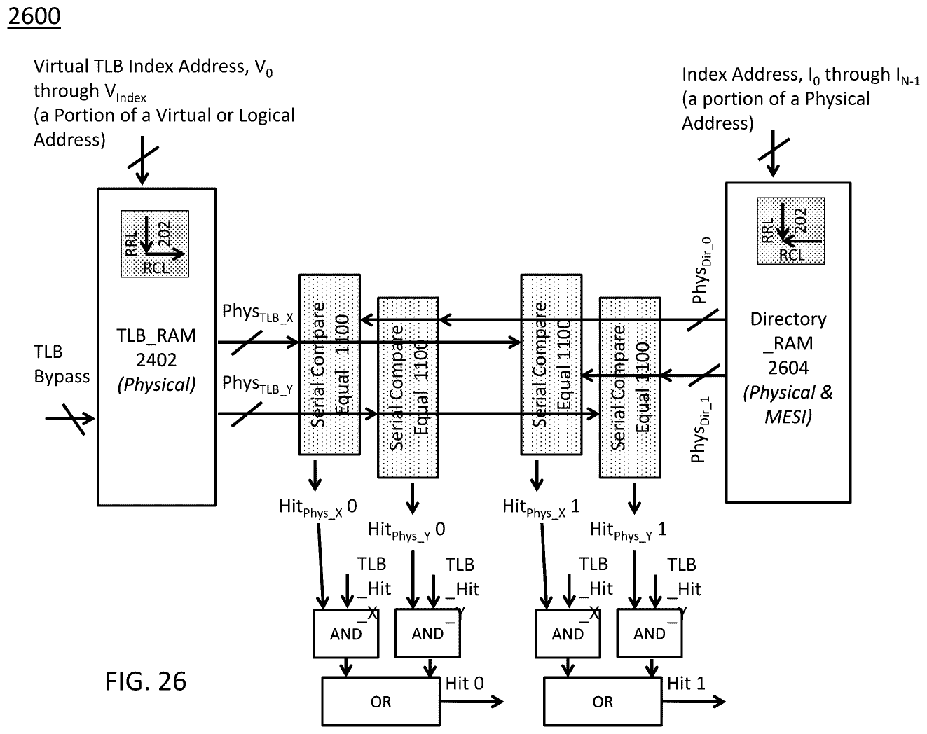

FIGS. 25 and 26 collectively depict a lookup path for an exemplary two-way set associative cache having a two-way set associative TLB in its entirety, according to one or more embodiments. In contrast to the illustrative lookup path shown in FIG. 24, the exemplary lookup path shown in FIGS. 25 and 26 can operate at the full bandwidth of the underlying RQL micro pipeline. Unfortunately, its “hit” rate will be far lower due to its 2 times lower set associativity-two-way associative for FIG. 26 versus four-way associative for FIG. 24.

Given that the latency of the cache is already large compared to its bandwidth, there may be little advantage derived in using the full bandwidth cache at all even if the hit rates were identical, which they are not.

Principles according to embodiments of the present disclosure may used to configure pipelined SFQ memory arrays such that the cycle that their output data is available (e.g., from cache) is a function of (i.e., depends on) the value of a subset of their address bits (e.g., highest order address bits), wherein the value of that subset of address bits may be indicative of how far signals generating the output data, associated with the decoded address, must travel principally within the columns of the memory array itself; that is, the value of the subset of address bits may be coded to represent the distance associated with a signal path between a memory cell and its corresponding output logic. The subset of address bits and their associated rows will be referred to herein as a “fixed-delay-address” subset. Rather than suppress variable pipeline latencies intrinsic to SFQ, one or more embodiments of the inventive concept seek to exploit them. These embodiments, may not only apply to memory arrays, but may apply more broadly to interchangeable (i.e., fungible) logic and memory. Thus, one or more embodiments to be described in further detail below may apply equally to “memory arrays,” “logic arrays,” and interchangeable arrays. It should be understood that incorporating variable latency arrays can add complexity and area to the design of an entity, such as a CPU, receiving the data, with a trade-off being significant improvements in performance.

It should also be understood that the delays of the subset of decoders and rows in a fixed-delay-address subset may all be designed to have the same delay—delay flattened, padded where necessary—regardless of the row. These delay adjustments are generally minor when compared to the delays associated with the entire set of fixed-delay-address subsets.

For requests to pipelines with multiple entry points and variable delay lengths, collisions can occur internally within each memory array or on a data output bus, where the output from a plurality of memory arrays converges. Such collisions should be avoided in order to prevent return of corrupt data. Adding delays to shorter pipeline entry points to assure identical latencies in the pipeline solves the collision problems but sacrifices performance; applying this approach assures that all paths through a memory array will have the worst-case latency corresponding to the slowest address.

As a consequence of permitting variable latency pipelines in an attempt to improve overall performance by driving average array access latency down, data can and will return out of order. The control logic used to prevent collisions can be configured to account for out of order data returns, according to one or more embodiments. For example, additional control logic may be configured to track the address of the emerging data, according to some embodiments. Although the RAM (data RAM, such as, for example, a D-cache) can handle the out-of-order data return, it can add complexity to the design of the area of the CPU receiving the data.

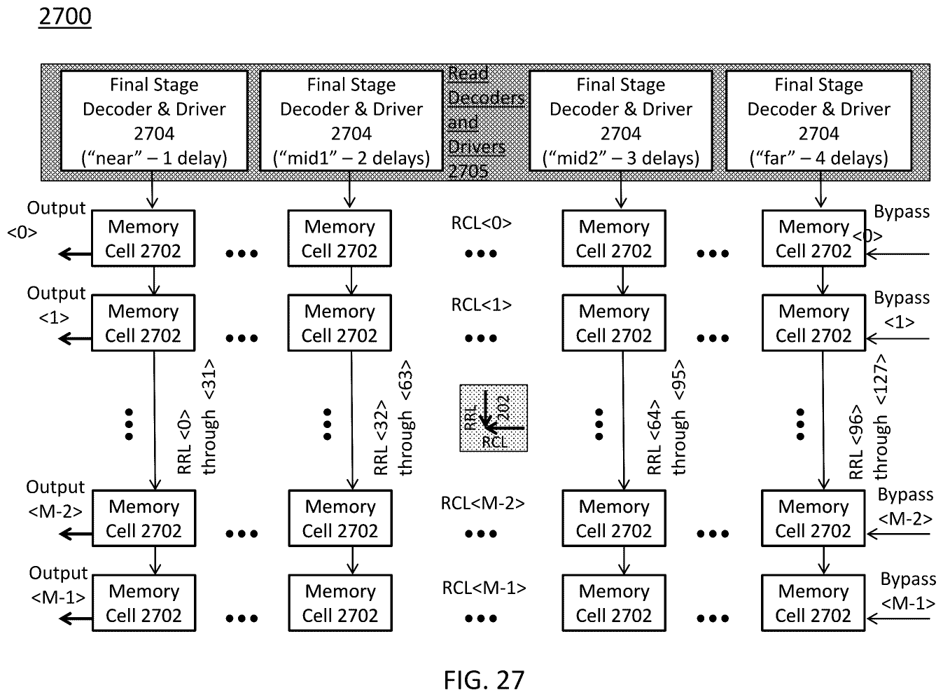

FIG. 27 is a block diagram depicting at least of an exemplary variable delay pipelined SFQ memory array 2700, according to one or more embodiments. With reference to FIG. 27, the variable delay pipelined SFQ memory array 2700 includes a plurality of memory cells 2702 and read decoders and drivers 2704 coupled to the memory cells. In this illustrative embodiment, a memory array having 128 RRLs (RRL 0 to 127) and M read CLs (read CL 0 to M−1) is assumed, where M is an integer greater than one. It is further assumed that each of the RRLs are organized into one of four different “regions,” where each separate region has a designated latency between a memory cell and its corresponding output logic (i.e., memory output) associated therewith. Although four distinct regions are shown in this example, it is to be understood that embodiments of the invention are not limited to this specific arrangement; that is, the number of regions may be less than four (e.g., two or three), or more than four (e.g., five or greater).

Using four different regions, each region can be assigned 32 RRLs. In this example, it is assumed that memory cells associated with RRLs 0 through 31 are nearest to the output logic and therefore have the smallest latency (i.e., shortest delay) (e.g., 1 delay unit), RRLs 32 through 63 are further away from the output logic than RRLs 0 through 31 and therefore have the second smallest latency (e.g., 2 delay units), RRLs 64 through 95 are further away from the output logic than RRLs 32 through 63 and therefore have the third smallest latency (e.g., 3 delay units), and RRLs 96 through 131 are the furthest away from the output logic and therefore have the largest latency (e.g., 4 delay units), as shown in FIG. 27. Each of the regions may include their own final stage decoder and driver circuitry 2704 associated therewith configured to control the movement of data through the corresponding RCLs. Such control may include adding delay and reordering of out-of-order returned data, as will be described in more detail herein below. Each column of memory cells and their corresponding final stage decoder and driver circuitry 2704 may be considered a fixed-delay-address subset.

Assume that the amount of delay between one fixed-delay-address subset and the next may be (and is, for exemplary embodiments) consistent across all the subset values. For example, if there are two address bits and the amount of delay between consecutive fixed-delay-address subsets is one delay unit (e.g., a delay may be defined generally here as N RQL cycles, where N is an integer equal to or greater than one), codepoints and respective delays associated therewith could be “00” is the fastest, “01” is 1 delay later than the fastest, “10” is 2 delays later than the fastest, and “11” is 3 delays later than the fastest. In the discussion that follows, it will be shown that the amount of delay between consecutive fixed-delay-address subsets is consistent across all the subset values, and resolves what at first appears to be inconsistencies in previous figures. This discussion involves FIG. 27, Table A, Table B, and referencing previous FIGS. 3A through 4; the labeling convention (which may be arbitrarily assigned) employed in connection with this discussion is also provided. Depending on how many memory cells are included in each column, array rows can be partitioned into more than or less than the number of fixed-delay-address subsets shown, as previously stated. The latency through any path within a fixed-delay-address subset may be designed to be identical. Only one row is shown for each subset in the exemplary diagram shown in FIG. 27.

With reference to FIG. 27, it should be noted that bypass signals <0> through <M−1>, where M is an integer greater than 1, are included to indicate that data on one side of the RAM can be passed to its outputs at its other side via the SFQ (single flux quantum) column circuits associated with each memory cell.

It should be further noted that FIGS. 3A through 3C are intended to indicate the raw NDRO delay of an array, without delay padding introduced to all or many of the previous figures to assure functional operation (depending on where the delay is introduced in the path). Different from the configurations shown in earlier figures, the illustrative circuit shown in FIG. 27 “buckets” (i.e., assigns) rows into four fixed-delay-address subsets, with delays ranging incrementally from one to four delay units (e.g., four RQL cycles for the 128-column exemplary array), adding phase delay or cycle delay to almost all the Final Stage Decoder and Driver circuits (and/or intermediate decoders) in each subset except for the most remote from the memory outputs. Because of these aforementioned differences, confusion might arise in understanding FIG. 27 and FIGS. 3A, 3B, and 3C collectively, but, if one understands that FIG. 27 has padded delay paths and FIGS. 3A, 3B, and 3C represent raw delays of the arrays, this confusion can be resolved.

By way of example only and without limitation or loss of generality, Table A below includes tabulated exemplary raw array delays obtained from FIGS. 3A, 3B, and 3C.

TABLE A

| | | | Fixed-Delay- |
|---|---|---|---|
| | Read Row | Column Raw | Address Subset |
| FIG. | Line | Delay in Cycles | Label |
| 3C | 0 | 0 | Near |
| No FIG. | 31 | 1 | Near Middle |
| 3B | 63 | 2 | Near Middle |
| 3A | 127 | 4 | Far |

To transform a raw array of Table A, into any fixed-delay-address subset of RAM of FIG. 27, delay can be introduced. In FIG. 27, the near read row line <0>, and those through to read row line <31>, are padded with decreasing phase delay as their row number increases in the read path leading to the final row so that each of their delays is 1 delay (for our example 1-RQL cycle) regardless of their address in this subset of rows.

The other rows noted in Table A, read row line <31>, read row line <63>, and read row line <127>, are raw delay values (or close to raw delay values) that correspond to FIG. 27. Given that they are the last row in a fixed-delay-address subset, they set/define the overall delay of the entire subset.

A discussion of Table B follows below. In general, delays can be different among fixed-delay-address subsets. In FIG. 27, however, they are defined to be the same one-cycle difference for simplicity (Again, to avoid confusion, no correspondence with FIGS. 3A, 3B, and 3C represented in Table A should be considered because those array timings represent illustrative raw delays.). In the discussion herein, it is to be appreciated that the term “far” (or “farthest”) is intended to refer to a distance of a signal path from a memory cell to a corresponding circuit element (e.g., row or column output) being greatest relative to a distance of signal paths between the circuit element and other memory cells in the system. Thus, by way of example only, the farthest set of final stage decoder and drivers may be assigned to the far fixed-delay-address subset having high order address bits “11;” these are the memory cells farthest from their corresponding outputs and have a delay of four cycles. The set of final stage decoder and drivers, ranging from middle to far, may be assigned to the middle-far fixed-delay-address subset having high order address bits “10;” they have a delay of three cycles. The set of final stage decoder and drivers, ranging from near to middle, may be assigned to the middle-near fixed-delay-address subset having high order address bits “01;” they have a delay of two cycles. The set of near stage decoder and drivers may be assigned to the near fixed-delay-address subset having high order address bits “00;” they have a delay of one cycle.

By way of example and without limitation or loss of generality, Table B below includes tabulated delays through the illustrative memory array 2700 of FIG. 27.

TABLE B

| Read Row | Fixed RQL Cycles | High Order | Fixed-Delay-Address |
|---|---|---|---|
| Line Range | (Designed to be) | Address Bits | Subset Label |
| 0-31 | 1 | 00 | Near |
| 32-63 | 2 | 01 | Middle Near |
| 64-95 | 3 | 10 | Middle Far |
| 96-127 | 4 | 11 | Far |

With reference to FIG. 27, the following naming convention may be used, although it is to be understood that embodiments of the invention are not limited to any specific naming convention:
S (row addr<11 . . . >)=slow=delay of “far” fixed-delay-address subset
MS (row addr<10 . . . >)=medium slower=delay of “middle-far” fixed-delay-address subset
MF (row addr<01 . . . >)=medium faster=delay of “middle-near” fixed-delay-address subset
F (row addr<00 . . . >)=fast=delay of “near” fixed-delay-address subset

The discussion above establishes the fact that the amount of delay between consecutive fixed-delay-address subsets can be made consistent across all the subset values.

The number of address bits used to point to a fixed-delay-address subset may depend on the number of such subsets. For example, if four fixed-delay-address subsets are employed, then two address bits would be needed to point to one of the fixed-delay-address subsets; to generalize, N address bits are required to uniquely point to one of 2′ fixed-delay-address subsets, where N is an integer.

Before embarking on out-of-order accesses and collisions, it is best to show how the variable delay pipelined SFQ memory array 2700 of FIG. 27 can be used to reduce latency in a cache.

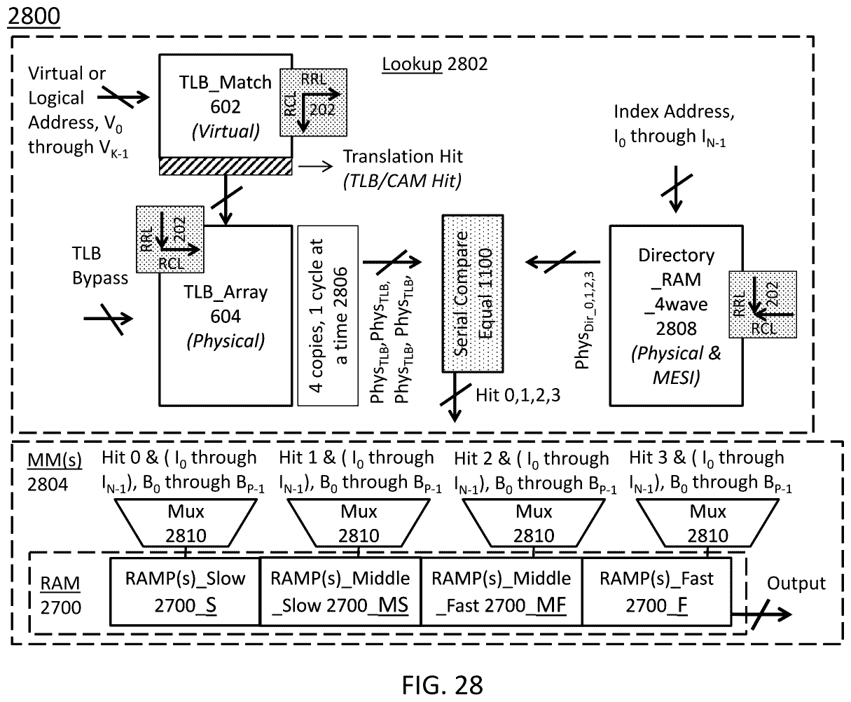

FIG. 28 is a block diagram depicting at least a portion of an exemplary four-way set associative cache 2800, with a fully associate TLB 602/604, that is capable of metamorphosis, according to one or more alternative embodiments of the inventive concept. With reference to FIG. 28, the four-way set associative cache 2800 may include lookup circuitry 2802 operatively coupled to one or more metamorphosing memories 2804. The lookup circuitry 2802 may comprise a fully associative TLB, including at least one TLB_Match 602 (TLB content addressable memory holding virtual (i.e., logical) addresses) and at least one TLB Array 604 (TLB holding physical addresses), at least one serial compare equal circuit 1100 (which may evaluate over a plurality of RQL cycles), and at least one Directory_RAM_4wave 2808 (containing the physical address bits and cache management bits, such as MESI to support, for example, four sets). More particularly, in cache 2800, a lookup operation may be performed first before MM(s) 2804 is accessed (MM(s) can serves as a data RAM 408 of FIG. 4). Such a cache organization saves power and reduces wire congestion but in conventional caches increases latency. Advantageously latencies of Hit 0, 1, 2, 3 may be offset by variable delay pipelined SFQ memory array 2700 of FIG. 27.

All components in the lookup circuitry 2802 may be accessed through both a parallel and sequential data flow ordering (as described already with the many illustrative lookup path embodiments), from the receipt of a virtual address (V₀ through V_{K-1}, where K is an integer greater than one) and an index address (I₀ through I_{N-1}, where N is an integer greater than one) supplied to the lookup circuitry 2802, to the generation of a hit result(s) (e.g., Hit 0, 1, 2, and 3) output by the lookup circuitry 2802. Copy circuitry 2806 coupled to an output of the TLB_Array 604 may be configured to generate four copies of the physical address stored in the TLB Array 604, each copy of the physical address being sent to the serial compare equal circuit 1100 one RQL cycle at a time for comparison with the physical address output by the Directory_RAM_4wave 2808 and presented to the serial compare equal circuit 1100.

It is to be appreciated that each of the hit results generated by the lookup circuitry 2802 will be different from one another (identifying a “hit” to a particular set in the directory, if the directory stores the particular set). Hits may be delayed by one RQL/SFQ cycle for each sequential hit output. Thus, Hit 0 may be representative of the earliest available hit result output, Hit 1 will be available one RQL/SFQ cycle after Hit 0, Hit 2 will be available two RQL/SFQ cycles after Hit 0, and Hit 3 will be available three RQL/SFQ cycles after Hit 0. It should also be appreciated that in this example, there are four hit results generated by the lookup circuitry 2802, the number of hit results corresponding to the number of different “sets” of the set associative cache 2800. All the sets are organized in MM(s) 208 (which, for simplicity sake, may be a data RAM 408 of a cache 400 of FIG. 4). The variable delay pipelined SFQ memory array 2700 of FIG. 27 is divided into four portions of the RAM (abbreviated RAMP), wherein the latency of each portion is fixed, and labeled with S, MS, MF, and F suffixes, which indicate latency.

Exploiting the variable delay pipelined SFQ memory array 2700 of FIG. 27, set 0 data is retained in RAMP(s)_Slow 2700_S, having the greatest latency due to its rows being farthest from the output, set 1 data is retained in RAMP(s)_Middle_Slow 2700_MS, having lower latency compared to set 0 data due to its rows being nearer to the output, set 2 data is retained in RAMP(s)_Middle_Fast 2700_MF, having lower latency compared to set 1 data due to its rows being nearer to the output, set 3 data is retained in RAMP(s)_Fast 2700_F, having the least latency to the output However, embodiments of the invention are not limited thereto. For example, if the memory array is divided into six distinct regions, the copy circuitry 2806 coupled to the output of the TLB_Array 604 may be configured to generate six copies of the physical address stored in the TLB_Array 604, each copy of the physical address being sent to the serial compare equal circuit 1100 one RQL cycle at a time, to generate six hit results (e.g., Hit 0, 1, 2, 3, 4, 5).

With continued reference to FIG. 28, the hit results, Hit 0, 1, 2, 3, generated as an output by the lookup circuitry 2802 may be supplied to the metamorphosing memories 2804. Metamorphosing memories 2804 can include at least one data RAM, which may include, for example, at least portions of RAMs 2700_S, 2700_MS, 2700_MF and 2700_N (collectively, RAM 2700). Each of the RAMs may be associated with a corresponding one of a plurality of distinct “sets” into which each of the RRLs, designed to have identical latency, may be organized. In the example described above in connection with FIG. 27, there are four different regions into which the plurality of RRLs are organized: slow (RAMP(s)_Slow 2700_S, associated with memory cells (and corresponding RRLs) that are farthest from the data output; middle slow (RAMP(s)_Middle_Slow 2700_MS, associated with memory cells (and their corresponding RRLs) that are next farthest from the data output; middle fast (RAMP(s)_Middle_Fast 2700_MF, associated with memory cells (and their corresponding RRLs) that are next closest to the data output; and fast (RAMP(s)_Fast 2700_F, associated with memory cells (and their corresponding RRLs) that are nearest to the data output.

Each of the RAMP(s) may have a corresponding multiplexer (Mux) 2810 connected thereto. Each multiplexer 2810 may be configured to receive at least one full address input, which may include a corresponding one of the timed hit results, Hit 0 through Hit 3, which may logically ANDed with the index address (I₀ through I_{N-1}), and a block offset address (e.g., B₀ through B_{P-1}, where P is an integer greater than one). Other inputs to the multiplexors 2810 (not explicitly shown) may include a “operand” (and its associated “operator” location) for MM(s) when it is being used to perform computation (rather than storage). The multiplexers 2810 may be configured to select a given one of the RAMs 2700 for outputting its data to the output of the cache 2800 (which enables metamorphosing memory—memory which can perform computations), based on a location of the memory cells and a distance from the memory cell selected by the requested address to the output.

The exemplary cache 2800 shown in FIG. 28 may functionally operate at a quarter of the peak bandwidth of the underlying RQL/SFQ pipeline. Notice, that by driving the slow (i.e., farthest) portion of the RAM (e.g., 2700_F) with the fast hit result (e.g., Hit 0), and, similarly, driving the fast (i.e., nearest) portion of the RAM (e.g., 2700_N) with the slowest hi result (e.g., Hit 3), the latency of the data output from the cache 2800 can be advantageously configured to invariant (or at least substantially invariant) with respect to the input address, regardless of the location in which the addressed memory cell physically resides in the cache 2800 (e.g., Set 0, 1, 2, 3). This particular invariant cache latency is the lowest available.

There may be a timing sequence operation that is not explicitly expressed by the labels shown in FIG. 28, but is expressed herein. Hits should be picked off their TDM pulse train. Note, that only one hit per cache read operation can be registered, for a correctly functioning cache 2800. What is shown occurring in the metamorphosing memories 2804 is that each address feeding the multiplexer(s) 2810 may include a timed hit result (e.g., Hit 0, 1, 2, or 3), index address (e.g., I0 through IN−1), which may be logically ANDed with the hit result, and the block offset address (e.g., B0 through BP−1), as previously stated. Each hit has a block offset address and index address, which are timed to match the timing of each hit result so that only one address is propagated into any one portion of the RAM 2700, per cache request.

Next, an introduction of some concepts, so that the RAM of FIG. 27 can be exploited fully, such as data collisions and out-of-order data return, will be provided that are then further described in conjunction with their corresponding figures.

The amount of delay between the data returning from consecutive fixed-delay-address subset values in a particular request stream can be variable, and how the decodes of the codepoints map to the speeds can be variable. Consider a chain of latches, where the output of each latch feeds the input of a next subsequent latch in the chain (with one important exception being an action (i.e., insertion) cycle). For example, if there are two address bits, and the amount of delay between consecutive subset values is one cycle. A signal path through the chain of latches and an assignment of address bit may appear as follows: upstream cycle staging→action (i.e., insertion) cycle (address is available for checking/setting chain)→“11” slow→D→“10” one cycle faster→D→“01” two cycles faster→D→“00” three cycles faster→downstream cycle staging→data valid, where “D” is potential delay. The term “upstream cycle staging” as used herein is intended to refer to cycles that a d-cache request exists but the corresponding subset of address bits is not yet known. The term “downstream cycle staging” as used herein is intended to refer to cycles that are later in the data flow.

The 3 “Ds” in the chain of latches represent the addition of delay cycles, to make the delay between consecutive fixed-delay-address subsets to be, for example, 2 RQL cycles. (If the delay between consecutive subsets is more than 2, then D would represent more than one staging latch. If the delay between consecutive subsets is 1, like the chain example above, then there would be no latch for D). The four “11” thru “00” latches represent the four addressing speeds assigned to the fixed-delay-address subsets in this example, although it is to be appreciated that embodiments of the invention are not limited to this number of latches or addressing speeds.

“Downstream cycle staging” represents cycles where the address propagates to and through the RAM (data RAM, for example a D-cache) until the output data bus is valid.

There would likely be a similar chain that contains a multibit request tag field that identifies the requestor in some way. Such bits may include the subset of cache address bits, associated with each fixed-delay-address subset, being used to monitor the differences (i.e., skew) in the cache data output timing. An example of a requestor may be an instruction unit sending operand fetch requests to the cache.

Almost all of the latches in the chain propagate their value to the next subsequent latch in the chain, with one exception being the action cycle. During an action cycle, the following actions/events may occur:
1) address bits are decoded to set one of the corresponding latches slow, faster by, e.g., one RQL cycle, faster by, e.g., two RQL cycles, or faster by, e.g., three RQL cycles. Since “00” is defined in this example as the fastest, it sets the rightmost bit, which is the shortest bit in the chain. Similarly, “11” sets the longest bit.
2) collisions are detected. If the bit being set on the action cycle (see above) is also being propagated into, then a collision is detected (see below).
3) out-of-order (“OOO”) requests are detected. If the bit being set during the action cycle is to the right of a bit being propagated into, then an out-of-order condition may be detected (see below).

A description relating to an exemplary operation of a pipelined SFQ memory array according to one or more embodiments of the inventive concept follows, wherein it may be assumed that: (i) a RAM array exists; (ii) there is a requestor that sends requests to the RAM; (iii) there is “RAM logic” near (proximate to the RAM) that receives requests, controls the RAM access, and returns the RAM output data to the requestor, along with a data valid indication; (iv) the RAM logic can send a rejected (i.e., “killed”) indication back to the requestor, rather than a data valid indication; (v) there is “requestor logic” that generates RAM requests and uses a data valid indication to process the data returned from the RAM, and also uses the rejected indication to take corresponding actions; and (vi) the requestor logic can send back-to-back pipelined requests.

As previously described, the cycle that RAM output data is available may be dependent on the value of a subset of RAM address bits (known as “fixed-delay-address subset bits”), where the value of that subset corresponds to how far, in space and/or time, that decoded address must travel within the RAM array, from a memory cell to corresponding output logic. This may add complexity to the design of the requestor logic.

This may mean that, for pipelined requests, collisions on the RAM data output bus can occur, which should be avoided in order to prevent the return of corrupt data. Since avoiding such collisions may result in a newer (i.e., subsequent) request being rejected, the pipeline may need to be stalled and/or restarted. This also means that data returned can be out of order. Although RAM logic may be able to handle sending the out-of-order data return, this may add complexity to the design of the requestor logic (e.g., reordering logic may be needed to modify the order of the returned data). Assume that the RAM logic is configured to inform the requestor logic about out of order data returns to help the requestor logic.

By way of example only, assume that the amount of delay between one subset value (fixed-delay-address subset), and the next-slowest subset value is consistent across all the subset values. For example, if there are two address bits, and the amount of delay between consecutive subset values is one cycle, the address codepoints and representative delays may be assigned as: “00” is the fastest; “01” one cycle later; “10” two cycles later; and “11” three cycles later. (See Table B above).

It should be understood that, in general, the number of address bits used can be variable, the amount of delay between consecutive waves of data (e.g., in a wave pipelining context) associated with the fixed-delay-address subset bits can be variable, and how the decoding of codepoints maps to the different latencies can be variable. Embodiments of the inventive concept may be configured to adapt the memory array to such variations. For logic and structural simplicity, however, the illustrative embodiment supports fixed delays and four subset addresses corresponding to two bits, although it is to be appreciated that the inventive concept is not limited thereto.

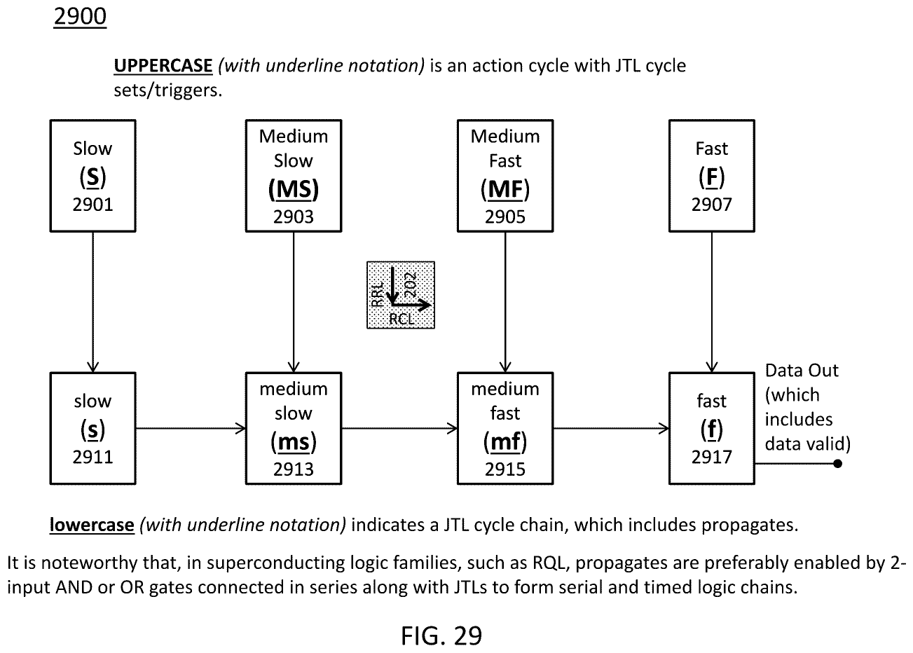

FIG. 29 is a block diagram conceptually depicting at least a portion of an exemplary variable delay pipelined memory array 2900, according to one or more embodiments. As shown in FIG. 29, the memory array 2900 is organized into four subsets of latencies: slow, medium slow, medium fast, and fast. Each of the blocks 2911, 2913, 2915 and 2917 in a serial chain of blocks represents a RQL cycle chain, which includes “propagate” paths. For superconducting logic families, such as RQL, propagates are preferably enabled by two-input AND or OR gates connected in series along with JTLs to form serial and timed logic chains. Propagate refers to a bit in a serial chain moving from one chain element to the next. It is meant to contrast with a bit in the chain being set from a path outside the chain. As shown, each of the blocks 2911, 2913, 2915, 2917 is connected such that an output of one block feeds an input of a next subsequent block in the RQL cycle chain. The block 2911 which is furthest from the output may be assigned the slow(s) designation, with the next block 2913 being assigned the medium slow (ms) designation, the next block 2915 being assigned the medium fast (mf) designation, and block 2917, which is closest to the array output, being assigned the fast (f) designation.

Each of the blocks 2911, 2913, 2915, 2917 may be associated with a corresponding action cycle with RQL cycle sets/triggers. For example, block 2911 may be associated with action cycle 2901 configured to perform slow (S) actions, block 2913 may be associated with action cycle 2903 configured to perform medium slow (MS) actions, block 2915 may be associated with action cycle 2905 configured to perform medium fast (MF) actions, and block 2917 may be associated with action cycle 2907 configured to perform fast (F) actions.

By way of illustration only and without limitation, with reference to FIG. 29, picture a chain of RQL cycles, where the output of each RQL cycle feeds the input of the next RQL cycle. The RQL cycles are interrupted by an “action cycle” as illustrated in the following sequence:
upstream RQL cycle staging→action cycle→downstream RQL cycle staging→data valid

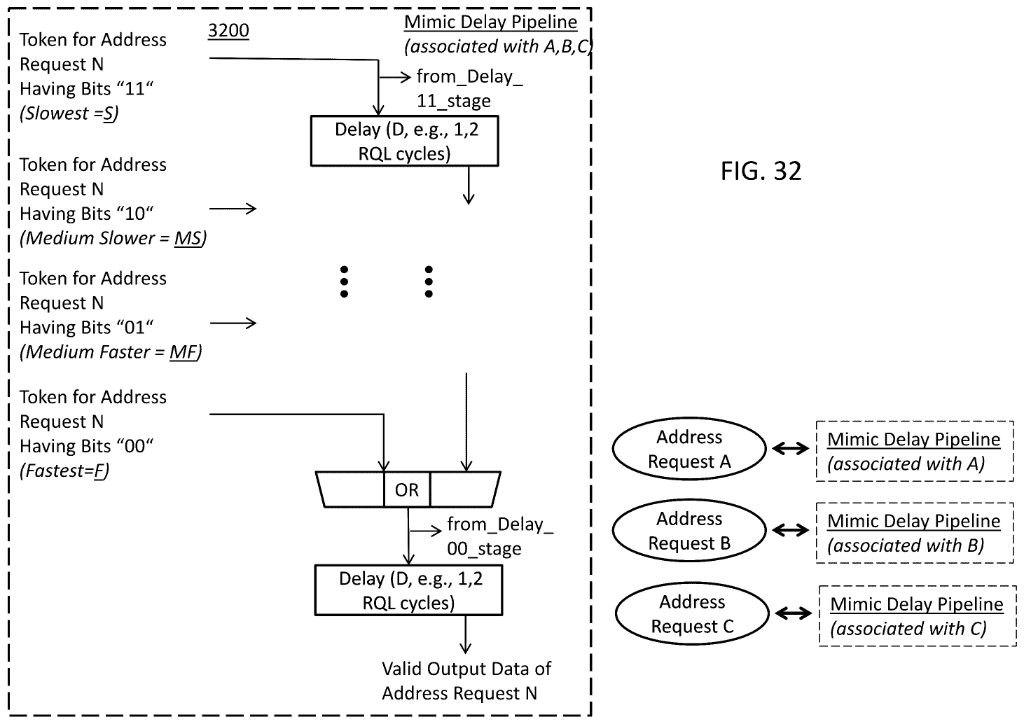

The term “upstream RQL cycle staging,” as may be used herein, is intended to represent cycles for which a prior RAM request can exist and is resident as a wave of data (in the context of a wave pipelining scheme). Subset address bits of a next (i.e., new) RAM request are not yet known. The term “downstream RQL cycle staging,” as may be used herein, is intended to represent cycles where the address propagates to and through the RAM until the output data bus is valid. The term “action cycle,” as may be used herein,” may be defined as the first cycle that subset address bits are available for checking/setting the chain. In one or more embodiments, the four subset address decode values and corresponding action cycles associated therewith may be assigned as follows:
“11” S=slow, “10” MS=medium slow, “01” MF=medium fast, “00” F=fast
   The S/MS/MF/F abbreviations are obtained from Table B and text immediately following that table. (See also, an alternative embodiment depicted in FIG. 32.)

On the action cycle, there is a new request, fed from the final “upstream RQL cycle staging” mentioned above, with a corresponding subset address value, that maps to one of S/MS/MF/F. That value sets a corresponding RQL cycle chain bit labeled as s/ms/mf/f.

With continued reference to FIG. 29, one way to represent the respective cycles and their sets may be using the following convention. Specifically, entities having uppercase letters (2901, 2903, 2905, 2907) may represent action cycles where new requests are potentially setting corresponding RQL cycle chain bits pointed to by the vertical arrows shown in FIG. 29. Entities having lowercase letters (2911, 2913, 2915, 2917) may represent RQL cycle chain bits propagating to downstream chain bits pointed to by the horizontal arrows in FIG. 29. Each of the vertical and horizontal arrows represent an RQL cycle. A discussion of an illustrative operation of the variable delay pipelined memory array 2900 follows, with the understanding that embodiments of the invention are not limited to the operation described.

The “f” bit feeds the start of the “downstream RQL cycle staging” previously mentioned. There would likely be a similar chain that contains a multibit request tag field that identifies a requestor in some way (e.g., identification bits). Such bits may also include the subset of RAM address bits being used to skew the RAM data output timing.

During the action cycle, certain prescribed actions may occur, including, for example, the following:

(1) One of the subset address decodes S, MS, MF, F will set (“turn on” or “enable”) a corresponding one of the RQL cycles s, ms, mf, f.

(2) A collision may be detected. If the bit being set on the action cycle (e.g., vertical arrows in FIG. 29) is also being propagated into (e.g., horizontal arrows FIG. 29), then a collision will be detected. For example, on a given RQL cycle, S (2901) sets s (2911), and on the next RQL cycle, MS (2903) and s (2911) both collide into ms (2913). In the collision formula, this can be represented as “s and MS” (a collision cycle). In a multi-cycle example, this can be labelled as “S/MS,” which will mean S on a given RQL cycle, followed by MS on the next RQL cycle.

(3) Out-of-order requests may be detected. If the bit being set on the action cycle (e.g., vertical arrows of FIG. 29) is to the right of a bit being propagated into (e.g., horizontal arrows FIG. 29), then an out-of-order condition will be detected. For example, on a given RQL cycle, S (2901) sets s (2911), and on the next RQL cycle, s (2911) propagates to ms (2913) and MF (2905) sets mf (2915). What has happened here is that a later request jumped in front of an earlier request, because the later request may have had a subset address value that was two RQL cycles quicker than the earlier request. In the out-of-order formula, this can be represented as “s and MF.” In a multi-cycle example, this can be labelled as “S/MF,” which will mean S on a given RQL cycle, followed by MF on the next RQL cycle.

The functions for collision cycles and out-of-order (OOO) definitions and can be expressed as follows, with reference to the designations used in FIG. 29:

$$Collision cycles = ( \underline{s} and \underline{MS} ) or ( \underline{ms} and \underline{MF} ) or ( \underline{mf} and \underline{F} ) \qquad [ 1 ]$$

$$OOO = ( \underline{s} and \underline{MS} ) or ( \underline{s} and \underline{F} ) or ( \underline{ms} and \underline{F} ) \qquad [ 2 ]$$

A series of examples are provided herein below that can be used to verify the accuracy of the above expressions [1], [2] for collision cycles and out-of-order definitions, respectively.

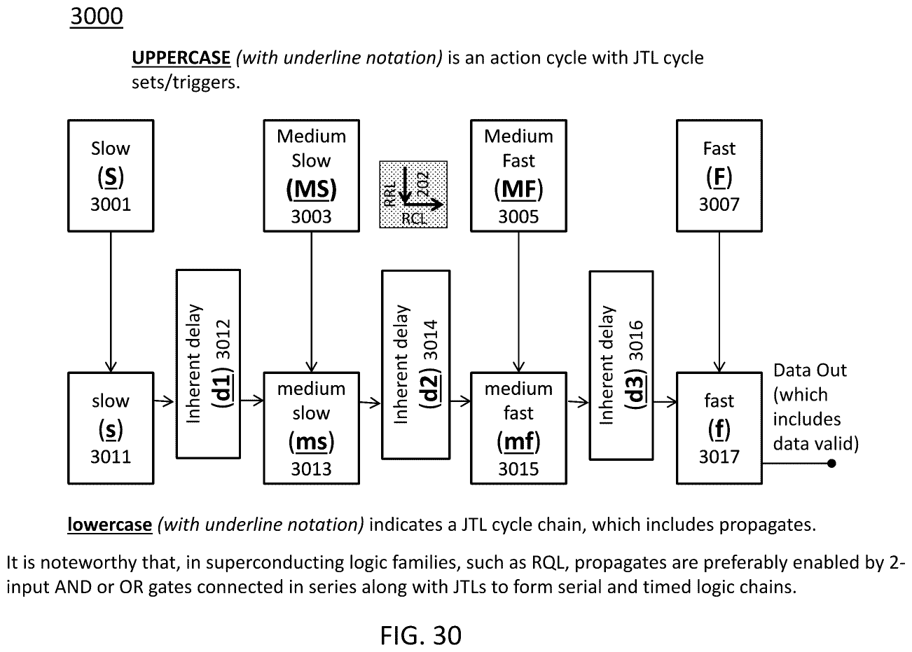

FIG. 30 is a block diagram depicting at least a portion of an exemplary variable delay pipelined memory array 3000 including added delay elements, according to one or more embodiments. The variable delay pipelined memory array 3000 may be implemented in a manner consistent with the illustrative variable delay pipelined memory array 2900 shown in FIG. 29, with additional cycles of delay inserted between consecutive subset values. More particularly, a first delay block (having a delay value d1) 3012 may be inserted between consecutive subset values 3011 and 3013, a second delay block (having a delay value d2) 3014 may be inserted between consecutive subset values 3013 and 3015, and a third delay block (having a delay value d3) 3016 may be inserted between consecutive subset values 3015 and 3017. The respective delay values d1, d2, d3 may, in one or more embodiments, be the same (e.g., one RQL cycle). In some embodiments, two or more of the delay values may be different from one another. However, for the Boolean expressions described herein the delays (through 3012, 314, 3016) are the same.

As an example of a collision, assume that on a given RQL cycle, S (3001) sets s (3011), on the second RQL cycle, s (3011) propagates to d1 (3012), and on the third RQL cycle, MS (3003) and d1 (3012) both collide into ms (3013). In the subsequent collision expression, this case can be represented as “d1 and MS” (the collision cycle). (Multi-cycle examples are not included for the “additional cycle of delay” cases). Similar to the expression, the collision cycles may be determined as follows:
Collision cycles=(d1 and MS) or (d2 and MF) or (d3 and F)

As an example of an out-of-order condition, assume that on a given RQL cycle, S (3001) sets s (3011), on the second RQL cycle, s (3011) propagates to d1 (3012), and on the third RQL cycle, d1 (3012) propagates to ms (3013) and MF (3005) sets mf (3015). What has occurred in this example is that a later request jumped in front of an earlier request, because the later request had a subset address value that was four RQL cycles quicker than the earlier request. In the subsequent out-of-order condition expression, this can be represented as “d1 and MF.” (Again, multi-cycle examples are not included for the “additional cycle of delay” cases). Somewhat similar to expression [2] above, the out-of-order definition may be determined as follows:
OOO=(s and MS) or
((s or d1 or ms) and MF) or
((s or d1 or ms or d2 or mf) and F).
   Other similar examples could be developed for cases where additional delay cycles are included.

The “collision cycles” and “out-of-order” definitions can be generalized using words rather than variables, to cover a variable number of subset address bits, a variable number of delay cycles, and a variable number of subset address decodes. As used in the definitions below, the term “RQL cycle chain” refers to all the bits from “s” to “f.”
collision cycles=Both sets of a RQL cycle chain bit are occurring at the same time,
   where the term “both sets” may be defined as an RQL cycle chain propagate and action cycle set. The “propagate” may either be from the previous subset address RQL cycle or from the rightmost previous delay RQL cycle. An example of a propagate from the previous subset address RQL cycle would be, in FIG. 29, S 2901 setting s 2911, followed by s 2911 propagating into ms 2913, where S 2901 is the previous subset address RQL cycle, relative to MS 2903.

If a delay such as d1 3012 is multiple RQL cycles, then that delay itself would be a chain of latches, propagating values from left to right, just like the horizontal arrows in FIG. 30 are going toward the right. The term “rightmost” refers to the final delay latch in that mini-chain, the one that feeds ms 3013.

The out-of-order definition may be expressed in words as follows:
OOO=The RQL cycle chain already has at least one upstream bit on,
   where the bit(s) are at least two cycles upstream (i.e., to the left in FIG. 30) of the RQL cycle stream bit that is being set on the action cycle. The upstream RQL cycle(s) can be a mix of previous subset address RQL cycles and delay RQL cycles.

If a collision is detected, the RAM read enable for the newer request must be blocked (or otherwise delayed from being serviced) in order to prevent corruption of the array output data. (For this technology, the array output corruption function would be an “OR” of the two colliding data sources).

In one or more embodiments, if a collision is detected, the newer request will not modify the value of any RQL cycle chain bits, including the request tag field in the address. The collision may be reported to the requestor logic and then vanishes, at least from the perspective of the RAM logic. It is then up to the requestor logic to resolve the collision, for example by recycling (i.e., reissuing) the request. The prior request, that the newer request had collided with, will continue to be processed as if no collision occurred.

On the action cycle (or one cycle later) and/or on the data valid cycle, the request tag field may be used by the RAM logic to inform the requestor logic about what request(s) had a collision, or is out of order, or how many address skew cycles the request had. Other information may alternatively, or in addition to, be provided to the requestor logic.

The action cycle of the RAM logic may occur as soon as the incoming request signal and corresponding subset of address bits are staged (the term “latched” would be used for conventional CMOS designs). In some embodiments, it may be that the upstream requestor logic making the RAM request includes its own chain of RQL cycles with its own action cycle that is earlier than the action cycle of the RAM logic.

In fact, this arrangement may allow the requestor logic to avoid collisions in the first place, or at least take action sooner to handle collisions upon detection. The arrangement may also enable the requestor logic to handle out-of-order conditions more efficiently. For example, the requestor logic may be configured to pick subset address bits whose value is known relatively early with relatively good timing, or to predict subset address values earlier with relatively good accuracy. Perhaps this would result in choosing address bits that have better late-mode timing (i.e., late timing in a cycle), if the address bits, for example, were coming from an adder.

For embodiments in which the requestor logic includes its own RQL cycle chain, the subset of address bits chosen for skewing the RAM output data timing may be bits that are not modified downstream from the requestor logic. Specifically, these address bits used for skewing the RAM output data timing should not be translated physical address bits that the requestor logic is unaware of, but the RAM logic is aware of. For example, if the RAM logic was aware of TLB physical address output bits, that address a RAM being used as a dcache, to avoid synonyms. An example of this would be if some TLB output physical address bits were being used as array index bits into the directory and cache arrays.

Some examples used to derive the above expressions [1], [2] for collision cycles and out-of-order definitions, respectively, are provided below. (Those expressions are also copied below for comparison). In the examples shown below, reference may be made to the label designations shown in FIG. 29. These examples assume two address bits are used for selecting one of the fixed-delay-address subsets, but assume no delay cycles (d1 or d2 or d3 cycles) for simplification purposes. In the example below, the naming convention “x/x” will be used to refer to two action cycles in a row that are setting the “x” RQL cycle.

The examples below are not exhaustive, because they only include back-to-back action cycles, as opposed to gap cycle(s) between 2 action cycles. To be specific, the examples illustrate all the terms shown in the out-of-order and collision expressions, but for lowercase terms in the formulas, that are fed from both action cycle sets & propagate sets, only the action cycle sets are illustrated.

For column headings, s=slow, and f=fast (i.e., faster by three RQL cycles, as previously explained). The two unlabeled RQL cycles in-between are ms=medium slow, and mf=medium fast, which are one and two RQL cycles faster than s, respectively. A fifth column has been added in the example below, to the right of the “f” column, because seeing that fifth RQL cycle makes it more clear what is happening in some of the examples. Each sequential row is one cycle. Propagating latch cycle bits move from left to right. The naming convention “set x” appearing to the right of a row means set the “x” RQL cycle.

### No Collision and No OOO Condition

S/S
no collision, no OOO

| s | f |
|---|---|
| 00000 | S |
| 10000 | S |
| 11000 | |
| 01100 | |
| 00110 | |
| 00011 | |
| 00001 | |

F/F
no collision, no OOO

| s | f |
|---|---|
| 00000 | F |
| 00010 | F |
| 00011 | |
| 00001 | |
| 00000 | |

(also, no collision for MS/MS or MF/MF)

F/MF
no collision, no OOO

| s | f |
|---|---|
| 00000 | F |
| 00010 | MF |
| 00101 | |
| 00010 | |
| 00001 | |
| 00000 | |

(Also no collision for F/MS, F/S, MF/MS, MF/S, MS/S)

### Collision and No OOO Condition

For comparison purposes, the expression [1] above for collision cycles is repeated below:

Collision cycles=(s and MS) or (ms and MF) or (mf and F).

S/MS
collision

| s | f |
|---|---|
| 00000 | S |
| 10000 | MS: bit being set by both new set and propagate |
| 01000 | |

MS/MF
collision

| s | f |
|---|---|
| 00000 | MS |
| 01000 | MF: bit being set by both new set and propagate |
| 00100 | |

MF/F
collision

| s | f |
|---|---|
| 00000 | MF: bit being set by both new set and propagate |
| 00100 | F |
| 00010 | |

### OOO and No Collision

For comparison purposes, the expression [2] above for out-of-order conditions is repeated below:

OOO=(s and MF) or (s and F) or (ms and F)

S/MF
OOO, no collision

| s | f |
|---|---|
| 00000 | S |
| 10000 | MF: bit being set is to the right of a bit being propagated into |
| 01100 | =new request returning data faster than old request |
| 00110 | =OOO |

S/F
OOO, no collision

| s | f |
|---|---|
| 00000 | S |
| 10000 | F: bit being set is to the right of a bit being propagated into |
| 01010 | =new request returning data faster than old request |
| 00101 | =OOO |

MS/F
OOO, no collision

| s | f |
|---|---|
| 00000 | MS |
| 01000 | F: bit being set is to the right of a bit being propagated into |
| 00110 | = new request returning data faster than old request |
| 00011 | = OOO |

Earlier, it was discussed how TDM and/or wave pipelining could be used to make the lookup path bussing more wirable, where a drawback is that lookup bandwidth is cut in half.

Previously, it was discussed how subset-address skew can cause data RAM(s) 408 output bus collisions. A preferred embodiment was to kill the newer of the two requests to avoid the collision, and have the requestor unit recycle it. Later, an alternative embodiment suggests holding the newer of the two requests as an internal dcache unit requester, with a limited number of such internal requestors, and associated state machines for each.

If lookup bandwidth is cut in half, and we start with part of the earlier embodiment for handling subset-address skew, consider an option that avoids collisions by delaying the newer request by one RQL cycle. Such a one cycle delay will be called a backup.

For the examples discussed, assume, by way of example only, that lookup request results and corresponding action requests are only available on even cycles, or only available on odd cycles. (Embodiments may be workable with a minimum of one cycle between lookup request results, without the added restriction of even (or odd) cycles.) Assume there is only one cycle of delay between consecutive subset address values (as in FIG. 29). Also assume the data RAM(s) 408 is running at full bandwidth, even though the associated lookup path is only running at half bandwidth.

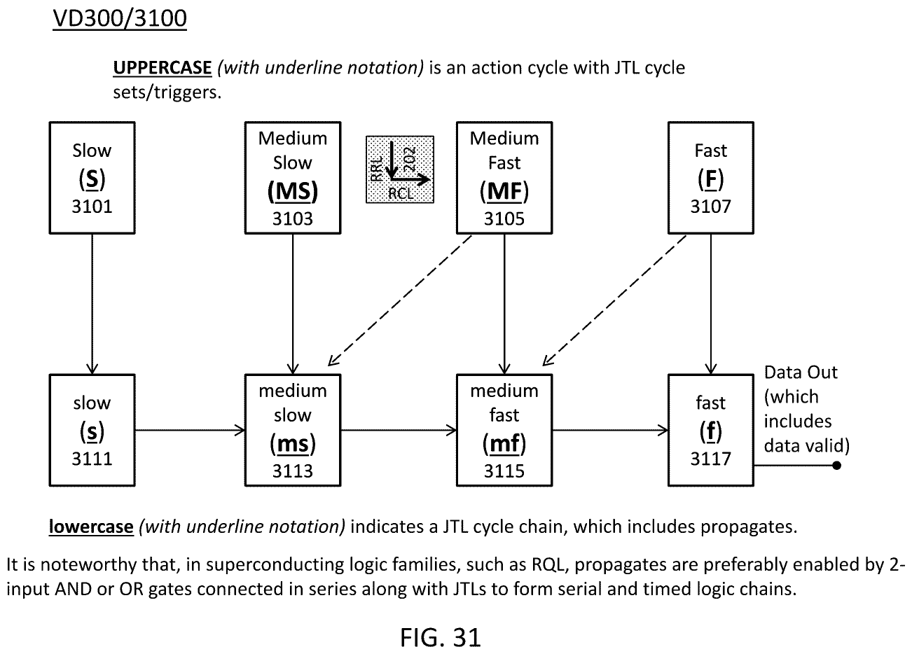

One difference between FIGS. 29 and 31 is the addition of two diagonal dashed arrows. Because action cycles in this illustrative embodiment are always two cycles apart, this limits the number of collision cases to two. Those cases are as follows:
1) (mf and F), where that case is caused by cycle sequence MS/g/F,
2) (ms and MF), where that case is caused by cycle sequence S/g/MF, potentially followed by a 2^{nd} collision (mf and F), by appending cycle sequence /g/F, where g represents a gap cycle (the cycle between consecutive even or odd cycles).

OOO cases are not discussed, since their detection and handling is not substantially different than the original embodiment of FIG. 29.

Let's discuss each of the above two cases in substantial detail, referencing the blocks in FIG. 31, as well as the corresponding two examples below, where the format of the two examples is somewhat similar to the many examples shown earlier.
First example ((mf and F)=MS/g/F):
On cycle 1, MS (3103) sets ms (3113).
On cycle 2, ms (3113) propagates to mf (3115).
On cycle 3, mf (3115) propagates to f (3117)
   (the horizontal arrow in FIG. 31 and the ‘1’ in the 4^{th} row in the 1^{st} example below) and
   F (3107) is about to collide into f (3117)
   (the vertical arrow in FIG. 31).

The collision is prevented by blocking the RAM read enable for the newer request. So far, the handling matches the original embodiment of FIG. 29. The new aspect is that a backup is done on the newer request: the F (3107) backs up into mf (3115) so that it will leave the RQL cycle chain one cycle later than originally expected. The backup is shown in FIG. 31 as the diagonal arrow from F (3107) to mf (3115). The backup is shown in the first example below as the ‘b’ in the 4^{th} row, which is immediately behind the ‘1’ in that row that it would have collided with. The RAM read address for the newer request is staged one cycle. On cycle 4, mf (3115) propagates to f (3117) (the ‘b’ in the 5^{th} row in the 1^{st} example below). The RAM read enable is turned on for the newer request, and the corresponding staged RAM read address is sent to the RAM. On cycle 5, F (3107) sets f (3117), to verify that no more collisions occur (row 6 in 1^{st} example below). Another such check is done two cycles later.
Second example ((ms and MF) followed by (mf and F)=S/g/MF/g/F):
On cycle 1, S (3101) sets s (3111).
On cycle 2, s (3111) propagates to ms (3113).
On cycle 3, ms (3113) propagates to mf (3115)
   (the horizontal arrow in FIG. 31 and the ‘1’ in the 4^{th} row in the 2^{nd} example below) and
   MF (3105) is about to collide into mf (3115) (the vertical arrow in FIG. 31).

The collision is prevented by blocking the RAM read enable for the newer request at the appropriate time. So far, the handling matches the original embodiment of FIG. 29. The new aspect is that a 1^{st} backup is done on the newer request: the MF (3105) backs up into ms (3113) so that it will leave the RQL cycle chain one cycle later than originally expected. The first backup is shown in FIG. 31 as the diagonal arrow from MF (3105) to ms (3113).

The 1^{st} backup is shown in the second example below as the ‘b’ in the 4^{th} row. The RAM read address for the newer request is staged one cycle. On cycle 4, mf (3115) propagates to f (3117), and ms (3113) propagates to mf (3115), (where ms was the 1^{st} backup that occurred last cycle, shown as the ‘b’ in row 5 of the 2^{nd} example below). The RAM read enable will be turned on for the 1^{st} backup request, and the corresponding staged RAM read address is sent to the RAM, both at the appropriate time. On cycle 5, mf (3115) propagates to f (3117), the horizontal arrow in FIG. 31, and the 1^{st} backup, shown as the rightmost ‘b’ in row 6 in the 2^{nd} example below) and F (3107) is about to collide with the 1^{st} backup into f (3117) (the vertical arrow in FIG. 31). The collision is prevented by blocking the RAM read enable for the newer request at the appropriate time.

A 2nd backup is done on the newer request: the F (3107) backs up into mf (3115) so that it will leave the RQL cycle chain one cycle later than originally expected. The 2nd backup is shown in FIG. 31 as the diagonal arrow from F (3107) to mf (3115). The 2nd backup is shown in the 2nd example below as the leftmost ‘b’ in the 6^{th} row, where there are back-to-back backups represented by the 2 b's in that row. The RAM read address for the newer request is staged one cycle. On cycle 6, mf (3115) propagates to f (3117), (the 2nd backup that occurred last cycle, shown as the leftmost ‘b’ in row 7 of the 2^{nd} example below). The RAM read enable will turned on for the 2^{nd} backup request, and the corresponding staged RAM read address is sent to the RAM. On cycle 7, F (3107) sets f (3117), to verify that no more collisions occur (row 8 in the 2^{nd} example below). Another such check is done 2 cycles later.

One reason that FIG. 31 doesn't have a diagonal arrow from MS (3103) to s (3111), is that a collision at ms (3113) can only occur if S (3101) is immediately followed by MS (3103). But it was stated earlier for this idea that action cycles cannot occur on back-to-back cycles (there must be a gap cycle in between).

The 2 examples below follow a format similar to the previous examples, except for at least the following differences:
1) all 4 cycle chain points are labeled (instead of 2);
2) a total of 7 chain points are shown (instead of 5);
3) the case labeling includes g (gap) cycles;
4) “b” labeling (backup) is used for the backup cycle and its propagation (instead of ‘l’ labeling); and
5) the case labeling includes a blank followed by “/g/F/g/F”.
   This suffix expression is not the key part of the example. Instead, it is adding pressure to the chain to verify that no more avoidable or unavoidable collisions occur.

MS/g/F/g/F/g/F
avoid collision
mm

| ss | f f |
|---|---|
| 0000000 | MS |
| 0100000 | |
| 0010000 | F: bit being set by both new set & propagate: |
| 00b1000 | avoid collision by setting b/backup instead |
| 000b100 | F: the later F's are to check for |
| 0001b10 | avoidable or unavoidable collisions: |
| 00001b1 | F to make sure stream doesn't get overloaded |
| 000101b | |

S/g/MF/g/F/g/F/g/F
avoid collisions
mm

| ss | f f |
|---|---|
| 0000000 | S |
| 1000000 | |
| 0100000 | MF: bit being set by both new set and normal propagate: |
| 0b10000 | avoid collision by setting b/backup instead |
| 00b1000 | F: bit being set by both new set & ‘b’ propagate: |
| 00bb100 | again avoid collision by setting another b/backup instead |
| 000bb10 | F: the later F's are to see if there are more |
| 0001bb1 | avoidable or unavoidable collisions: |
| 00001bb | F to make sure stream doesn't get overloaded |
| 000101b | |

With respect to FIG. 32, two-bit high order address bits are decoded and then gated with request valid (read enable). Below are action gated, and relative cycle targeted row addresses, which will be referred to as “fixed-delay-address-request subset” of each fixed-delay-address subset. They are used for injecting a token into the “mimic delay pipeline” of FIG. 32, which will be described below.

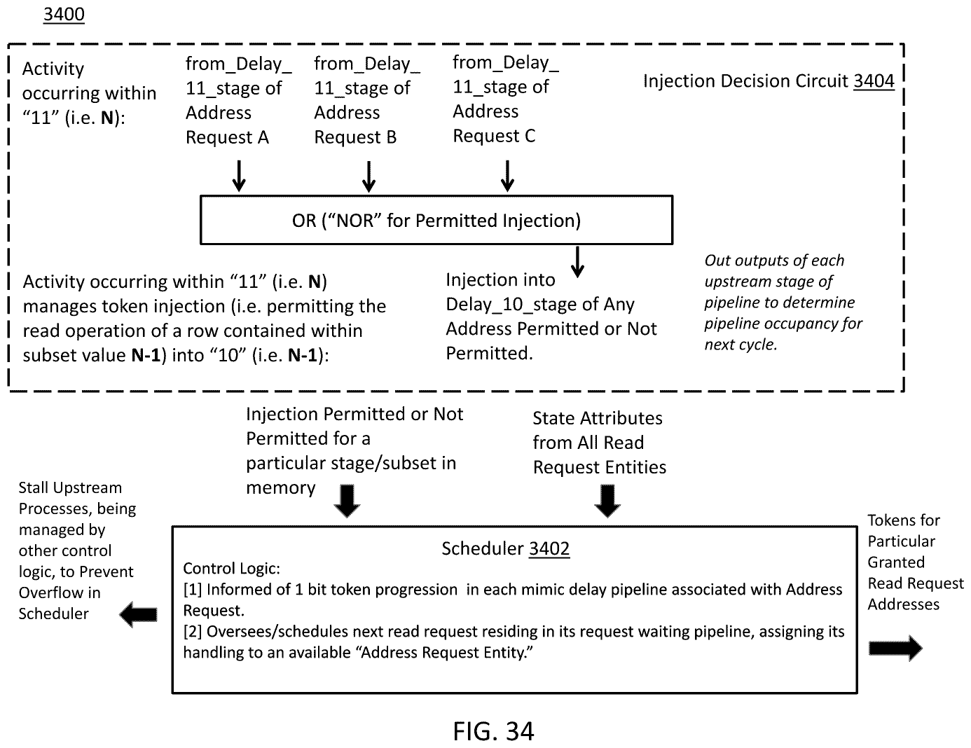

FIG. 32 depicts an alternative embodiment of the control circuits for a variable latency RAM having a plurality of mimic delay pipelines and their associated address request entities, which collectively not only indicate the movement of waves ongoing in the array/memory which they are mimicking, but individually as associated pairs of an address request entity and mimic delay pipeline that identify the address of the data egressing the array on any particular cycle. Essentially, upon recognizing an opening in the RAM and an available mimic delay pipeline and associated address request entity, the scheduler, to be described with respect to FIG. 34, injects a token at the associated address input (fixed-delay-address subsets) in a mimic delay pipeline and records its associated address in an address request entity.

The labeling of address requestors as A: C should not be confused with the separate/independent labeling of cache ways or set associativity as A: D.

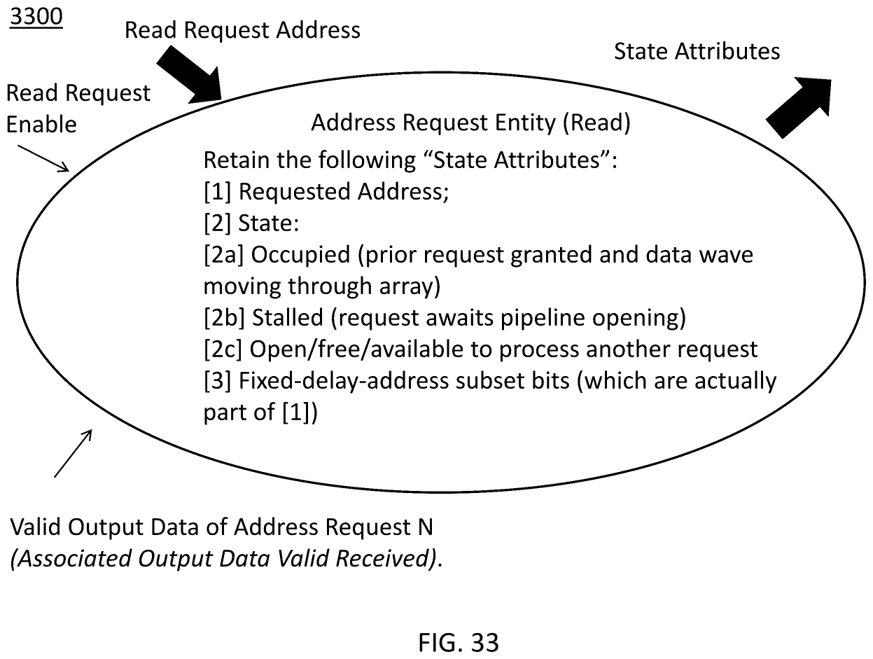

FIG. 33 depicts the inputs, outputs, and states of an address request entity. The inputs include (1) read request address, (2) read request enable, and (3) valid output data of address request N. They are principally sourced by the scheduler of FIG. 34, but with one exception the “Valid Output Data Address Request N” sourced from FIG. 32. The outputs are just the state attributes, which are provided to the scheduler entity of FIG. 34. The state, or state attributes, can include (1) the request address; (2) state, more specifically including (2a) occupied (prior request granted and thus wave moving through array), (2b) stalled (request awaits pipeline opening), and (2c) open/free/available to process another request; and (3) fixed-delay-address subset bits (which are actually part of (1)).

When the Valid Output Data of Address Request N token is received, the state of the address request entity is set to indicate that it is open/free/available to process another request (2c). When the read request enable is activated, the request is granted unless the/this particular request must be stalled to await a pipeline opening (2b). The scheduler of FIG. 34 will only issue requests to open/free/available address request entities, and not those in an occupied or stalled state.

FIG. 34 depicts a scheduler and an injection decision circuit. The injection decision circuit essentially samples upstream tokens (i.e., data wave activity) to determine in advance whether a downstream token, if injected, would collide with an existing upstream token. Such sampling can be done on a stage-by-stage basis operating between fixed-delay address subsets, where data collisions can occur.

Yet another alternative embodiment exists for which the scheduler permits only in order retrieval of data; OOO is prevented.

It will be understood that, although the terms “first,” “second,” etc., may be used herein to describe various elements, these elements should not be limited by such terms. These terms are only used to distinguish one element from another and should not be interpreted as conveying any particular order of the elements with respect to one another. For example, a first element could be termed a second element, and, similarly, a second element could be termed a first element, without departing from the scope of the present disclosure. As may be used herein, the term “and/or” when used in conjunction with an associated list of elements is intended to include any and all combinations of one or more of the associated listed elements. For example, the phrase “A and/or B” is intended to include element A alone, element B alone, or elements A and B.

The terminology used herein is for the purpose of describing particular embodiments of the inventive concepts only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” as used herein, are intended to specify the presence of stated features, integers, steps, operations, elements, and/or components, but do not necessarily preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

In accordance with embodiments of the present disclosure described herein, when an element such as a device or circuit, for example, is referred to as being “connected” or “coupled” to another element, it is to be understood that the element can be directly connected or coupled to the other element or intervening elements may be present. In contrast, when an element is referred to as being “directly connected” or “directly coupled” to another element, it is intended that there are no intervening elements present.

Relative terms such as, for example, “below,” “above,” “upper,” “lower,” “horizontal,” “lateral,” “vertical,” “right” (or “rightmost”) or “left” (or “leftmost”), may be used herein to describe a relationship of one element, layer or region to another element, layer or region as illustrated in the figures. It will be understood, however, that these terms are intended to encompass different orientations of a device or structure in place of or in addition to the orientation depicted in the figures.

Like reference numbers and/or labels, as may be used herein, are intended to refer to like elements throughout the several drawings. Thus, the same numbers and/or labels may be described with reference to other drawings even if they are neither explicitly mentioned nor described in the corresponding drawing. Moreover, elements that are not denoted by reference numbers and/or labels may be described with reference to other drawings.

In the drawings and specification, there have been disclosed typical embodiments of the invention and, although specific terms may be employed, they are intended to be used in a generic and descriptive sense only and not for purposes of limitation, the scope of the invention being set forth in the appended claims.

1. A time-division multiplexed (TDM) lookup circuit for use in a superconducting cache, the TDM lookup circuit comprising:
a superconducting memory; and
at least one comparator circuit operatively coupled to the superconducting memory, the comparator circuit including a first input adapted to receive a first address corresponding to a requested data location in the superconducting memory and a second input adapted to receive a second address corresponding to a memory location external to the TDM lookup circuit, the comparator being configured to perform at least one compare process wherein the first address is compared with the second address and an output signal is generated that is indicative of whether a match has occurred between the first and second addresses;
wherein the at least one comparator is configured to perform multiple compare processes per lookup access.

2. (canceled)

3. The TDM lookup circuit according to claim 1, wherein the superconducting memory is configured as a directory or a translation lookaside buffer (TLB).

4. The TDM lookup circuit according to claim 3, wherein the superconducting memory is configured as a fully associative TLB or a set associative TLB.

5. The TDM lookup circuit according to claim 1, wherein the at least one comparator circuit is configured to perform serial bit-by-bit comparisons in an increasing time sequence.

6. The TDM lookup circuit according to claim 1, wherein the at least one comparator circuit comprises:
a plurality of XOR logic gates configured to detect bit-by-bit mismatches between respective bits of the first and second addresses;
a plurality of OR logic gates serially connected and configured to accumulate mismatch results generated by the plurality of XOR logic gates; and
an output circuit configured to convert a miss signal, indicating that an overall mismatch has occurred, into a hit signal, indicating that a match was detected.

7. The TDM lookup circuit according to claim 6, wherein each of the plurality of OR logic gates is configured to merge a current mismatch result of a corresponding one of the plurality of XOR logic gates with prior mismatch results of corresponding ones of the plurality of XOR logic gates coupled to a preceding one of the plurality of OR logic gates.

8. The TDM lookup circuit according to claim 1, wherein the at least one comparator circuit comprises:
an output circuit; and
a plurality of mismatch circuits connected in parallel to the output circuit,
wherein each of the plurality of mismatch circuits comprises:
a plurality of XOR logic gates configured to detect bit-by-bit mismatches between respective bits of the first and second addresses; and
a plurality of serially connected OR logic gates configured to accumulate mismatch results generated by the plurality of XOR logic gates,
wherein the output circuit is configured to merge mismatch results generated by the plurality of mismatch circuits into a combined mismatch result indicative of an overall mismatch between the first and second addresses.

9. The TDM lookup circuit according to claim 3, wherein the directory comprises one of a set associative directory or a fully associative directory.

10. The TDM lookup circuit according to claim 1, further comprising at least one copy delay circuit operatively coupled between the superconducting memory and the at least one comparator circuit.

11. The TDM lookup circuit according to claim 1, further comprising a column-oriented TDM circuit operatively coupled between the superconducting memory and the at least one comparator circuit.

12. A superconducting time-division multiplexed (TDM) memory circuit, comprising:
a plurality of row lines;
a plurality of column lines;
a plurality of superconducting memory cells, each of the superconducting memory cells arranged in a first direction along a corresponding one of the plurality of row lines, each of the superconducting memory cells arranged in a second direction along a corresponding one of the plurality of column lines, wherein the plurality of superconducting memory cells are arranged into at least first and second subsets;
a first decoder and driver circuit operatively coupled to superconducting memory cells in a first row line of the plurality of row lines in the first subset;
a second decoder and driver circuit operatively coupled to superconducting memory cells in a second row line of the plurality of row lines in the second subset;
a first delay circuit operatively coupled to the first decoder and driver circuit and having an output coupled to superconducting memory cells in a third row line of the plurality of row lines in the first subset; and
a second delay circuit operatively coupled to the second decoder and driver circuit and having an output coupled to superconducting memory cells in a fourth row line of the plurality of row lines in the second subset.

13. The superconducting TDM memory circuit of claim 12, wherein the first decoder and driver circuit and the first delay circuit are configured to respectively enable a first selection of at least two row lines of the plurality of row lines in the first subset, and the second decoder and driver circuit and the second delay circuit are configured to respectively enable a second selection of at least two row lines of the plurality of row lines in the second subset.

14. The superconducting TDM memory circuit of claim 12, wherein the first row line of the plurality of row lines is adjacent to the third row line of the plurality of row lines, and wherein the second row line of the plurality of row lines is adjacent to the fourth row line of the plurality of row lines.

15. The superconducting TDM memory circuit of claim 12, wherein each of the first and second delay circuits is configured to delay access to superconducting memory cells of the plurality of superconducting memory cells corresponding to a given column line of the plurality of column lines in each of the first and second subsets, respectively, by an integer number of single-flux-quantum (SFQ) logic cycles.

16. The superconducting TDM memory circuit of claim 12, wherein during a read operation, for each of the plurality of column lines, each of the first and second decoder and driver circuits is configured to initiate a propagation of data, on a first memory cycle, in the second direction across the plurality of superconducting memory cells from a first selection of one of the plurality of row lines in each of the first and second subsets, respectively, to a data output of the plurality of row lines,
wherein for each of the plurality of column lines, each of the first and second delay circuits is configured to initiate a propagation of data, on a second memory cycle subsequent to the first memory cycle, in the second direction across the plurality of superconducting memory cells from a second selection of one of the plurality of row lines in each of the first and subsets, respectively, to the data output of the plurality of row lines, and
wherein data outputs of the superconducting TDM memory circuit are provided by respective superconducting memory cells in a last row line of the plurality of row lines in each of the plurality of column lines.

17. The superconducting TDM memory circuit of claim 16, wherein during the read operation, each of the first and second delay circuits is configured to delay access to one of the plurality of superconducting memory cells corresponding to each of the plurality of column lines in the first and second subsets, respectively.

18. The superconducting TDM memory circuit of claim 16, wherein during a read operation, each of the first and second decoder and driver circuits, in conjunction with each of the first and second delay circuits, respectively, are configured to retrieve data from superconducting memory cells corresponding to at least two row lines in each of the first and second subsets, respectively, during each memory access.

19. The superconducting TDM memory circuit of claim 12, wherein during a write operation, for each of the plurality of column lines, each of the first and second decoder and driver circuits is configured to propagate a selection signal to receive data from the second direction across the superconducting memory cells from a data input to a selected row line of the plurality of write row lines in each of the first and subsets, respectively, and wherein data inputs of the superconducting TDM memory circuit are provided at write inputs of respective superconducting memory cells in an initial row line of the plurality of row lines in each of the plurality of column lines.

20. The superconducting TDM memory circuit of claim 19, wherein during the write operation, each of the first and second decoder and driver circuits is configured to enable writing of data into superconducting memory cells corresponding to at least two row lines in each of the first and second subsets, respectively, of the plurality of superconducting memory cells during each memory access.

21. The superconducting TDM memory circuit of claim 19, wherein during the write operation, the first and second delay circuits are configured to delay selection of the superconducting memory cells in the third and fourth row lines, respectively.

22. The superconducting TDM memory circuit of claim 12, wherein the first delay circuit is configured to provide a delayed version of a first enable signal, generated by the first decoder and driver circuit, to the to the superconducting memory cells in the third row line, and the second delay circuit is configured to provide a delayed version of a second enable signal, generated by the second decoder and driver circuit, to the to the superconducting memory cells in the fourth row line.

23. The superconducting TDM memory circuit of claim 12, wherein the first and second delay circuits are configured to delay access to superconducting memory cells corresponding to a given column line of the plurality of column lines in the first and second subsets, respectively, by an integer number of single-flux-quantum (SFQ) logic cycles.

24. The superconducting TDM memory circuit of claim 12, wherein the first row line of the plurality of row lines is non-adjacent to the third row line of the plurality of row lines, and wherein the second one of the plurality of row lines is non-adjacent to the fourth one of the plurality of row lines.

25. The superconducting TDM memory circuit of claim 12, wherein each of the first and second delay circuits comprises a superconducting feedforward circuit configured to introduce a prescribed cycle delay without including a latch in a signal path of each of the first and second delay circuits.

26. The superconducting TDM memory circuit of claim 25, wherein the prescribed cycle delay is configured to be equal to an integer number of single-flux-quantum logic (SFQ) cycles.
